(19) United States
(12) Patent Application Publication
(10) Pub. No.: US 2020/0385582 A1
(43) Pub. Date: Dec. 10, 2020

(54) CURABLE COMPOSITION, CURED PRODUCT, COLOR FILTER, METHOD FOR PRODUCING COLOR FILTER, SOLID-STATE IMAGING ELEMENT, AND IMAGE DISPLAY DEVICE

(71) Applicant: FUJIFILM Corporation, Tokyo (JP)

(72) Inventors: Yasuhiro SAWAMURA, Shizuoka (JP); Tokihiko Matsumura, Shizuoka (JP); Akio Mizuno, Shizuoka (JP); Hiromu Koizumi, Shizuoka (JP)

(73) Assignee: FUJIFILM Corporation, Tokyo (JP)

(21) Appl. No.: 17/000,442

(22) Filed: Aug. 24, 2020

Related U.S. Application Data
(63) Continuation of application No. PCT/JP2019/004487, filed on Feb. 7, 2019.

(30) Foreign Application Priority Data
Feb. 28, 2018 (JP) 2018-035195
Jan. 18, 2019 (JP) 2019-007285

(51) Int. Cl. C09B 57/00; G02F 1/1335; G02B 5/28; G03F 7/00

(52) U.S. Cl. CPC C09B 57/007; G03F 7/0007; G02B 5/28; G02F 1/133516

(57) ABSTRACT

Provided are a curable composition including a compound represented by Formula 1 and having a maximum absorption wavelength in a range of 600 nm or more and less than 700 nm, or a polymer having a structure represented by Formula 2 and having a maximum absorption wavelength in a range of 600 nm or more and less than 700 nm; a polymerizable compound; and a chromatic colorant different from the compound represented by Formula 1 and the polymer represented by Formula 2, as well as a cured product of the curable composition; a color filter including the cured product; a method for producing a color filter; a solid-state imaging element; and an image display device.

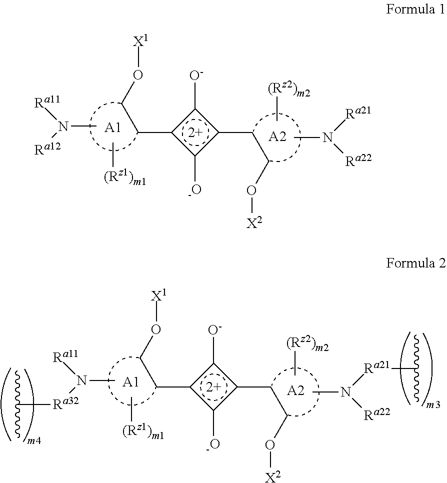

### CROSS-REFERENCE TO RELATED APPLICATIONS

This application is a continuation application of International Application No. PCT/JP2019/004487, filed Feb. 7, 2019, the disclosure of which is incorporated herein by reference in its entirety. Further, this application claims priority from Japanese Patent Application No. 2018-035195, filed Feb. 28, 2018, and No. 2019-007285, filed Jan. 18, 2019, the disclosures of which are incorporated herein by reference in their entirety.

### BACKGROUND OF THE INVENTION

### 1. Field of the Invention

The present disclosure relates to a curable composition, a cured product, a color filter, a method for producing a color filter, a solid-state imaging element, and an image display device.

### 2. Description of the Related Art

A member such as a color filter is produced by a photolithographic method or the like, using a coloring photosensitive composition which is formed by adding a polyfunctional monomer, a photopolymerization initiator, an alkali-soluble resin, and other components to a pigment dispersion composition such as a curable composition in which an organic pigment or an inorganic pigment is dispersed.

It is known to use a squarylium compound as the pigment.

Examples of a curable composition using a conventional squarylium compound include those described in WO2017/043175A, WO2017/154318A, and JP2014-510804A.

For example, WO2017/043175A discloses a near-infrared absorbing curable composition including a compound represented by Formula (1) and a compound having a crosslinkable group.

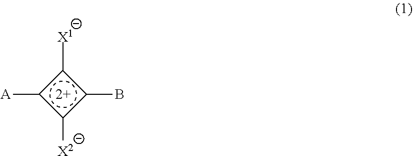

In Formula (1), X¹ and X² each independently represent O, S, or a dicyanomethylene group, and A and B each independently represent a group represented by Formula (2);

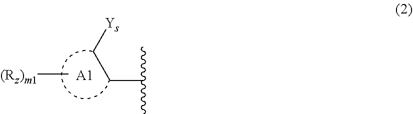

In Formula (2), a wavy line represents a bonding position in Formula (1), Ys represents a group having an active hydrogen, A1 represents an aromatic hydrocarbon ring structure or an aromatic heterocyclic structure, Rz represents a substituent, m1 represents an integer of 0 to mA, mA represents the maximum integer with which Rz can be substituted with A1, Ys may be bonded to A1 or Rz to form a ring structure, and Rz may be bonded to A1 to form a ring structure.

WO2017/154318A discloses a film including an aggregate of a dye and a resin, in which an average particle size of the aggregate of the dye is 30 to 450 nm.

JP2014-510804A discloses a squaraine compound of Formula I.

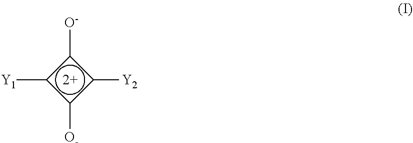

In the formula, Y₁ and Y₂ are each independently selected from an amino group which may be substituted and an aryl group which may be substituted.

### SUMMARY OF THE INVENTION

It has been studied to use a coloring agent having excellent spectral characteristics as a coloring agent used in forming a member such as a color filter. In the present disclosure, it is said that, with respect to the absorbance for light of specific wavelength A, the lower the absorbance for light of another wavelength B, the better the spectral characteristics, and the smaller the difference between the wavelength A and the wavelength B is, the better the spectral characteristics are. In general, the narrower the absorption wavelength peak width of the compound, the better the spectral characteristics.

In addition, it is known that a squarylium compound having a triarylamine structure and an aromatic ring structure bonding to a squaric acid and containing an oxygen atom at the ortho-position of a bonding site of the squaric acid has a small shoulder absorption on the short wavelength side, a narrow absorption wavelength peak width, and excellent spectral characteristics.

However, as a result of extensive studies, the present inventors have found that there is still room for improvement in spectral characteristics of the squarylium coloring agents used in WO2017/043175A, WO2017/154318A, and JP2014-510804A.

An object to be achieved by an embodiment according to the present disclosure is to provide a curable composition having excellent spectral characteristics of a cured product to be obtained, a cured product of the curable composition, a color filter comprising the cured product, a method for producing the color filter, and a solid-state imaging element or an image display device, each of which comprising the color filter.

Means for achieving the foregoing objects include the following aspects.

<1> A curable composition comprising:

a compound represented by Formula 1 and having a maximum absorption wavelength in a range of 600 nm or more and less than 700 nm, or a polymer having a structure represented by Formula 2 and having a maximum absorption wavelength in a range of 600 nm or more and less than 700 nm;

a polymerizable compound; and

a chromatic colorant different from the compound represented by Formula 1 and the polymer represented by Formula 2.

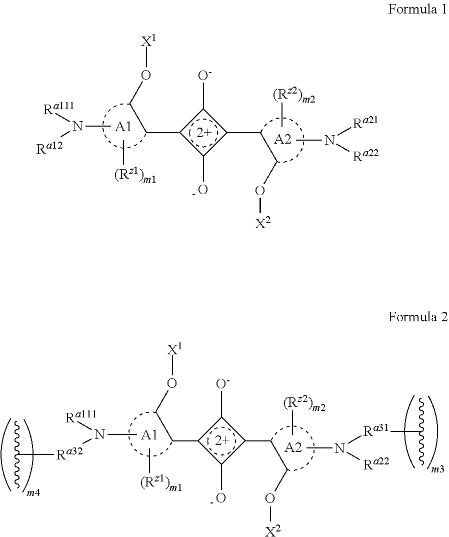

In Formula 1 and Formula 2, A1 and A2 each independently represent an aromatic ring structure which may have a fused ring, R^{z1} and R^{z2} each independently represent a monovalent substituent, at least one of R^{z1}'s and at least one of R^{z2}'s may be bonded to each other to form a ring structure, m1 represents an integer of 0 to mA1, mA1 represents the maximum number of substituents in A1, m2 represents an integer of 0 to mA2, mA2 represents the maximum number of substituents in A2, R^{z} may form a ring structure with any one of R^{a11} or R^{a12}, R^{z2} may form a ring structure with any one of R^{a21} or R^{a22}, X¹ and X² each independently represent a hydrogen atom or a substituent, X¹ and X² may be bonded to each other to form a ring structure, R^{a11}, R^{a12}, R^{a21}, and R^{a22} each independently represent an aromatic ring structure which may have a fused ring, R^{a31} and R^{a32} each independently represent an aromatic ring structure which may have a fused ring, or a linking group having an aromatic ring structure which may have a fused ring, m3 and m4 each independently represent 0 or 1, at least one of m3 or m4 is 1, at least one of R^{a11}, R^{a12}, R^{a21} or R^{a22} in Formula 1 represents an aromatic ring structure represented by A1 or A2 and having a substituent at a position adjacent to an atom to which a nitrogen atom in Formula 1 is bonded, or an aromatic ring structure represented by A1 or A2 and having a fused ring at a position adjacent to the atom to which a nitrogen atom in Formula 1 is bonded, at least one of R^{a11}, R^{a22}, R^{a31}, or R^{a32} in Formula 2 represents an aromatic ring structure represented by A1 or A2 and having a substituent at a position adjacent to an atom to which a nitrogen atom in Formula 2 is bonded, or an aromatic ring structure represented by A1 or A2 and having a fused ring at a position adjacent to the atom to which a nitrogen atom in Formula 2 is bonded, and a wavy line portion represents a bonding position to another structure.

<2> The curable composition according to <1>, in which the chromatic colorant is a yellow colorant.

<3> The curable composition according to <1> or <2>, in which the chromatic colorant is a yellow pigment.

<4> The curable composition according to any one of <1> to <3>, in which the chromatic colorant includes at least one selected from the group consisting of C.I. Pigment Yellow 139, C.I. Pigment Yellow 150, and C.I. Pigment Yellow 185.

<5> A curable composition used for producing a color filter, the curable composition comprising:

a compound represented by Formula 1 and having a maximum absorption wavelength in a range of 600 nm or more and less than 700 nm, or a polymer having a structure represented by Formula 2 and having a maximum absorption wavelength in a range of 600 nm or more and less than 700 nm; and

a polymerizable compound.

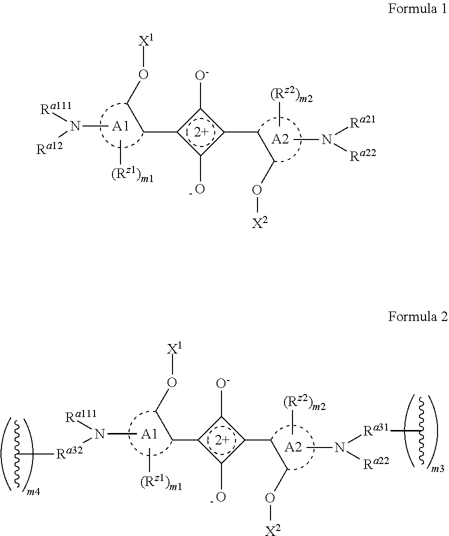

In Formula 1 and Formula 2, A1 and A2 each independently represent an aromatic ring structure which may have a fused ring, R and R^{z2} each independently represent a monovalent substituent, at least one of R^{z1}'s and at least one of R^{z2}'s may be bonded to each other to form a ring structure, m1 represents an integer of 0 to mA1, mA1 represents the maximum number of substituents in A1, m2 represents an integer of 0 to mA2, mA2 represents the maximum number of substituents in A2, R^{z1} may form a ring structure with any one of R^{a11} or R^{a12}, R^{z2} may form a ring structure with any one of R^{a21} or R^{a22}, X¹ and X² each independently represent a hydrogen atom or a substituent, X¹ and X² may be bonded to each other to form a ring structure, R^{a11}, R^{a12}, R^{a21}, and R^{a22} each independently represent an aromatic ring structure which may have a fused ring, R^{a31} and R^{a32} each independently represent an aromatic ring structure which may have a fused ring, or a linking group having an aromatic ring structure which may have a fused ring, m3 and m4 each independently represent 0 or 1, at least one of m3 or m4 is 1, at least one of R^{a11}, R^{a12}, R^{a21}, or R^{a22} in Formula 1 represents an aromatic ring structure represented by A1 or A2 and having a substituent at a position adjacent to an atom to which a nitrogen atom in Formula 1 is bonded, or an aromatic ring structure represented by A1 or A2 and having a fused ring at a position adjacent to the atom to which a nitrogen atom in Formula 1 is bonded, at least one of R^{a11}, R^{a22}, R^{a31}, or R^{a32} in Formula 2 represents an aromatic ring structure represented by A1 or A2 and having a substituent at a position adjacent to an atom to which a nitrogen atom in Formula 2 is bonded, or an aromatic ring structure represented by A1 or A2 and having a fused ring at a position adjacent to the atom to which a nitrogen atom in Formula 2 is bonded, and a wavy line portion represents a bonding position to another structure.

<6> The curable composition according to any one of <1> to <5>, in which at least one of A1 or A2 has a benzene ring structure.

<7> The curable composition according to any one of <1> to <6>, in which at least one of R^{a11}, R^{a12}, R^{a21}, or R^{a22} has a structure represented by Formula R-1.

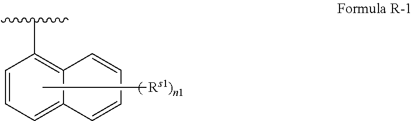

In Formula R-1, R^{s1}'s each independently represent a substituent, a plurality of R^{s1}'s may be bonded to each other to form a ring structure, n1 represents an integer of 0 to 7, and a wavy line portion represents a bonding site to a nitrogen atom in Formula 1.

<8> The curable composition according to any one of <1> to <7>, further comprising:

a photopolymerization initiator.

<9> A cured product obtained by curing the curable composition according to any one of <1> to <8>.

<10> A color filter comprising:

the cured product according to <9>.

<11> A method for producing a color filter, comprising:

a step of applying the curable composition according to any one of 1 to 8 onto a support to form a composition film;

a step of exposing the formed composition film to light in a pattern-wise manner; and

a step of developing the composition film after exposure to form a colored pattern.

<12> A method for producing a color filter, comprising:

a step of applying the curable composition according to any one of 1 to 8 onto a support and curing the applied curable composition to form a cured product;

a step of forming a photoresist layer on the cured product;

a step of exposing the photoresist layer to light in a pattern-wise manner and developing the exposed photoresist layer to form a resist pattern; and

a step of etching the cured product through the resist pattern.

<13> A solid-state imaging element comprising:

the color filter according to <10>.

<14> An image display device comprising:

the color filter according to <10>.

According to the embodiment of the present disclosure, there is provided a curable composition having excellent spectral characteristics of a cured product to be obtained.

In addition, an object to be achieved by another embodiment of the present disclosure is to provide a cured product having excellent spectral characteristics, a color filter comprising the cured product, a method for producing the color filter, and a solid-state imaging element or an image display device, each of which comprising the color filter.

### DESCRIPTION OF THE PREFERRED EMBODIMENTS

Hereinafter, the contents of the present disclosure will be described in detail. The description of constituent elements described below may be based on representative embodiments of the present disclosure, but the present disclosure is not limited to such embodiments.

In the present disclosure, a term “to” indicating a numerical range is used as a meaning including numerical values described before and after the term as a lower limit value and an upper limit value, respectively.

In a numerical range described in a stepwise manner in the present disclosure, an upper limit value or a lower limit value described in a certain numerical range may be replaced with an upper limit value or a lower limit value of another numerical range described in a stepwise manner. In addition, in the numerical range described in the present disclosure, the upper limit value or the lower limit value of the numerical range may be replaced with the values shown in the Examples.

Further, in the present disclosure, in a case where a plurality of substances corresponding to components are present in the composition, the amount of each component in the composition means a total amount of the plurality of substances present in the composition, unless otherwise specified.

Regarding a term, group (atomic group) in the present disclosure, a term with no description of “substituted” and “unsubstituted” includes both a group not having a substituent and a group having a substituent. For example, an “alkyl group” includes not only an alkyl group having no substituent (unsubstituted alkyl group), but also an alkyl group having a substituent (substituted alkyl group).

In the present disclosure, unless otherwise specified, “Me” represents a methyl group, “Et” represents an ethyl group, “Pr” represents a propyl group, “Bu” represents a butyl group, and “Ph” represents a phenyl group.

In the present disclosure, “(meth)acrylic” is a term used as a concept including both acrylic and methacrylic, and “(meth)acryloyl” is a term used as a concept including both acryloyl and methacryloyl.

In the present disclosure, a term “step” not only includes an independent step, but also includes a step, even in a case where the step may not be clearly distinguished from the other step, as long as the expected object of the step is achieved.

In the present disclosure, the term “total solid content” refers to a total mass of components excluding a solvent from the total composition of the composition. In addition, the “solid content” is a component excluding a solvent, as described above, and may be a solid or a liquid at 25° C., for example.

In addition, in the present disclosure, “% by mass” is identical to “% by weight” and “parts by mass” is identical to “parts by weight”.

Further, in the present disclosure, a combination of two or more preferred aspects is a more preferred aspect.

In addition, unless otherwise noted, a weight-average molecular weight (Mw) and a number-average molecular weight (Mn) in the present disclosure are molecular weights in terms of polystyrene as a standard substance, following the detection by a gel permeation chromatography (GPC) analyzer using columns of TSKgel GMHxL, TSKgel G4000HxL, and TSKgel G2000HxL (all of which are trade names manufactured by Tosoh Corporation), using tetrahydrofuran (THF) as a solvent and a differential refractometer.

Hereinafter, the present disclosure will be described in detail.

(Curable Composition)

A first aspect of the curable composition according to the present disclosure is a curable composition including a compound represented by Formula 1 and having a maximum absorption wavelength in a range of 600 nm or more and less than 700 nm, or a polymer having a structure represented by Formula 2 and having a maximum absorption wavelength in a range of 600 nm or more and less than 700 nm, a polymerizable compound, and a chromatic colorant different from the compound represented by Formula 1 and the polymer represented by Formula 2.

In addition, a second aspect of the curable composition according to the present disclosure is a curable composition used for producing a color filter, which includes a compound represented by Formula 1 and having a maximum absorption wavelength in a range of 600 nm or more and less than 700 nm, or a polymer having a structure represented by Formula 2 and having a maximum absorption wavelength in a range of 600 nm or more and less than 700 nm, and a polymerizable compound.

By using the curable composition according to the present disclosure, a cured product having excellent spectral characteristics of the cured product to be obtained is obtained.

As described above, it is known that a squarylium compound having a triarylamine structure and an oxygen atom at the ortho-position of the bonding site of a squaric acid in the aromatic ring structure bonding to the squaric acid has a small shoulder absorption on the short wavelength side, but there is a case where spectral characteristics are insufficient in a case where the spectral characteristics are improved by the above-mentioned structure.

Therefore, as a result of extensive studies, the present inventors have found that the spectral characteristics can be further improved by using a compound represented by Formula 1 and having a maximum absorption wavelength in a range of 600 nm or more and less than 700 nm, or a polymer having a structure represented by Formula 2 and having a maximum absorption wavelength in a range of 600 nm or more and less than 700 nm (hereinafter, the compound and the polymer are collectively referred to as “specific compound”) in the curable composition.

Although the reason why the above effect is obtained is unknown, it is considered that the absorption wavelength peak width is narrowed by having a triarylamine structure and an oxygen atom at the ortho-position with respect to the bonding site of a squaric acid in the aromatic ring structure that bonds to the squaric acid, and by having a substituent or a fused ring structure at a position adjacent to an atom to which a nitrogen atom is bonded in an aromatic ring structure other than the above aromatic ring structure in the triarylamine structure.

In the present disclosure, the “position adjacent to an atom to which a nitrogen atom is bonded” refers to an atom which is a ring member of an aromatic ring structure, and which, in a case where the atom to which a nitrogen atom is bonded is atom A, is a ring member of the same aromatic ring structure as the aromatic ring structure containing the atom A and is adjacent to the atom A.

Tn the first aspect, it is speculated that a specific compound is used in combination with a chromatic colorant other than the specific compound to thereby absorb light in a specific wavelength range, and the width of the absorption peak at the end of the above wavelength range is narrow, whereby a cured product having excellent spectral characteristics can be obtained.

Furthermore, as a result of extensive studies, the present inventors have found that, according to the first aspect, the obtained cured product is likely to have excellent light resistance. This is presumably because light absorption of the chromatic colorant other than the specific compound suppresses the decomposition of the specific compound by light.

In the second aspect, it is speculated that, in a case where a color filter is produced, the overlap of transmission wavelengths with pixels of other colors in the color filter is reduced.

The overlap of transmission wavelengths means that light in a certain wavelength range transmits through, for example, both a green element and a red element, and the small overlap (small wavelength range) is very important as a characteristic of the color filter.

For example, in a case where the color filter is used for a solid-state imaging element, it is considered that a smaller overlap leads to better image recognition ability and color reproducibility.

In particular, the curable composition according to the present disclosure is suitably used for producing a green element, but in a case where a green element including a cured product of the curable composition according to the present disclosure is used, it is considered that the overlap of the transmission wavelengths with the red element (G/R overlap) is reduced.

Hereinafter, details of each component included in the curable composition according to the present disclosure will be described. In the first aspect and second aspect, the overlapping components are the same, and the preferred aspects thereof are also the same.

<Specific Compound>

The specific compound used in the present disclosure is a compound represented by Formula 1 and having a maximum absorption wavelength in a range of 600 nm or more and less than 700 nm, or a polymer having a structure represented by Formula 2 and having a maximum absorption wavelength in a range of 600 nm or more and less than 700 nm.

In addition, the specific compound is preferably a colorant and more preferably a pigment.

In the present disclosure, the pigment means a coloring agent compound that is insoluble in a solvent. In addition, the dye refers to a coloring agent compound that is soluble in a solvent.

For example, the pigment used in the present disclosure preferably has a solubility in 100 g of propylene glycol monomethyl ether acetate at 25° C. and a solubility in 100 g of water at 25° C. of both 0.1 g or less, more preferably 0.05 g or less, and still more preferably 0.01 g or less. In addition, the dye used in the present disclosure has at least one of a solubility in 100 g of propylene glycol monomethyl ether acetate at 25° C. or a solubility in 100 g of water at 25° C. of preferably more than 0.1 g, more preferably 1 g or more, and still more preferably 5 g or more.

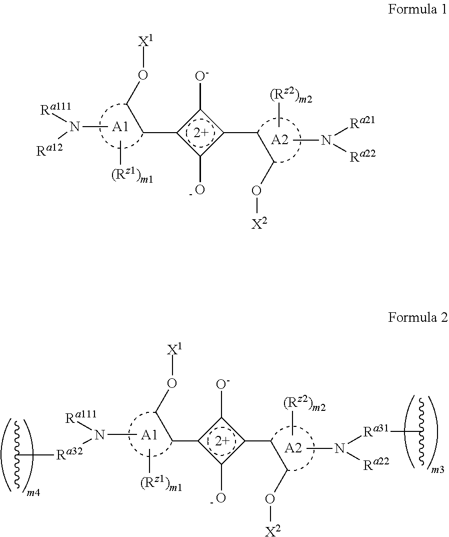

In Formula 1 and Formula 2, A1 and A2 each independently represent an aromatic ring structure which may have a fused ring, R and R^{z2} each independently represent a monovalent substituent, at least one of R^{z1}'s and at least one of R^{z2}'s may be bonded to each other to form a ring structure, m1 represents an integer of 0 to mA1, mA1 represents the maximum number of substituents in A1, m2 represents an integer of 0 to mA2, mA2 represents the maximum number of substituents in A2, R^{z1} may form a ring structure with any one of R^{a11} or R^{a12}, R^{z2} may form a ring structure with any one of R^{a21} or R^{a22}, X¹ and X² each independently represent a hydrogen atom or a substituent, X¹ and X² may be bonded to each other to form a ring structure, R^{a11}, R^{a12}, R^{a21} and R^{a22} each independently represent an aromatic ring structure which may have a fused ring, R^{a31} and R^{a32} each independently represent an aromatic ring structure which may have a fused ring, or a linking group having an aromatic ring structure which may have a fused ring, m3 and m4 each independently represent 0 or 1, at least one of m3 or m4 is 1, at least one of R^{a11}, R^{a12}, R^{a21}, or R^{a22} in Formula 1 represents an aromatic ring structure represented by A1 or A2 and having a substituent at a position adjacent to an atom to which a nitrogen atom in Formula 1 is bonded, or an aromatic ring structure represented by A1 or A2 and having a fused ring at a position adjacent to the atom to which a nitrogen atom in Formula 1 is bonded, at least one of R^{a11}, R^{a22}, R^{a31}, or R^{a32} in Formula 2 represents an aromatic ring structure represented by A1 or A2 and having a substituent at a position adjacent to an atom to which a nitrogen atom in Formula 2 is bonded, or an aromatic ring structure represented by A1 or A2 and having a fused ring at a position adjacent to the atom to which a nitrogen atom in Formula 2 is bonded, and a wavy line portion represents a bonding position to another structure.

In the compound represented by Formula 1, the cation is delocalized and present as shown in the following formula. That is, the compound represented by Formula 1 is a compound which is equivalent to a compound represented by Formula 1-1 or a compound represented by Formula 1-2.

In addition, the same applies to Formula 2.

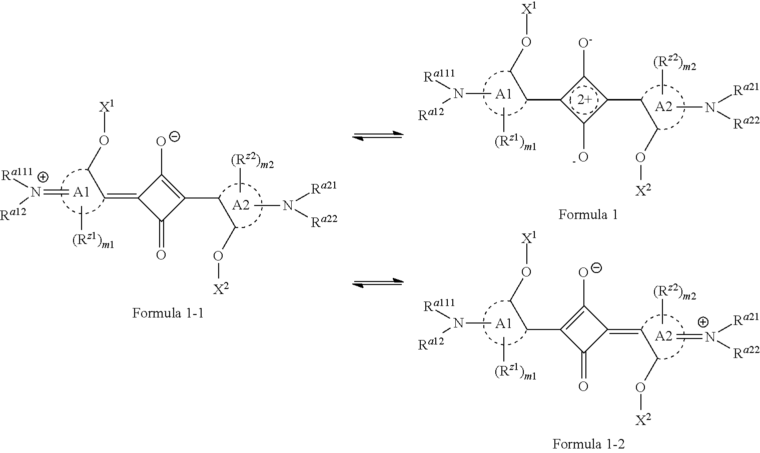

[A1 and A2]

In Formula 1, A1 and A2 each independently represent an aromatic ring structure which may have a fused ring, preferably an aromatic ring structure having 4 to 10 carbon atoms, more preferably an aromatic hydrocarbon ring structure having 6 to 10 carbon atoms, and still more preferably a benzene ring structure.

In addition, it is preferable that at least one of A1 or A2 has a benzene ring structure, and it is more preferable that both A1 and A2 have a benzene ring structure.

In a case where A1 and A2 are each an aromatic heterocyclic structure, the aromatic heterocyclic structure is preferably an aromatic heterocyclic structure having 4 to 5 carbon atoms and containing a sulfur atom, a nitrogen atom or an oxygen atom as a ring member, among which a thiophene ring structure or a pyrrole ring structure is preferable. The nitrogen atom of the pyrrole ring structure may be substituted with an alkyl group having 1 to 12 carbon atoms or the like.

[R^{z1} and R^{z2}]

In Formula 1, R and R^{z2} each independently represent a monovalent substituent, preferably an alkyl group, a hydroxy group, an alkoxy group, an aryl group, a fluoro group, or a chloro group, and more preferably an alkyl group, a hydroxy group, or an alkoxy group. The number of carbon atoms in the alkyl group is preferably 1 to 12, the number of carbon atoms in the alkoxy group is preferably 1 to 12, and the number of carbon atoms in the aryl group is preferably 4 to 10.

In Formula 1, at least one of R^{z1}'s and at least one of R^{z2}'s may be bonded to each other to form a ring structure, and examples of the ring structure to be formed include an aliphatic hydrocarbon ring structure and a heterocyclic structure.

In Formula 1, m1 represents an integer of 0 to mA1, and from the viewpoint that A1 is preferably a benzene ring structure, m1 is preferably an integer of 0 to 4, more preferably an integer of 0 to 2, and still more preferably 0 or 1.

In Formula 1, m2 represents an integer of 0 to mA1, and from the viewpoint that A2 is preferably a benzene ring structure, m2 is preferably an integer of 0 to 4, more preferably an integer of 0 to 2, and still more preferably 0 or 1.

In Formula 1, R^{z} may form a ring structure with any one of R^{a11} or R^{a12}, and the ring structure to be formed may be, for example, a 5-membered ring structure or 6-membered ring structure containing a nitrogen atom in Formula 1 as a ring member and preferably a pyrrolidine ring structure containing a nitrogen atom in Formula 1 as a ring member.

In Formula 1, R^{z2} may form a ring structure with any one of R^{a21} or R^{a22}, and the ring structure to be formed may be, for example, a 5-membered ring structure or 6-membered ring structure containing a nitrogen atom in Formula 1 as a ring member and preferably a pyrrolidine ring structure containing a nitrogen atom in Formula 1 as a ring member.

[X¹ and X²]

In Formula 1, X¹ and X² each independently represent a hydrogen atom or a substituent, preferably a hydrogen atom or an alkyl group, and more preferably a hydrogen atom.

In addition, X¹ and X² may be each independently bonded to an oxygen atom in Formula 1 to form an alkyl ester structure, an alkyl ether structure, or a carbamate structure, and the alkyl ester structure, the alkyl ether structure, or the carbamate structure may be bonded to each other to form a ring.

[R^{a11}, R^{a12}, R^{a21}, R^{a22}, R^{a31}, and R^{a32}]

R^{a11}, R^{a12}, R^{a21}, and R^{a22} each independently represent an aromatic ring structure which may have a fused ring, R^{a31} and R^{a32} each independently represent an aromatic ring structure which may have a fused ring, or a linking group having an aromatic ring structure which may have a fused ring, at least one of R^{a11}, R^{a12}, R^{a21}, or R^{a22} represents an aromatic ring structure having a substituent at a position adjacent to an atom to which a nitrogen atom in Formula 1 is bonded, or an aromatic ring structure having a fused ring at a position adjacent to the atom to which a nitrogen atom in Formula 1 is bonded, and at least one of R^{a11}, R^{a22}, R^{a31} or R^{a32} in Formula 2 represents an aromatic ring structure represented by A1 or A2 and having a substituent at a position adjacent to an atom to which a nitrogen atom in Formula 2 is bonded, or an aromatic ring structure represented by A1 or A2 and having a fused ring at a position adjacent to the atom to which a nitrogen atom in Formula 2 is bonded.

The aromatic ring structure which may have a fused ring is preferably a monovalent group.

The linking group having an aromatic ring structure which may have a fused ring in R^{a31} and R^{a32} is preferably a group obtained by removing one hydrogen atom from the above aromatic ring structure which may have a fused ring. In addition, in a case where m3 is 1 or m4 is 1, the corresponding R^{a31} and R^{a32} serve as the linking group.

In addition, the portion of the linking group other than the aromatic ring structure which may have a fused ring is not particularly limited, but is preferably a divalent linking group. Suitable examples of the divalent linking group include an alkylene group having 1 to 30 carbon atoms, an arylene group having 6 to 30 carbon atoms, a heterocyclic linking group, —CH═CH—, —O—, —S—, —C(═O)—, —CO₂—, —NR—, —CONR—, —O₂C—, —SO—, —SO₂—, and a linking group formed by linking two or more thereof.

In addition, the bond at a bonding position to another structure in the wavy line portion includes not only a covalent bond but also an ionic bond or a coordinate bond. That is, the wavy line portion side of the linking group in R^{a31} and R^{a32} may be an anionic group, a cationic group, or a structure having an unshared electron pair.

In addition, the aromatic ring structure having a substituent at a position adjacent to an atom to which a nitrogen atom in Formula 1 or Formula 2 is bonded may have a substituent at at least one of positions adjacent to the atom to which the nitrogen atom in Formula 1 or Formula 2 on the aromatic ring structure is bonded; or may have a substituent at both of two adjacent positions; or may have a substituent at one of the adjacent positions and may have a fused ring at one of the adjacent positions.

R^{a11} and R^{a12} in Formula 1 may be bonded to each other to form a ring structure, but preferably do not form a ring structure.

R^{a21} and R^{a22} in Formula 1 may be bonded to each other to form a ring structure, but preferably do not form a ring structure.

R^{a11} and R^{a31} in Formula 2 may be bonded to each other to form a ring structure, but preferably do not form a ring structure.

R^{a22} and R^{a32} in Formula 2 may be bonded to each other to form a ring structure, but preferably do not form a ring structure.

Further, the aromatic ring structure having a fused ring at the above-mentioned adjacent position of the nitrogen atom in Formula 1 or Formula 2 may have a fused ring at least one of the above-mentioned adjacent positions of the nitrogen atom in Formula 1 or Formula 2 on the aromatic ring structure, or may have a fused ring at both of two adjacent positions.

—Aromatic Ring Structure Having Substituent at Adjacent Position—

In the present disclosure, R^{a11}, R^{a12}, R^{a21}, R^{a22}, R^{a31}, or R^{a32} being an aromatic ring structure having a substituent at a position adjacent to an atom to which a nitrogen atom in Formula 1 or Formula 2 is bonded means that, for example, R^{a11}, R^{a12}, R^{a21}, or R^{a22} is a structure represented by Formula A.

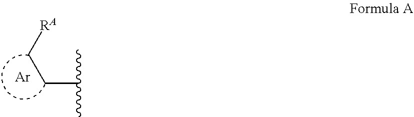

In Formula A, Ar represents an aromatic ring structure, R^{A} represents a substituent at a position adjacent to an atom to which a nitrogen atom in Formula 1 or Formula 2 in Ar is bonded, and a wavy line portion represents a bonding site to a nitrogen atom in Formula 1 or Formula 2.

In Formula A, Ar may have a substituent other than R^{A} or may have a fused ring.

The aromatic ring structure having a substituent at the adjacent position (for example, Ar in Formula A) is preferably an aromatic ring structure having 4 to 20 carbon atoms, more preferably an aromatic hydrocarbon ring structure having 6 to 20 carbon atoms, and still more preferably a benzene ring structure.

In a case where the aromatic ring structure having a substituent at the adjacent position is an aromatic heterocyclic structure, the aromatic heterocyclic structure is preferably an aromatic heterocyclic structure having 4 to 10 carbon atoms and containing a sulfur atom, a nitrogen atom or an oxygen atom as a ring member, among which a thiophene ring structure, a furan ring structure, or a pyrrole ring structure is preferable.

In addition, the aromatic ring structure having a substituent at the adjacent position may have a substituent at at least one of two adjacent positions, and may have a substituent at both of two adjacent positions. In addition, the aromatic ring structure may further have a substituent at a position other than the adjacent position.

The substituent (for example, R^{A} in Formula A) in the adjacent position may be any substituent larger than a hydrogen atom and is preferably an alkyl group, an aryl group, an alkoxy group, an amino group, a sulfide group, an acyl group, a trifluoromethyl group, a chloro group, a nitro group, a cyano group, or an amide group and more preferably an alkyl group, an aryl group, or a chloro group. The number of carbon atoms in the alkyl group is preferably 1 to 12. The number of carbon atoms in the aryl group is preferably 4 to 10. The number of carbon atoms in the alkoxy group is preferably 1 to 12. The number of carbon atoms in the acyl group is preferably 1 to 12.

The substituent in a position other than the adjacent position is preferably, for example, a substituent in the ortho-position, and a preferred aspect is also the same.

—Aromatic Ring Structure Having Fused Ring at Adjacent Position—

In the present disclosure, R^{a11}, R^{a12}, R^{a21}, R^{a22}, R^{a31}, or R^{a32} being an aromatic ring structure having a fused ring at a position adjacent to an atom to which a nitrogen atom in Formula 1 or Formula 2 is bonded means that, for example, R^{a11}, R^{a12}, R^{a21}, or R^{a22} is a structure represented by Formula B.

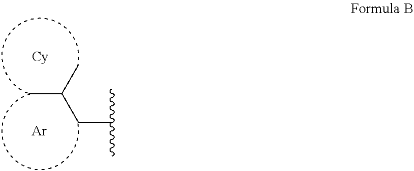

In Formula B, Ar represents an aromatic ring structure, Cy represents a fused ring at a position adjacent to an atom to which a nitrogen atom in Formula 1 or Formula 2 in Ar is bonded, and a wavy line portion represents a bonding site to a nitrogen atom in Formula 1 or Formula 2.

In Formula B, Ar and Cy may have a substituent or may further have a fused ring.

The aromatic ring structure having a fused ring at the adjacent position (for example, Ar in Formula B) is preferably an aromatic ring structure having 6 to 20 carbon atoms and more preferably a benzene ring structure.

In a case where the aromatic ring structure having a fused ring at the adjacent position is an aromatic heterocyclic structure, the aromatic heterocyclic structure is preferably an aromatic heterocyclic structure having 4 to 8 carbon atoms and containing a sulfur atom, a nitrogen atom or an oxygen atom as a ring member, among which a thiophene ring structure, a furan ring structure, or a pyrrole ring structure is preferable.

In the present disclosure, having a fused ring at the adjacent position means that a fused ring containing at least a carbon atom on an aromatic ring structure located at the position adjacent to an atom to which a nitrogen atom is bonded is formed.

The fused ring (for example, Cy in Formula B) in the aromatic ring structure having a fused ring at a position adjacent to an atom to which a nitrogen atom in R^{a11}, R^{a12}, R^{a21}, R^{a22}, R^{a31}, and R^{a32} is bonded is preferably an aromatic hydrocarbon ring, more preferably an aromatic hydrocarbon ring having 6 to 20 carbon atoms, and still more preferably a benzene ring.

At least one of R^{a11}, R^{a12}, R^{a21}, R^{a22}, R^{a31}, or R^{a32} is preferably a structure represented by Formula R-1.

The structure represented by Formula R-1 is an aromatic ring structure (benzene ring structure) having a fused ring (benzene ring) at a position adjacent to an atom to which a nitrogen atom is bonded.

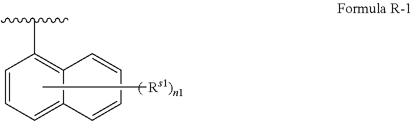

In Formula R-1, R^{s1}'s each independently represent a substituent, a plurality of R^{s1}'s may be bonded to each other to form a ring structure, n1 represents an integer of 0 to 7, and a wavy line portion represents a bonding site to a nitrogen atom in Formula 1.

In Formula R-1, R^{s1}'s each independently represent a substituent, and the substituent is preferably an alkyl group having 1 to 12 carbon atoms, an aryl group having 4 to 10 carbon atoms, or a halogen atom.

In Formula R-1, n1 represents an integer of 0 to 7, preferably an integer of 0 to 2, and more preferably 0 or 1.

—Aromatic Ring Structure Having Neither Substituent Nor Fused Ring at Adjacent Position—

At least one of R^{a11}, R^{a12}, R^{a21}, or R^{a22} in Formula 1 may represent an aromatic ring structure having a substituent at a position adjacent to an atom to which a nitrogen atom in Formula 1 is bonded, or an aromatic ring structure having a fused ring at a position adjacent to the atom to which a nitrogen atom in Formula 1 is bonded, and any of R^{a11}, R^{a12}, R^{a21}, and R^{a22} may be an aromatic ring structure having neither a substituent nor a fused ring at the adjacent position.

At least one of R^{a11}, R^{a22}, R^{a31}, or R^{a32} in Formula 2 may represent an aromatic ring structure having a substituent at a position adjacent to an atom to which a nitrogen atom in Formula 2 is bonded, or an aromatic ring structure having a fused ring at a position adjacent to the atom to which a nitrogen atom in Formula 2 is bonded, and any of R^{a11}, R^{a22}, R^{a31}, and R^{a32} may be an aromatic ring structure having neither a substituent nor a fused ring at the adjacent position.

Examples of the aromatic ring structure having neither a substituent nor a fused ring at the adjacent position include an unsubstituted aromatic ring structure, an aromatic ring structure having no substituent at the adjacent position and having a substituent at a position other than the adjacent position, and an aromatic ring structure having no fused ring at the adjacent position and having a fused ring at a position other than the adjacent position.

The aromatic ring structure having neither a substituent nor a fused ring at the adjacent position is preferably an aromatic ring structure having 4 to 20 carbon atoms, more preferably an aromatic hydrocarbon ring structure having 6 to 20 carbon atoms, and still more preferably a benzene ring structure.

In a case where the aromatic ring structure having neither a substituent nor a fused ring at the adjacent position is an aromatic heterocyclic structure, the aromatic heterocyclic structure is preferably an aromatic heterocyclic structure having 4 to 8 carbon atoms and containing a sulfur atom, a nitrogen atom or an oxygen atom as a ring member, among which a thiophene ring structure, a furan ring structure, or a pyrrole ring structure is preferable. Examples of the substituent in the aromatic ring structure having a substituent at a position other than the adjacent position include an alkyl group having 1 to 12 carbon atoms, an aryl group having 4 to 10 carbon atoms, and a halogen atom.

The fused ring in the aromatic ring structure having a fused ring at a position other than the adjacent position is preferably an aromatic ring structure having 4 to 20 carbon atoms, more preferably an aromatic hydrocarbon ring structure having 6 to 20 carbon atoms, and still more preferably a benzene ring structure.

In the entire specific compound, a total number of substituents at a position adjacent to an atom to which a nitrogen atom in Formula 1 or Formula 2 included in R^{a11}, R^{a12}, R^{a21}, R^{a22}, R^{a31}, and R^{a32} is bonded, and fused rings at a position adjacent to an atom to which a nitrogen atom in Formula 1 or Formula 2 is bonded is preferably 1 or more and more preferably 2 or more. The upper limit of the total number of substituents and fused rings is preferably 8 or less and more preferably 4 or less.

A preferred number of 7-plane carbon atoms forming an aromatic ring in the entire specific compound is preferably 36 atoms or more (six benzene rings), more preferably 40 atoms or more (five benzene rings and one naphthyl ring), and still more preferably 44 atoms or more (4 benzene rings and 2 naphthyl rings).

—Polymer Having Structure Represented by Formula 2 and Having Maximum Absorption Wavelength in Range of 600 nm or More and Less than 700 nm—

The polymer having a structure represented by Formula 2 and having a maximum absorption wavelength in a range of 600 nm or more and less than 700 nm may be a polymer or an oligomer.

The polymer may have only one structure represented by Formula 2 or may have two or more structures represented by Formula 2, but preferably has a structural unit having the structure represented by Formula 2.

In addition, the polymer may have only one type of the structure represented by Formula 2, or may have two or more types of the structures represented by Formula 2. The structure represented by Formula 2 in the polymer is bonded to a polymer chain at a wavy line portion in Formula 2. For example, in a case where only one of m3 and m4 is 1, the polymer is a polymer having the structure represented by Formula 2 in a side chain thereof, and in a case where both of m3 and m4 are 1, the polymer is a polymer having the structure represented by Formula 2 in a main chain or side chain thereof.

In the present disclosure, the term “main chain” refers to a relatively longest binding chain in the molecule of a polymer compound that constitutes a resin, and the term “side chain” refers to an atomic group branched from the main chain.

In the present disclosure, the polymer is preferably a polymer having a structural unit represented by Formula (A) which will be described later (also referred to as a polymer (A)), a polymer having a structural unit represented by Formula (B) which will be described later (also referred to as a polymer (B)), a polymer having a structural unit represented by Formula (C) which will be described later (also referred to as a polymer (C)), or a polymer represented by Formula (D) (also referred to as a polymer (D)). The polymer is more preferably the polymer (A), the polymer (C), or the polymer (D), and the polymer is particularly preferably the polymer (A) or the polymer (D) from the viewpoint that a cured film having excellent reliability is easily obtained. Hereinafter, the polymers (A) to (D) will be described in detail.

### <<Polymer (A)>>

The polymer (A) contains a structural unit represented by Formula (A). In the polymer (A), the content of the structural unit represented by Formula (A) is preferably 10% by mass to 100% by mass with respect to the total mass of the polymer (A). The lower limit of the content of the structural unit represented by Formula (A) is more preferably 20% by mass or more, still more preferably 30% by mass or more, and particularly preferably 50% by mass or more. The upper limit of the content of the structural unit represented by Formula (A) is more preferably 95% by mass or less.

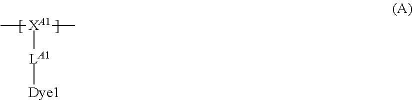

In Formula (A). X^{A1} represents a linking group which is formed by polymerization, and L^{A1} represents a single bond or a divalent linking group. Dye1 represents a group having the structure represented by Formula 2.

In Formula (A), X^{A1} represents a linking group which is formed by polymerization. That is, X^{A1} represents the main chain of the structural unit. X^{A1} is not limited as long as it is a linking group which is formed from a known polymerizable monomer. Examples of such a linking group include linking groups represented by (XX-1) to (XX-30) below, among which linking groups represented by (XX-1) to (XX-24) below are preferable; a linking group represented by (XX-1), (XX-2), (XX-10) to (XX-17), (XX-18), (XX-19), or (XX-24) is more preferable; a linking group represented by (XX-1), (XX-2), (XX-10) to (XX-17), or (XX-24) is still more preferable; and a linking group represented by (XX-1), (XX-2), or (XX-11) is particularly preferable.

In the formula, it indicates that it is linked to L^{A1} at the site indicated by *. Me represents a methyl group. In addition, R in (XX-18) and (XX-19) represents a hydrogen atom, an alkyl group having 1 to 5 carbon atoms, or a phenyl group.

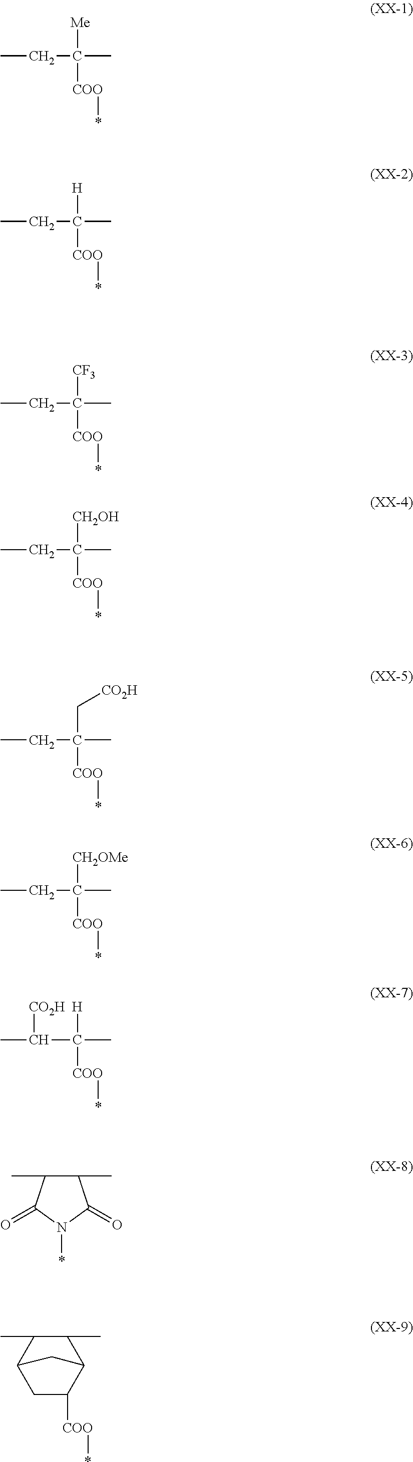

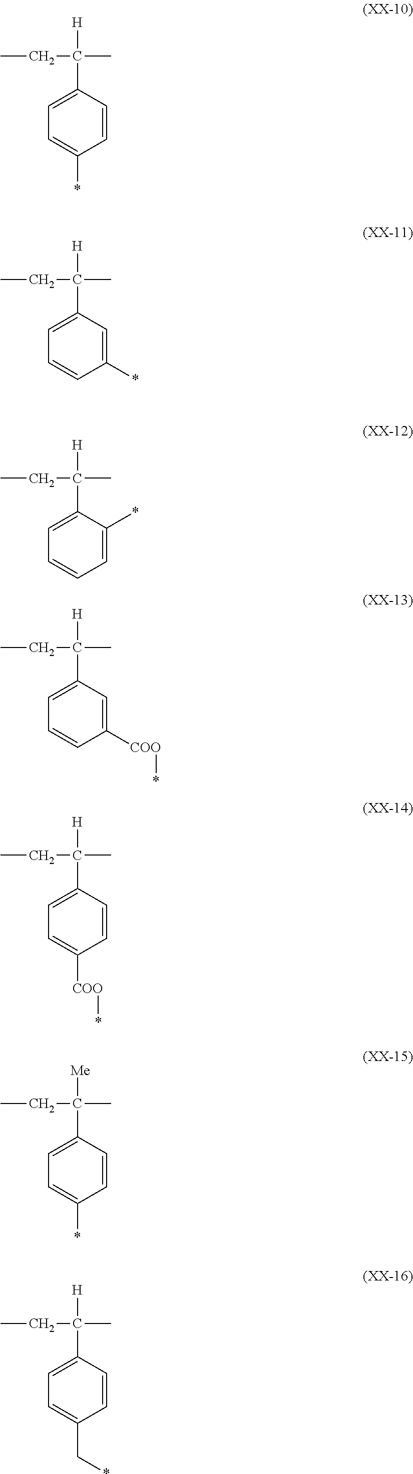

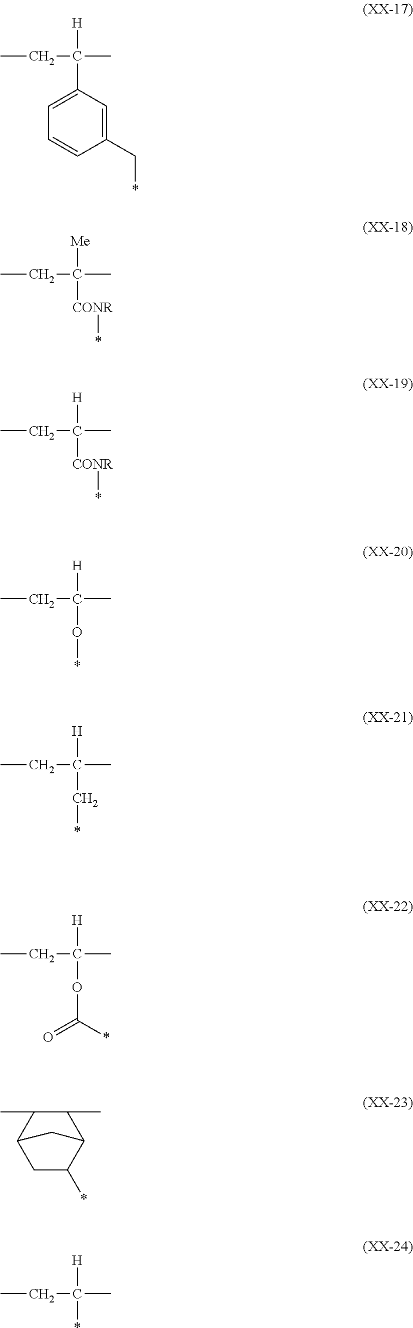

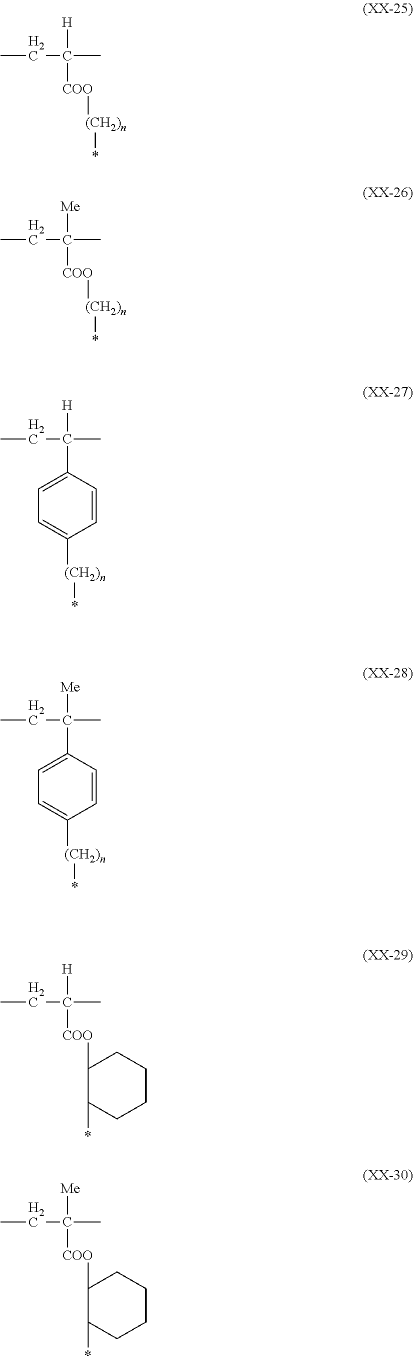

Examples of the divalent linking group in L^{A1} include an alkylene group having 1 to 30 carbon atoms, an arylene group having 6 to 30 carbon atoms, a heterocyclic linking group, —CH═CH—, —O—, —S—, —C(═O)—, —CO₂—, —NR—, —CONR—, —O₂C—, —SO—, —SO₂— and a linking group formed by linking two or more thereof, and a group represented by Formula (L-1). Here, R represents a hydrogen atom, an alkyl group, an aryl group, or a heterocyclic group.

The polymer containing the structural unit represented by Formula (A) can be synthesized by (1) a method of synthesizing a monomer having the structure represented by Formula (2) by addition polymerization, or (2) a method of reacting a polymer having a highly reactive functional group, such as an isocyanate group, an acid anhydride group or an epoxy group, with a compound having a functional group (a hydroxy group, a primary or secondary amino group, a carboxy group, or the like) capable of reacting with a highly reactive group and structure represented by Formula (2) and a structure represented by Formula (2).

Known addition polymerization (radical polymerization, anionic polymerization, or cationic polymerization) can be applied to the addition polymerization. Above all, the synthesis by radical polymerization is particularly preferable because the reaction conditions can be moderated. Known reaction conditions can be applied to the radical polymerization.

From the viewpoint of heat resistance, the polymer having the structural unit represented by Formula (A) is preferably a radical polymer obtained by radical polymerization using a coloring agent monomer having an ethylenically unsaturated bond.

<<<Other Structural Units>>>

The polymer according to the present disclosure may include other structural units in addition to the structural unit represented by Formula (A). Other structural units may contain a functional group such as a polymerizable group or an acid group. Other structural units may not contain a functional group. The polymer preferably has one or more selected from a structural unit having an acid group and a structural unit having a polymerizable group, and more preferably contain a structural unit having an acid group.

Examples of the polymerizable group include a vinyl group, a (meth)allyl group, a (meth)acrylamide group, and a (meth)acryloyloxy group. Among them, a (meth)acrylamide group or a (meth)acryloyloxy group is preferable.

The content of the structural unit having a polymerizable group is preferably more than 0% by mass and 50% by mass or less with respect to the total mass of the polymer. The lower limit of the content of the structural unit having a polymerizable group is more preferably 1% by mass or more and still more preferably 3% by mass or more. The upper limit of the content of the structural unit having a polymerizable group is more preferably 35% by mass or less and still more preferably 30% by mass or less.

Examples of the acid group include a carboxy group, a sulfonic acid group, and a phosphoric acid group. Only one type of acid group may be contained, or two or more types of acid groups may be contained.

The content of the structural unit having an acid group is preferably 0% by mass to 50% by mass with respect to the total mass of the polymer. The lower limit of the content of the structural unit having an acid group is more preferably 1% by mass or more and still more preferably 3% by mass or more. The upper limit of the content of the structural unit having an acid group is more preferably 35% by mass or less and still more preferably 30% by mass or less.

Examples of other functional groups include a group consisting of repeating 2 to 20 unsubstituted alkyleneoxy chains, a development promoting group such as a lactone, an acid anhydride, an amide, or a cyano group, and a hydrophobicity-adjusting group such as a long-chain or cyclic alkyl group, an aralkyl group, an aryl group, a polyalkylene oxide group, a hydroxyl group, a maleimide group, or an amino group, which can be appropriately introduced.

In the group consisting of repeating 2 to 20 unsubstituted alkyleneoxy chains, the number of repeating alkyleneoxy chains is preferably 2 to 10, more preferably 2 to 15, and still more preferably 2 to 10. One alkyleneoxy chain is represented by —(CH₂)ₙO—, n represents an integer, and n is preferably 1 to 10, more preferably 1 to 5, and still more preferably 2 or 3.

Specific examples of other structural units will be described, but the present disclosure is not limited thereto. Here, Me represents a methyl group, and Et represents an ethyl group.

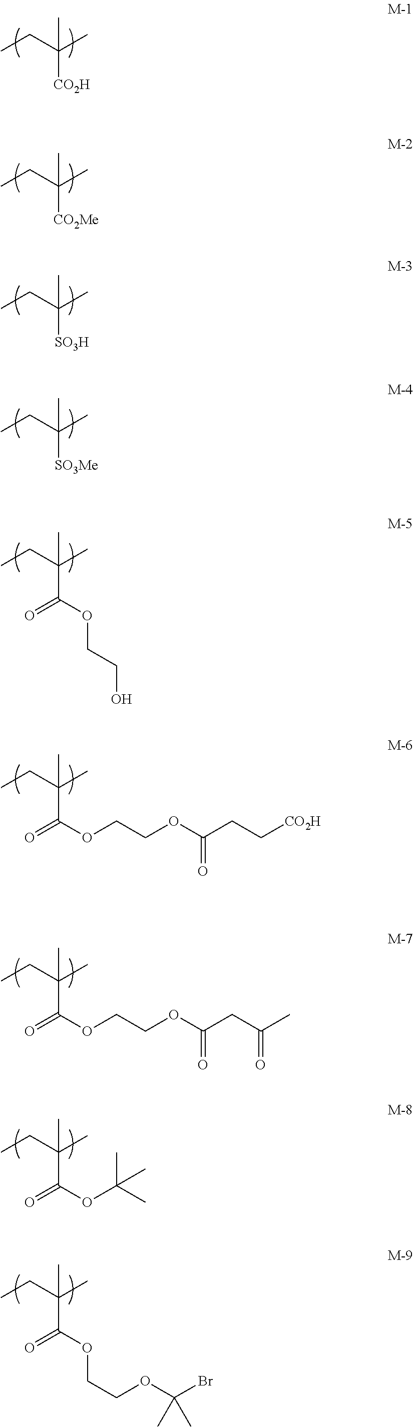

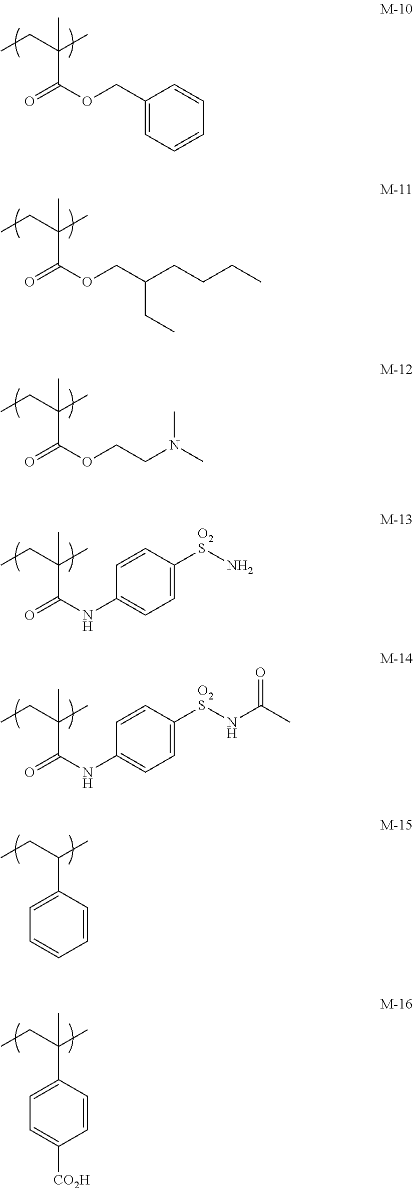

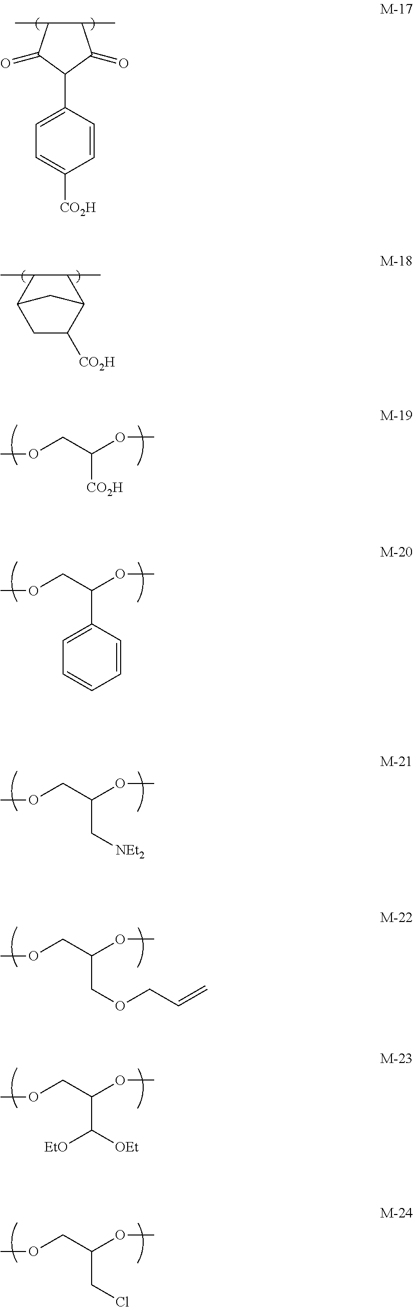

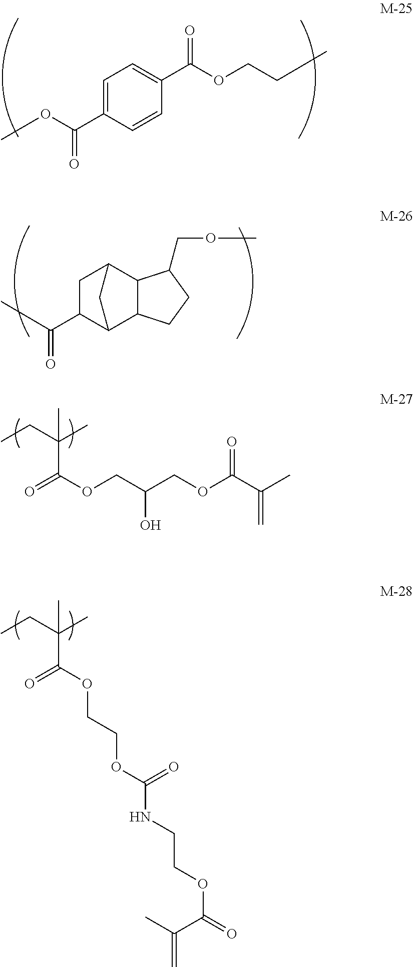

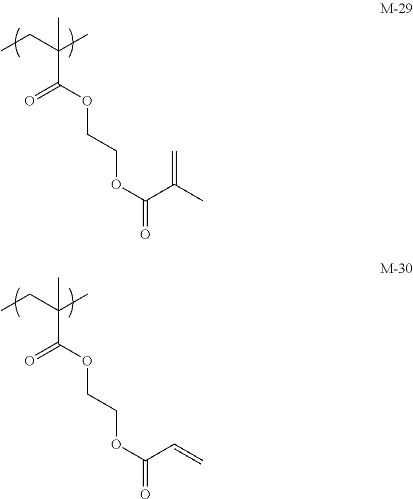

<<Polymer (B)>>

The polymer (B) contains a cation having the structure represented by Formula 2 and a structural unit represented by Formula (B).

In the polymer (B), the content of the structural unit represented by Formula (B) is preferably 10% by mass to 100% by mass with respect to the total mass of the polymer. The lower limit of the content of the structural unit represented by Formula (B) is more preferably 20% by mass or more, still more preferably 30% by mass or more, and particularly preferably 50% by mass or more. The upper limit of the content of the structural unit represented by Formula (B) is more preferably 95% by mass or less.

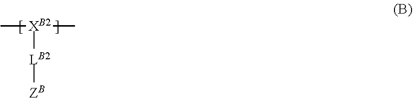

In Formula (B), X represents a linking group which is formed by polymerization, L^{B2} represents a single bond or a divalent linking group, and Z^{B} represents an anion or a cation.

XB² has the same definition as X^{A1} in Formula (A), and a preferred range thereof is also the same.

LB² represents a single bond or a divalent linking group. The divalent linking group may be, for example, a hydrocarbon group, —NH—, —CO—, —COO—, and a divalent group containing a coloring agent skeleton, examples thereof include an alkylene group having 1 to 20 carbon atoms, an arylene group having 6 to 20 carbon atoms, a heterocyclic group having 4 to 20 carbon atoms, an alkylsulfonyl group having 1 to 20 carbon atoms, an arylsulfonyl group having 6 to 20 carbon atoms, an alkylcarbonyl group having 1 to 20 carbon atoms, an arylcarbonyl group having 6 to 20 carbon atoms, an alkylamino group having 1 to 20 carbon atoms, an arylamino group having 6 to 20 carbon atoms, an alkylcarbonyloxy group having 1 to 2 carbon atoms, and an arylcarbonyloxy group having 6 to 20 carbon atoms. These divalent linking groups are preferably substituted with an electron-withdrawing group. Examples of the electron-withdrawing group include a halogen atom (a fluorine atom, a chlorine atom, a bromine atom, or an iodine atom), a nitro group, a cyano group, a halogenated alkyl group (for example, a trifluoromethyl group), and a halogenated aryl group.

Z^{B} represents an anion or a cation, and is preferably an anion.

The anion is not particularly limited, and examples thereof include —SO₃—, —COO—, —PO₄—, a bis(sulfonyl)imide anion, a tris(sulfonyl)methide anion, and a tetraarylborate anion. In addition, an anion represented by Formula (Z-1), an anion represented by Formula (Z-2), and an anion represented by Formula (Z-3) are also preferable. In addition, the anion may be a monovalent anion or a polyvalent anion, but is preferably a monovalent anion.

The cation is not particularly limited, but is preferably a primary to quaternary ammonium cation. In addition, the cation may be a monovalent cation or a polyvalent cation, but is preferably a monovalent cation.

Z^{B} is preferably an anion represented by Formulae (Z-1) to (Z-3), and particularly preferably a group represented by Formula (2-1), a fluorinated alkylsulfonimide group (in Formula (2-2), Y² represents a nitrogen atom and A² represents a fluorinated alkylsulfonyl group), or a fluorinated alkylsulfonemethide group (in Formula (2-2), Y² represents a carbon atom and A² represents a fluorinated alkylsulfonyl group).

*—Y¹-A¹ Formula (Z-1)

In Formula (Z-1), * represents a bonding site to LB² in Formula (B), Y¹ represents a fluorinated alkylene group, and A¹ represents SO₃—.

In Formula (Z-1), Y¹ represents a fluorinated alkylene group. The number of carbon atoms in the fluorinated alkylene group is preferably 1 to 20, more preferably 1 to 10, and still more preferably 1 to 6. In addition, a perfluoroalkylene group is more preferable.

*—Y²-(A²)ₙ Formula (Z-2)

In Formula (Z-2), * represents a bonding site to L^{B2} in Formula (B).

Y² represents an anion consisting of a boron atom, a carbon atom, a nitrogen atom, or a phosphorus atom.

In a case where Y² is a boron atom, n is 3, and A² is preferably an alkyl group having at least one group selected from the group consisting of a halogen atom, a cyano group, a fluorine atom and a cyano group, or an aryl group having at least one group selected from the group consisting of a fluorine atom and a cyano group.

In a case where Y² is a carbon atom, n is 2, and A² is preferably an alkyl group having at least one selected from the group consisting of a halogen atom, a cyano group, a fluorine atom and a cyano group, an aryl group having at least one selected from the group consisting of a fluorine atom and a cyano group, an alkylsulfonyl group which may have at least one selected from the group consisting of a fluorine atom and a cyano group, or an arylsulfonyl group which may have at least one selected from the group consisting of a fluorine atom and a cyano group. Two A²'s may be bonded to each other to form a ring.

In a case where Y² is a nitrogen atom, n is 1, and A² is preferably an alkyl group having at least one selected from the group consisting of a fluorine atom and a cyano group, an aryl group having at least one selected from the group consisting of a fluorine atom and a cyano group, an alkylsulfonyl group which may have at least one selected from the group consisting of a fluorine atom and a cyano group, or an arylsulfonyl group which may have at least one selected from the group consisting of a fluorine atom and a cyano group.

In a case where Y² is a phosphorus atom, n is 1 or 3, and A² is preferably an alkyl group having at least one selected from the group consisting of a halogen atom, a cyano group, a fluorine atom and a cyano group, an aryl group having at least one selected from the group consisting of a fluorine atom and a cyano group, an alkylsulfonyl group which may have at least one selected from the group consisting of a fluorine atom and a cyano group, or an arylsulfonyl group which may have at least one selected from the group consisting of a fluorine atom and a cyano group.

In a case where n is 2 or more, a plurality of A²'s may be the same as or different from each other.

In a case where Formula (Z-1) and Formula (Z-2) contain a fluorine atom, the percentage of the fluorine atom contained in Z is preferably 5 atom % to 80 atom % and more preferably 10 atom % to 70 atom % with respect to the total number of atoms constituting Z^{B}.

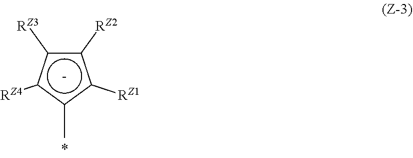

In Formula (Z-3), * represents a bonding site to LB² in Formula (B).

R^{Z1} to R^{Z4} are each independently preferably a cyano group or a fluorinated alkyl group.

Specific examples of the structural unit represented by Formula (B) include the structures described in paragraphs [0162] to [0166] of JP2014-199436A.

The polymer (B) may contain other structural units described for the polymer (A) in addition to the structural unit represented by Formula (B). In addition, the polymer (B) may further contain the structural unit represented by Formula (A) and a structural unit represented by Formula (C) which will be described later.

<<Polymer (C)>>

The polymer (C) contains a structural unit represented by Formula (C). In the polymer (C), the content of the structural unit represented by Formula (C) is preferably 10% by mass to 100% by mass with respect to the total mass of the polymer. The lower limit of the content of the structural unit represented by Formula (C) is more preferably 20% by mass or more, still more preferably 30% by mass or more, and particularly preferably 50% by mass or more. The upper limit of the content of the structural unit represented by Formula (C) is more preferably 95% by mass or less.

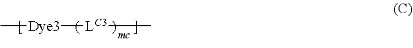

In Formula (C). L^{C3} represents a single bond or a divalent linking group, Dye3 represents a group having the structure represented by Formula 2, and me represents 0 or 1.

In Formula (C), L^{C3} represents a single bond or a divalent linking group. Suitable examples of the divalent linking group represented by L^{C3} include an alkylene group having 1 to 30 carbon atoms, an arylene group having 6 to 30 carbon atoms, a heterocyclic linking group, —CH═CH—, —O—, —S—, —C(═O)—, —CO₂—, —NR—, —CONR—, —O₂C—, —SO—, —SO₂—, and a linking group formed by linking two or more thereof.

m represents 0 or 1, but is preferably 1.

For details of Formula (C), reference can be made to the description of paragraphs [0165] to [0167] of JP2013-029760A and paragraphs [0080] to [0088] of JP2015-057487A, the contents of which are incorporated herein by reference.

The polymer (C) may contain other structural units described for the polymer (A) in addition to the structural unit represented by Formula (C).

The polymer (C) can be synthesized by sequential polymerization. The sequential polymerization includes polyaddition (for example, a reaction of a diisocyanate compound with a diol, a reaction of a diepoxy compound with a dicarboxylic acid, or a reaction of a tetracarboxylic dianhydride with a diol) and polycondensation (for example, a reaction of a dicarboxylic acid with a diol, or a reaction of a dicarboxylic acid with a diamine). Above all, the synthesis by a polyaddition reaction is particularly preferable because the reaction conditions can be moderated and the structure represented by Formula 2 is not decomposed. Known reaction conditions can be applied to the sequential polymerization.

<<Polymer (D)>>

The polymer (D) is represented by Formula (D).

L^{D4}Dye4)_{nd} (D)

In Formula (D), L^{D4} represents an nd-valent linking group, nd represents 2 to 20, and Dye4's each independently represent a polymer chain having the structure represented by Formula 2.

In Formula (D), nd is preferably 2 to 15, more preferably 2 to 14, still more preferably 2 to 8, particularly preferably 2 to 7, and most preferably 2 to 6.

Although nd in one molecule is an integer, a plurality of polymers (D) having different n may be used, and the average value of n may not be an integer.

In the present disclosure, nd in one molecule is preferably an integer of 2 to 20.

In addition, in a case where the polymer (D) is a mixture containing 50% by mass of a polymer a1 in which n in Formula (D) is 2, and 50% by mass of a polymer a2 in which n in Formula (D) is 1, nd becomes an average value of 1.5.

LD⁴ represents an nd-valent linking group. The nd-valent linking group includes a group consisting of 1 to 100 carbon atoms, 0 to 10 nitrogen atoms, 0 to 50 oxygen atoms, 1 to 200 hydrogen atoms, and 0 to 20 sulfur atoms, which may be unsubstituted or may further have a substituent.

Specific examples of the nd-valent linking group include the following groups, and groups (which may form a ring structure) constituted by combining two or more of the following groups.

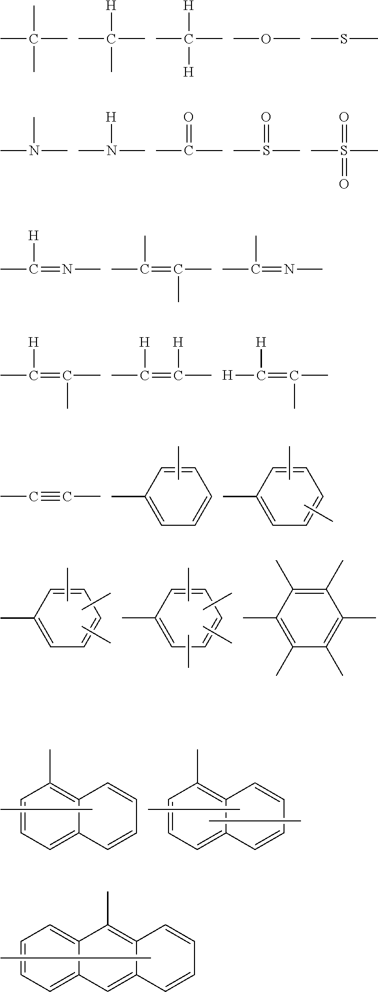

Specific examples of the nd-valent linking group are shown below. However, the present disclosure is not limited thereto. In addition, linking groups described in paragraphs [0071] to [0072] of JP2008-222950A and linking groups described in paragraph [0176] of JP2013-029760A can also be mentioned as the nd-valent linking group.

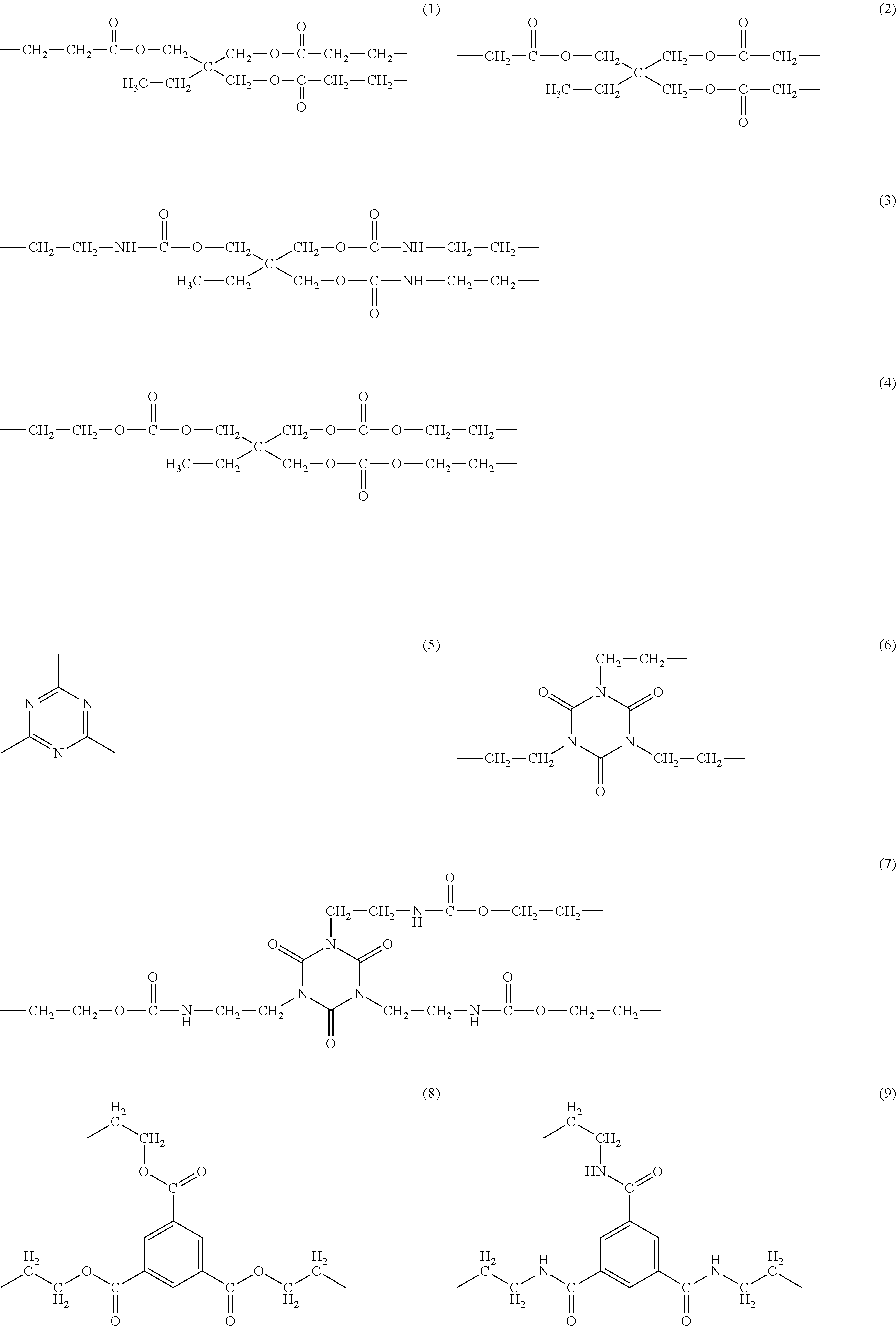

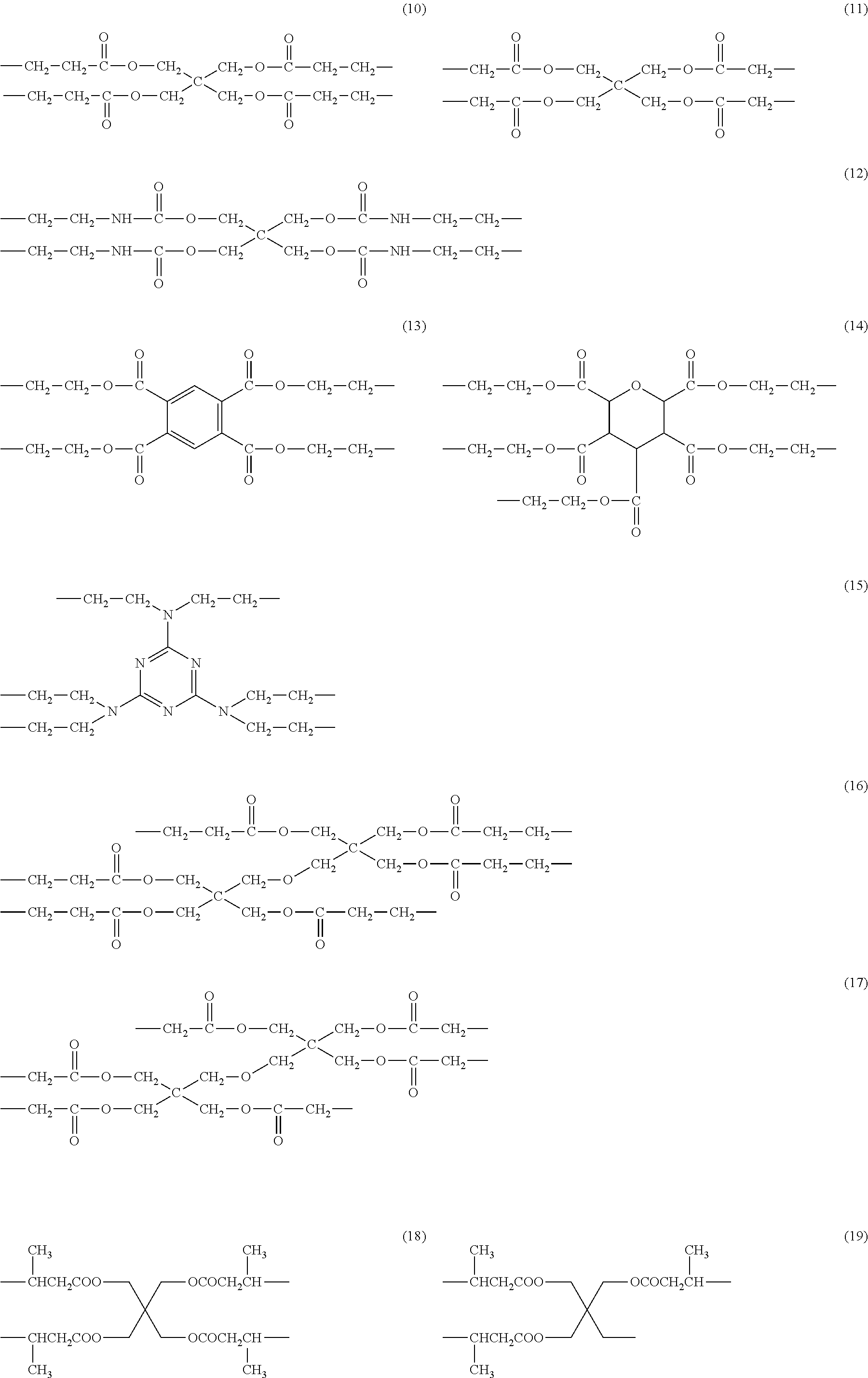

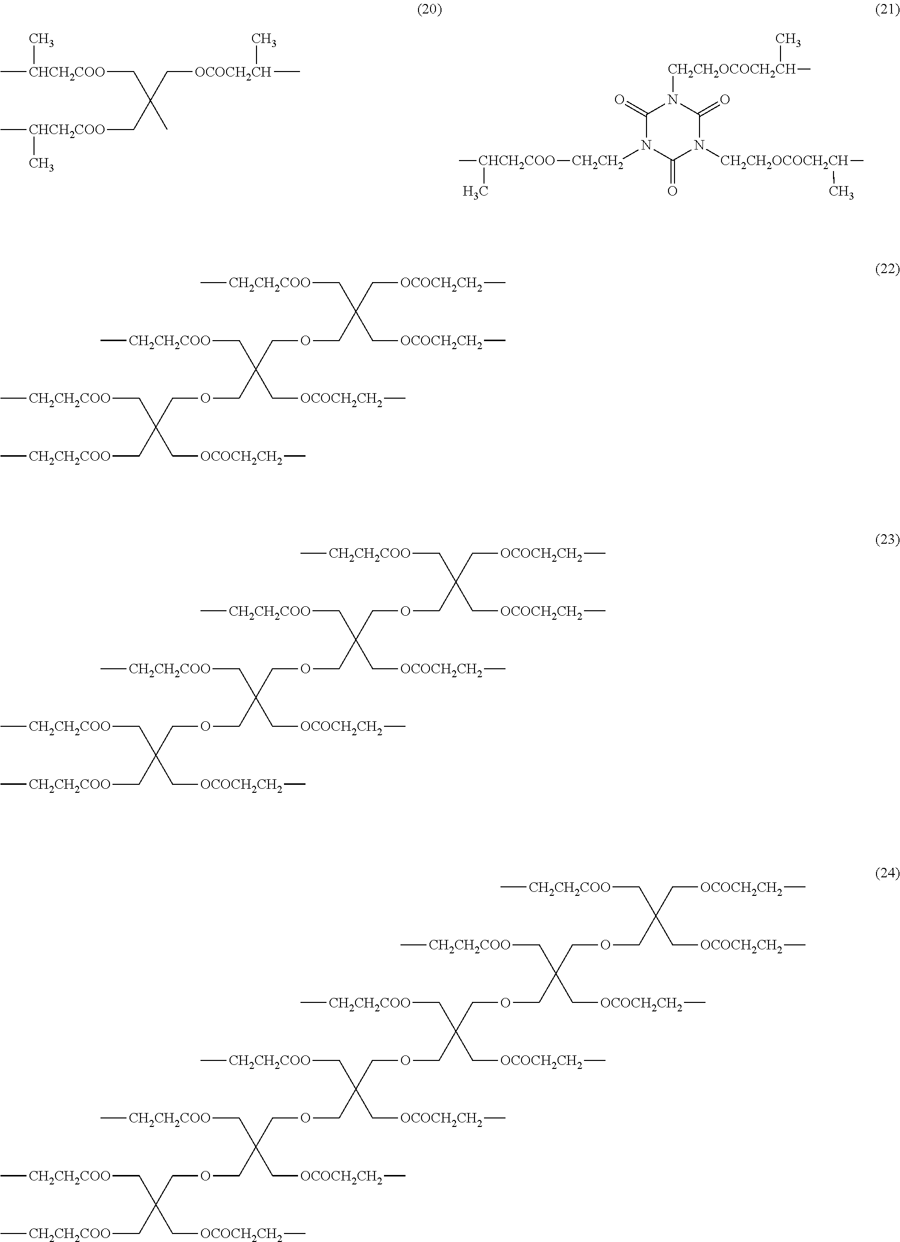

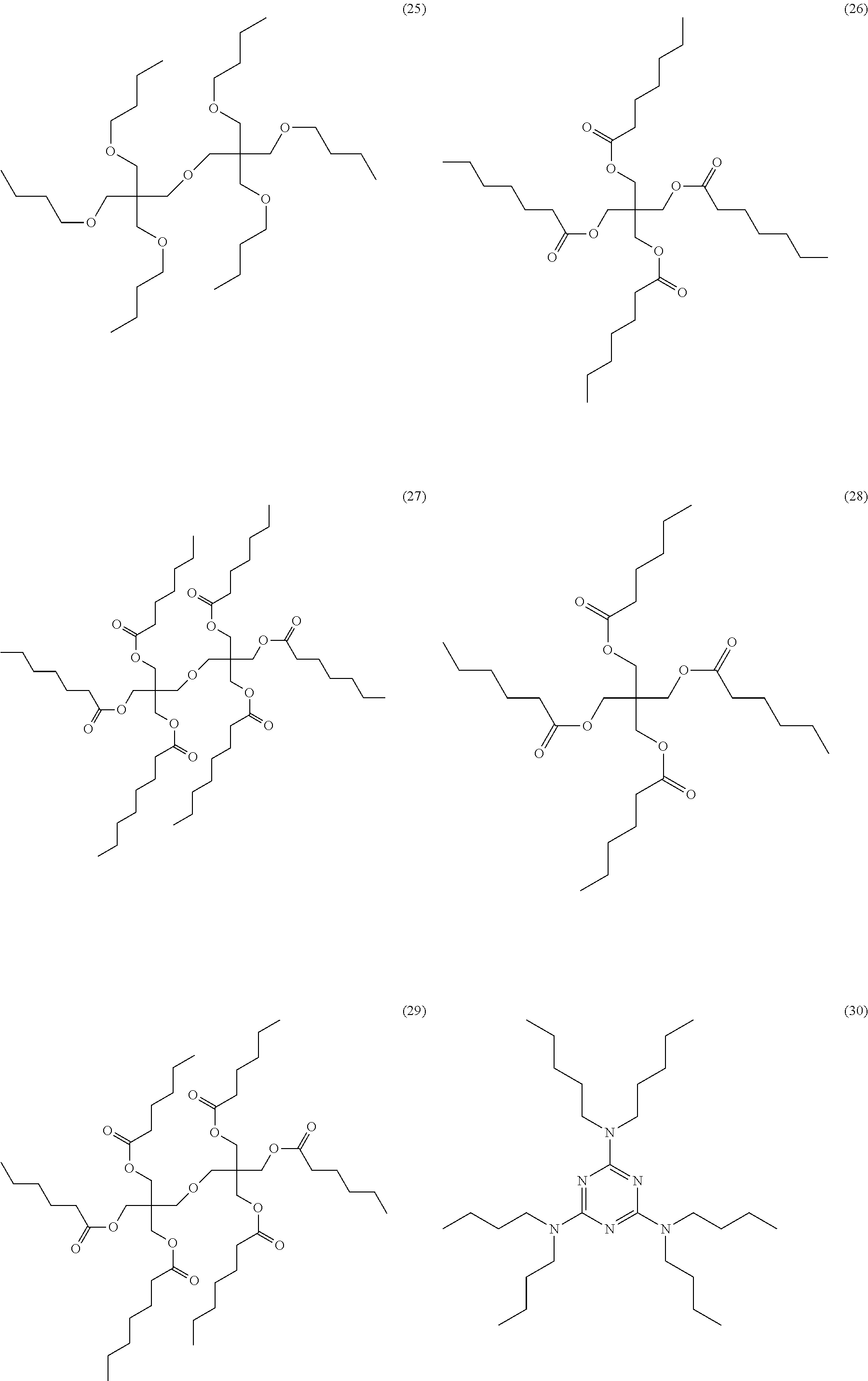 [SMILES: CCCCOCC(COCCCC)(COCCCC)COCC(COCCCC)(COCCCC)COCCCC ; CCCCCCC(=O)OCC(COC(=O)CCCCCC)(COC(=O)CCCCCC)COC(=O)CCCCCC ; CCCCCCCC(=O)OCC(COCC(COC(=O)CCCCCC)(COC(=O)CCCCCC)COC(=O)CCCCCCC)(COC(=O)CCCCCC)COC(=O)CCCCCC ; CCCCCC(=O)OCC(COC(=O)CCCCC)(COC(=O)CCCCC)COC(=O)CCCCC ; CCCCCCC(=O)OCC(COCC(COC(=O)CCCCC)(COC(=O)CCCCC)COC(=O)CCCCCC)(COC(=O)CCCCC)COC(=O)CCCCC ; CCCCCN(CCCCC)c1nc(N(CCCC)CCCC)nc(N(CCCC)CCCC)n1]

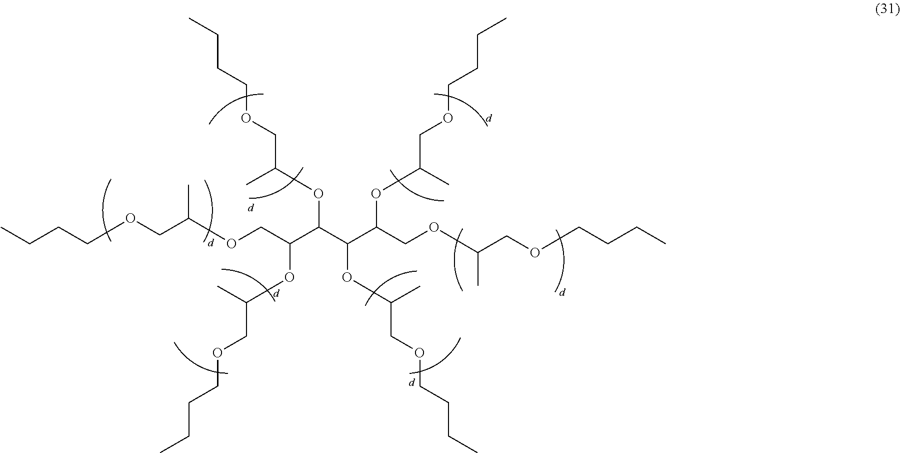

d's each independently represent an integer of 1 or more.

The polymer (D) is also preferably represented by Formula (Da).

L^{D4}Dye4a)_{nd} (Da)

In Formula (Da), L^{D4} represents an nd-valent linking group, nd represents 2 to 20, Dye4a represents a polymer chain having the structure represented by Formula 2, and S represents a sulfur atom.

One preferred aspect of the polymer (D) is a polymer represented by Formula (D-1).

(D-R^{D2})_{nD}—R^{D1}-(L^{D1}_P)_{mD} (D-1)

In Formula (D-1), R^{D1} represents a (mD+nD)-valent linking group, P represents a monovalent substituent having a polymer chain, D represents a structure represented by Formula 2, R^{D2} and L^{D1} each independently represent a single bond or a divalent linking group; mD represents an integer of 1 to 13, and in a case where mD is 2 or more, a plurality of P's may be different from each other; nD represents an integer of 2 to 14, and in a case where nD is 2 or more, a plurality of D's may be different from each other; and mD+nD represents an integer of 2 to 15.

In Formula (D-1), mD is preferably 1 to 5, more preferably 1 to 4, and particularly preferably 1 to 3.

In Formula (D-1), nD is preferably 2 to 8, more preferably 2 to 7, still more preferably 2 to 6, and particularly preferably 2 to 5.

In Formula (D-1), mD+nD is preferably 2 to 15.

Although mD and nD in one coloring agent are each an integer, in the present disclosure, a plurality of polymers having different mD and nD in Formula (D-1) may be contained. Therefore, the average value of m and n may not be an integer. In the present disclosure, mD in one polymer preferably represents an integer of 1 to 13. In addition, in a case where the polymer (D) is a mixture of a plurality of polymers (D), the average value of mD preferably represents 1 to 13, and the average value of nD preferably represents 2 to 14.

In Formula (D-1), R^{D1} represents a (mD+nD)-valent linking group. mD+nD satisfies 2 to 15.

The (mD+nD)-valent linking group represented by R^{D1} includes a group consisting of 1 to 100 carbon atoms, 0 to 10 nitrogen atoms, 0 to 50 oxygen atoms, 1 to 200 hydrogen atoms, and 0 to 20 sulfur atoms, which may be unsubstituted or may further have a substituent.

Specific example of the (mD+nD)-valent linking group represented by R^{D1} include the structures described for L^{D4} described above.

In Formula (D-1), R^{D2} and L^{D1} each independently represent a single bond or a divalent linking group. In a case where a plurality of R^{D2}'s and a plurality of L^{D1}'s are present, R^{D2}'s and L^{D1}'s may be the same as or different from each other, respectively.

The divalent linking group includes a group consisting of 1 to 100 carbon atoms, 0 to 10 nitrogen atoms, 0 to 50 oxygen atoms, 1 to 200 hydrogen atoms, and 0 to 20 sulfur atoms, which may be unsubstituted or may further have a substituent.

Specific examples of the divalent linking group include the following groups, and groups constituted by combining two or more of the following groups. R^{D2} and L^{D1} are each preferably a group containing —S— and more preferably —S—.

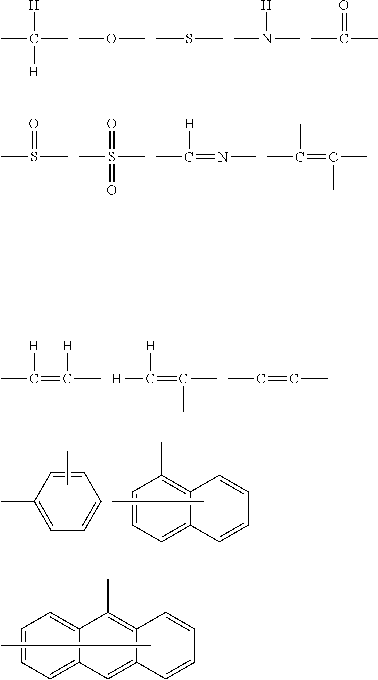

In Formula (D-1), P is preferably a monovalent substituent having a structural unit derived from a vinyl compound. In a case where mD is 2 or more, an mD-number of P's may be the same as or different from each other.

In a case where mD is 1, P is preferably a monovalent substituent having 2 to 20 (preferably 2 to 15, and more preferably 2 to 10) structural units derived from a vinyl compound. In addition, it is preferred that, in a case where mD is 2 or more, the average value of an m-number of structural units of P derived from a vinyl compound is 2 to 20 (preferably 2 to 15, and more preferably 2 to 10). According to this aspect, the flatness of a coating film is improved.

The number of structural units of P in a case where mD is 1, and the average value of an mD-number of structural units of P in a case where mD is 2 or more can be determined by nuclear magnetic resonance (NMR). Specifically, for example, the calculation can be made in such a manner that mD is determined from a peak surface area ratio between the (mD+nD)-valent linking group represented by R^{D1} and the structure D represented by Formula 2, and the peak surface area ratio of the structural unit is divided by mD.

Examples of the structural unit constituting P include the other structural units described for the polymer (A). The other structural unit preferably has one or more structural units selected from the group consisting of the structural unit having an acid group and the structural unit having a polymerizable group, and more preferably contains a structural unit having an acid group.

In a case where P contains a structural unit having an acid group, the content of the structural unit containing an acid group is preferably 10 mol % to 80 mol % and more preferably 10 mol % to 65 mol % with respect to all the structural units of P.

In a case where P contains a structural unit having a polymerizable group, the content of the structural unit having a polymerizable group is preferably 10 mol % to 80 mol % and more preferably 10 mol % to 65 mol % with respect to all the structural units of P.

In the present disclosure, in a case where the content of the “structural unit” is defined by a molar ratio, the above-mentioned “structural unit” has the same meaning as the “monomer unit”. In addition, in the present disclosure, the “monomer unit” may be modified after polymerization, by a polymer reaction or the like.

The polymer represented by Formula (D-1) can be synthesized by the following method or the like.

(1) A method of carrying out a polymer reaction of a polymer in which a functional group selected from a carboxy group, a hydroxy group, an amino group, and the like is introduced into a terminal with an acid halide having the structure represented by Formula 2 and an alkyl halide having the structure represented by Formula 2, an isocyanate having the structure represented by Formula 2, or the like.

(2) A method of carrying out a Michael addition reaction of a polymer having an ethylenically unsaturated bond introduced into a terminal with a mercaptan having the structure represented by Formula 2.

(3) A method of reacting a polymer having an ethylenically unsaturated bond introduced into a terminal with a mercaptan having the structure represented by Formula 2 in the presence of a radical generator.

(4) A method of reacting a polymer having a plurality of mercaptans introduced into a terminal with a compound having an ethylenically unsaturated bond and the structure represented by Formula 2 in the presence of a radical generator.

(5) A method of radically polymerizing a vinyl compound in the presence of a thiol compound having the structure represented by Formula 2.

Among the above-mentioned methods, the synthesis methods (2) to (5) are preferable, and the synthesis methods (3) to (5) are more preferable, from the viewpoint of ease of synthesis.

In addition, one preferred aspect of the polymer (D) is a polymer represented by Formula (D-2).

P²-(Q²)_{nD2} (D-2)

In Formula (D-2), P² represents an nD2-valent linking group, Q² represents a polymer chain containing a structural unit having the structure represented by Formula 2, and the average value of an nD2-number of Q²'s of structural units having the structure represented by Formula 2 is 2 or more, and nD2 represents an integer of 3 to 10.

The nd2-valent linking group for P² in Formula (D-2) includes a group consisting of 1 to 100 carbon atoms, 0 to 10 nitrogen atoms, 0 to 50 oxygen atoms, 1 to 200 hydrogen atoms, and 0 to 20 sulfur atoms, which may be unsubstituted or may further have a substituent.

The nD2-valent linking group for P² is preferably a group consisting of 1 to 60 carbon atoms, 0 to 10 nitrogen atoms, 0 to 40 oxygen atoms, 1 to 120 hydrogen atoms, and 0 to 10 sulfur atoms; more preferably a group consisting of 1 to 50 carbon atoms, 0 to 10 nitrogen atoms, 0 to 30 oxygen atoms, 1 to 100 hydrogen atoms, and 0 to 7 sulfur atoms; and still more preferably a group consisting of 1 to 40 carbon atoms, 0 to 8 nitrogen atoms, 0 to 20 oxygen atoms, 1 to 80 hydrogen atoms, and 0 to 5 sulfur atoms.

The nD2-valent linking group represented by P² is preferably a linking group derived from a polyhydric alcohol.

The polymer represented by Formula (D-2) is preferably represented by Formula (D-2a).

AD1B^{D1}—C^{D1}—S-Q^{D})_{nd} (D-2a)

In Formula (D-2a), A^{D1} represents an nd-valent linking group, B^{D1} represents a single bond, —O—, —S—, —CO—, —NR^{2a}—, —O₂C—, —CO₂—, —NR^{2a}OC—, or —CONR^{2a}—, R^{2a} represents a hydrogen atom, an alkyl group, or an aryl group, C^{D1} represents a single bond or a divalent linking group, S represents a sulfur atom, Q^{D} represents a polymer chain containing a structural unit having the structure represented by Formula 2, the average value of an nD-number of QD's of structural units having the structure represented by Formula 2 is 2 or more, and nD represents an integer of 3 to 10.

In Formula (D-2a), the n-valent linking group for A^{D1} is preferably a group selected from the group consisting of an aliphatic hydrocarbon group which may have an oxygen atom in the main chain, an aromatic ring group and a heterocyclic group, or a group consisting of a combination of two or more of these groups.

Examples of the aliphatic hydrocarbon group include an alkylene group and an alkenylene group. The number of carbon atoms in the alkylene group is, for example, preferably 1 to 60 and more preferably 1 to 30. The number of carbon atoms in the alkenylene group is, for example, preferably 1 to 60 and more preferably 1 to 30.

Examples of the aliphatic hydrocarbon group having an oxygen atom in the main chain include groups represented by —(OR^{x1})ₘ₂ₐ— and —(R^{x1}O)ₘ₂ₐ—. The aliphatic hydrocarbon group having an oxygen atom in the main chain may be linear, branched, or cyclic. The main chain in the linking group refers to a skeleton portion of the linking group, which does not include a substituent.

R^{x1} represents an alkylene group or an alkenylene group. m2a represents an integer of 1 or more, and in a case where m2a is 2 or more, an m2a-number of R^{x1}'s may be the same as or different from each other.

The number of carbon atoms in the alkylene group for R^{x1} is preferably 1 to 20, more preferably 1 to 10, and more preferably 1 to 5. The alkylene group may be linear, branched, or cyclic.

The number of carbon atoms in the alkenylene group for R^{x1} is preferably 2 to 20, more preferably 2 to 10, and still more preferably 2 to 5. The alkenylene group may be linear, branched, or cyclic.

The aromatic ring group may be monocyclic or polycyclic.

The heterocyclic group is preferably a 5- or 6-membered ring. The heterocyclic group may be monocyclic or polycyclic. Examples of the hetero atom contained in the heterocyclic group include a nitrogen atom, an oxygen atom, and a sulfur atom. A nitrogen atom is preferable. The number of hetero atoms is preferably 1 to 3.

Preferred examples of the nd-valent linking group for AD include a hydrocarbon group which may have an oxygen atom in the main chain, an aromatic ring group, a heterocyclic group, a combination of a hydrocarbon group which may have an oxygen atom in the main chain and an aromatic ring group, and a combination of a hydrocarbon group which may have an oxygen atom in the main chain and a heterocyclic group.

In Formula (D-2a), B^{D1} is preferably a single bond, —O—, —CO—, —O₂C—, —CO₂—, —NR^{2a}OC—, or —CONR^{2a}OC—,

R^{2a} represents a hydrogen atom, an alkyl group, or an aryl group.

The number of carbon atoms in the alkyl group for R^{2a} is preferably 1 to 30 and more preferably 1 to 10. The alkyl group may be linear, branched, or cyclic.

The number of carbon atoms in the aryl group for R² is preferably 6 to 30 and more preferably 6 to 12.

R^{2a} is preferably a hydrogen atom or an alkyl group and more preferably a hydrogen atom.

In Formula (D-2a), C^{D1} represents a single bond or a divalent linking group.

The divalent linking group is preferably an alkylene group, an arylene group, or an oxyalkylene group and more preferably an alkylene group or an oxyalkylene group.

The numbers of carbon atoms in the alkylene group and the oxyalkylene group are each independently preferably 1 to 30 and more preferably 1 to 10. The alkyl group and the oxyalkylene group may be linear, branched, or cyclic.

The number of carbon atoms in the arylene group is preferably 6 to 30 and more preferably 6 to 12.

Specific examples of the nd-valent linking group represented by P² are shown below. However, the present disclosure is not limited thereto.

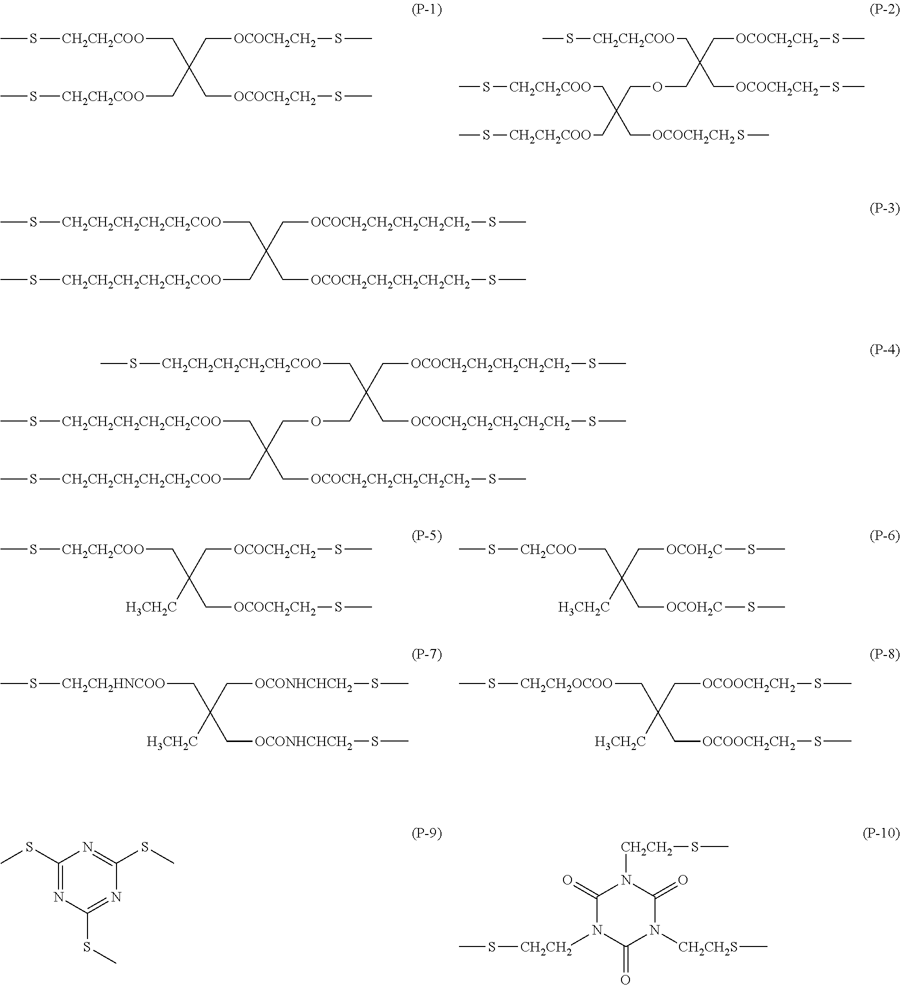

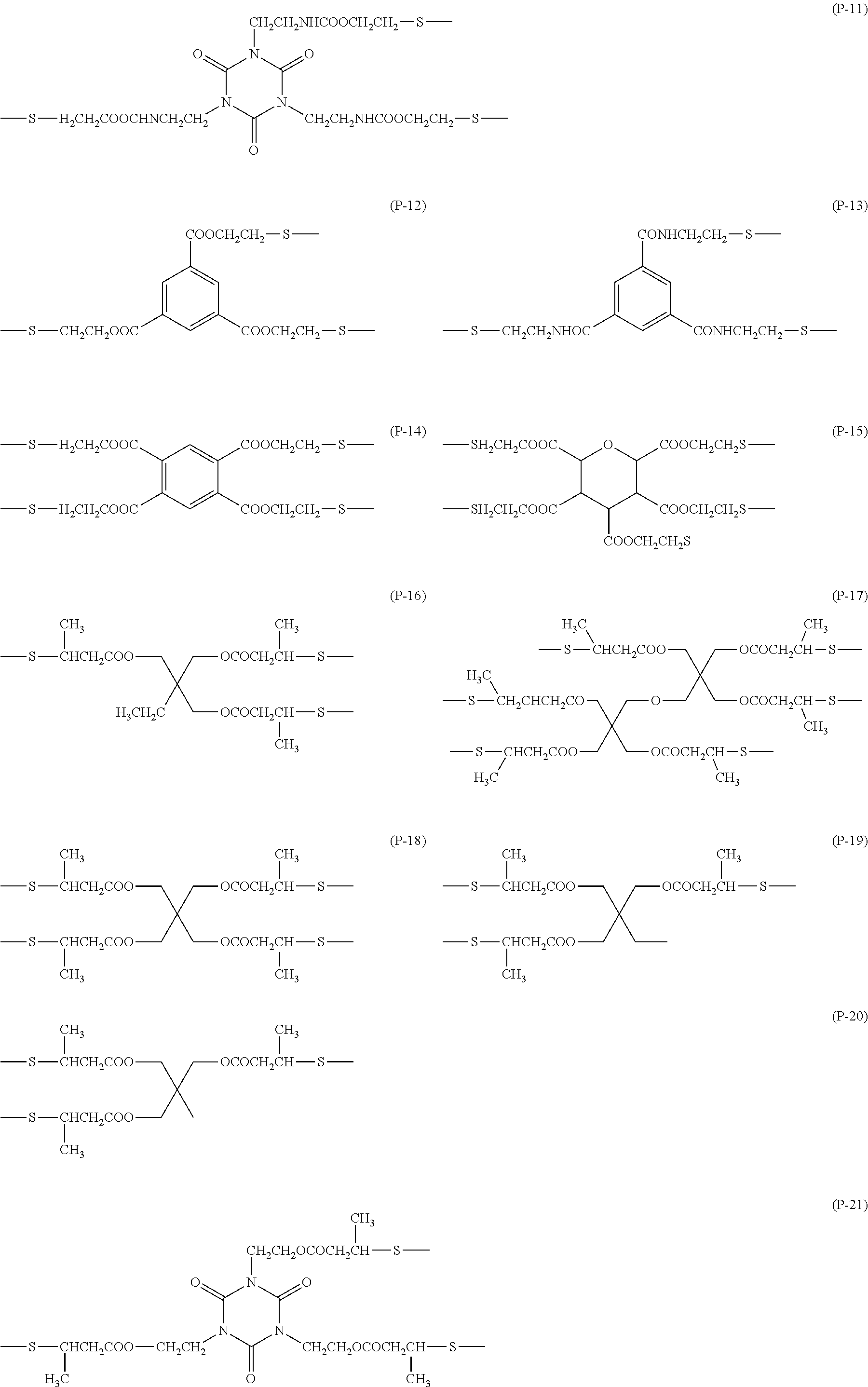

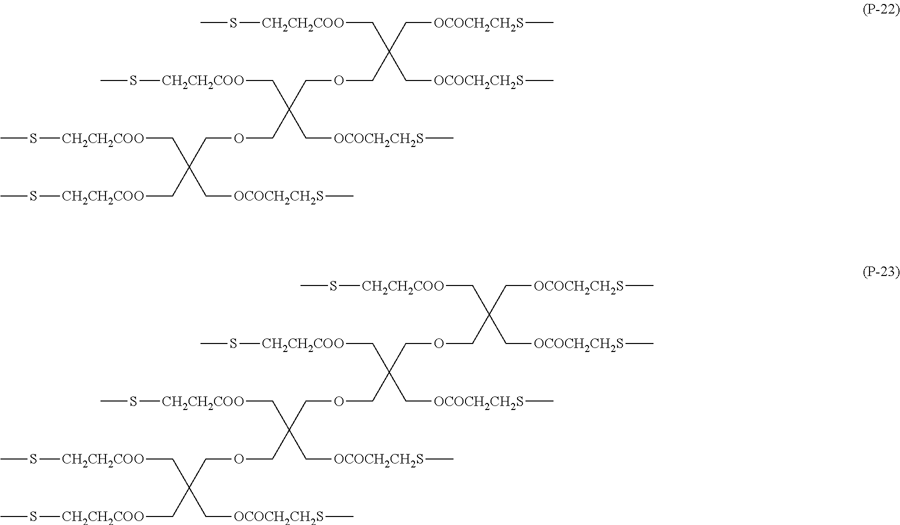

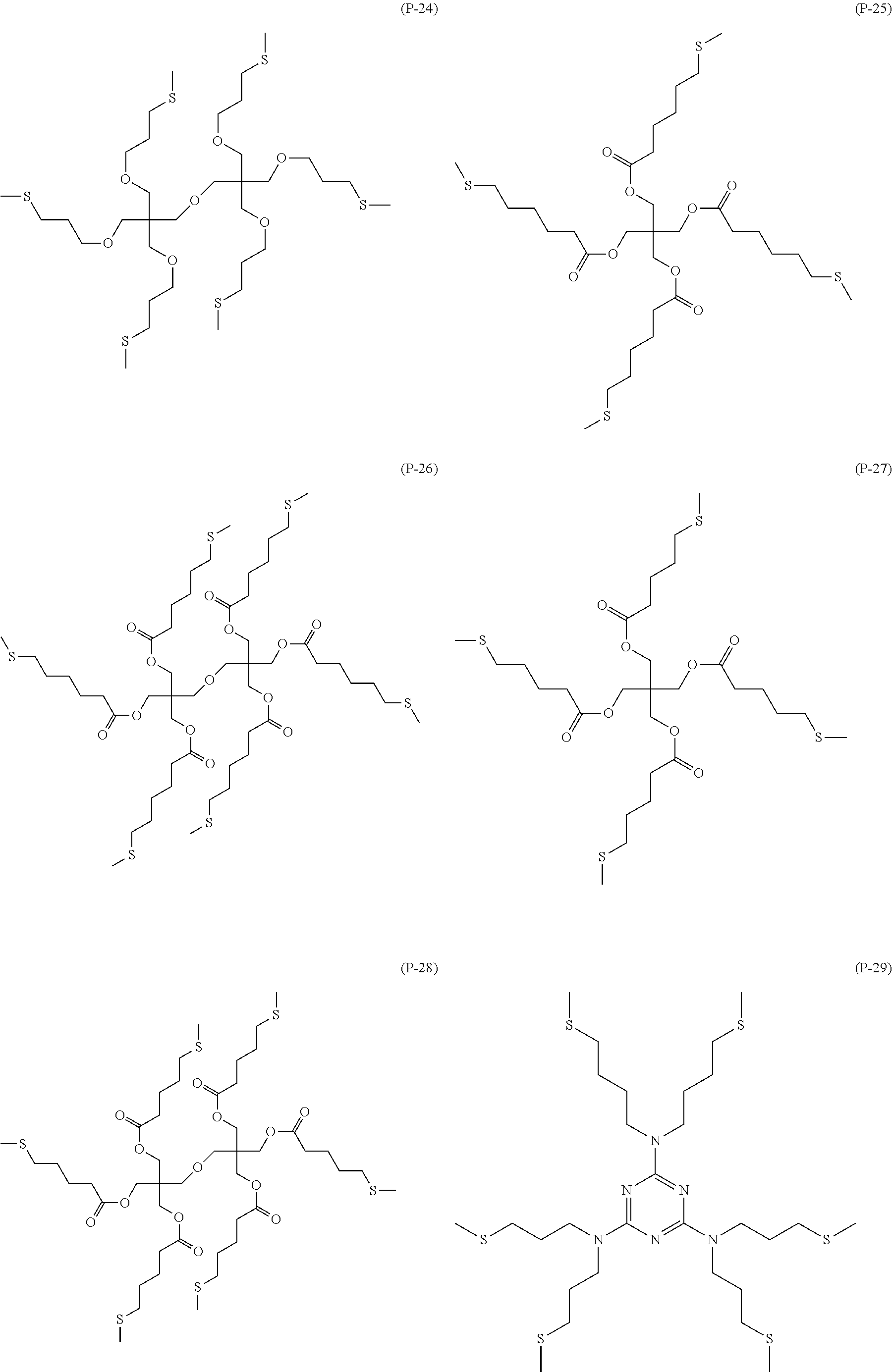

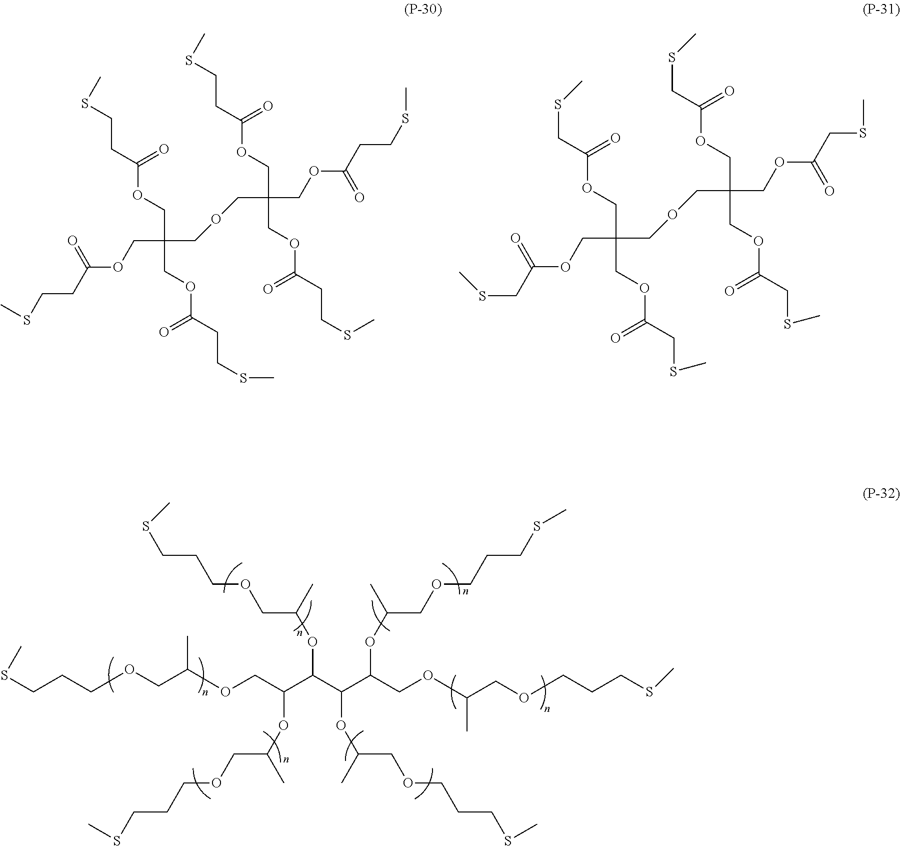

The polymer chain for Q^{D} represents a polymer chain containing a structural unit having the structure represented by Formula 2, and the average value of an nd-number of Q^{D}'s of structural units having the structure represented by Formula 2 is 2 or more. An nd-number of Q^{D}'s may be the same as or different from each another.

In the polymer chain for Q^{D}, the average value of the number of the structural units having the structure represented by Formula 2 is preferably 2 to 20, more preferably 2 to 15, and still more preferably 2 to 10.

The average value of the number of structural units having the structure represented by Formula 2 can be determined by nuclear magnetic resonance (NMR). Specifically, for example, the number of structural units in Formula (D-2) is determined from the peak surface area ratio between the nd-valent linking group represented by P^{D} and the structural unit of the polymer chain Q^{D}. Next, the number of structural units in the polymer chain Q^{D} can be calculated by dividing the obtained value by nd.

The weight-average molecular weights of the polymer chain Q^{D}'s are each independently preferably 2,000 to 40,000.

The polymer chain represented by Q^{D} is not particularly limited as long as it has the structure represented by Formula 2, but is preferably one selected from the group consisting of a (meth)acrylic-based resin, a styrene-based resin, and a (meth)acrylic/styrene-based resin.

The polymer chain having a structural unit having the structure represented by Formula 2 is not particularly limited, and examples thereof include the structural unit represented by Formula (A) and the repeating unit represented by Formula (C).

In addition, the content of the structural unit having the structure represented by Formula 2 in all the structural units constituting the polymer chain Q^{D} is preferably 5 mol % to 60 mol %, more preferably 10 mol % to 50 mol %, and still more preferably 20 mol % to 40 mol %.

The polymer chain Q^{D} may have other structural units described for the polymer (A), in addition to the structural unit having the structure represented by Formula (2). As other structural units, it is preferable to have one or more selected from a structural unit having an acid group and a structural unit having a polymerizable group.

In a case where the polymer chain Q^{D} contains a structural unit having a polymerizable group, the proportion of the structural unit having a polymerizable group is preferably 5 molar equivalents to 50 molar equivalents and more preferably 10 molar equivalents to 40 molar equivalents with respect to 100 molar equivalents of all the structural units of the polymer chain Q^{D}.

In a case where the polymer chain Q^{D} contains a structural unit having an acid group, the content of the structural unit having an acid group is preferably 5 molar equivalents to 50 molar equivalents and more preferably 10 molar equivalents to 40 molar equivalents with respect to 100 molar equivalents of all the structural units of the polymer chain Q^{D}.

The polymer represented by Formula (D-2) is not particularly limited, and can be produced by a method of carrying out radical polymerization of a polyfunctional thiol compound having 3 to 10 thiol groups in one molecule with a compound having the structure represented by Formula 2 and a radical polymerizable group (radical polymerizable coloring agent compound).

The radical polymerization of the polyfunctional thiol compound with the radical polymerizable coloring agent compound can be carried out, for example, by using a method in which a polyfunctional thiol compound and a radical polymerizable coloring agent compound are dissolved in an appropriate solvent, and a radical generator is added thereto, followed by addition at about 50° C. to 100° C. (thiol-ene reaction method).

<<<Properties of Polymer>>>

The weight-average molecular weight (Mw) of the polymer is preferably 2,000 to 40,000. The lower limit of Mw of the polymer is more preferably 3,000 or more and still more preferably 4,000 or more. The upper limit of Mw of the polymer is more preferably 35,000 or less and still more preferably 30,000 or less.

An acid value of the polymer is preferably 10 mgKOH/g or more, more preferably 20 mgKOH/g or more, still more preferably 27 mgKOH/g or more, and particularly preferably 30 mgKOH/g or more. In addition, the upper limit of the acid value is preferably 300 mgKOH/g or less, more preferably 200 mgKOH/g or less, still more preferably 180 mgKOH/g or less, particularly preferably 130 mgKOH/g or less, and most preferably 120 mgKOH/g or less. By satisfying the acid value within the above range, the developability can be further improved and therefore the development residue can be further reduced.

The ratio (Mw/Mn) of the weight-average molecular weight (Mw) to the number-average molecular weight (Mn) of the polymer is preferably 1.0 to 3.0, more preferably 1.0 to 2.5, and particularly preferably 1.0 to 2.0.

(Maximum Absorption Wavelength)

The maximum absorption wavelength of the specific compound is preferably in a range of 620 nm to 695 nm and more preferably in a range of 640 nm to 690 nm. The maximum absorption wavelength is measured using a Cary 5000 UV-Vis-NIR spectrophotometer (manufactured by Agilent Technologies, Inc.).

[Half-Width]

In a wavelength-absorbance curve obtained in the measurement of the maximum absorption wavelength, the half-width of the wavelength peak at the maximum absorption wavelength is preferably 1450 cm⁻¹ or less, more preferably 1400 cm⁻¹ or less, and still more preferably 1350 cm⁻¹ or less.

The lower limit of the half-width is not particularly limited, but is preferably 500 cm⁻¹ or more.

The half-width is measured by a method described in the Examples which will described later.

[Molar Light Absorption Coefficient]

The molar light absorption coefficient of the specific compound at the maximum absorption wavelength is preferably 2.0×105 L/(mol·cm) or more and more preferably 2.1×10⁵ L/(mol·cm) or more.

The molar light absorption coefficient is measured using a Cary 5000 UV-Vis-NIR spectrophotometer (manufactured by Agilent Technologies, Inc.).

[Absorbance at Wavelength of 570 nm]

From the viewpoint of the spectral characteristics of a cured product to be obtained, the percentage of the absorbance at a wavelength of 570 nm to the absorbance at a wavelength of 650 nm of the specific compound (absorbance at 570 nm/absorbance at 650 nm×100(%)) is preferably less than 8%, more preferably less than 7%, and still more preferably less than 6%.

[Average Particle Size]

In a case where the specific compound is a pigment, the average particle size thereof is preferably 0.01 μm to 0.1 μm and more preferably 0.01 μm to 0.05 μm.

In the present disclosure, unless otherwise specified, the average particle size of the pigment is measured on a volume basis using a MICROTRAC UPA 150 (manufactured by Nikkiso Co., Ltd).

[Content]

In the curable composition according to the present disclosure, the content of the specific compound is preferably 10% by mass to 70% by mass, more preferably 15% by mass to 60% by mass, and still more preferably 20% by mass to 50% by mass with respect to the total solid content of the curable composition.

Hereinafter, compounds 1 to 85, which are specific examples of the specific compound, are shown, the present invention is not limited thereto. In addition, the ratio of each structural unit in the compounds 82 to 85 can be arbitrarily set.

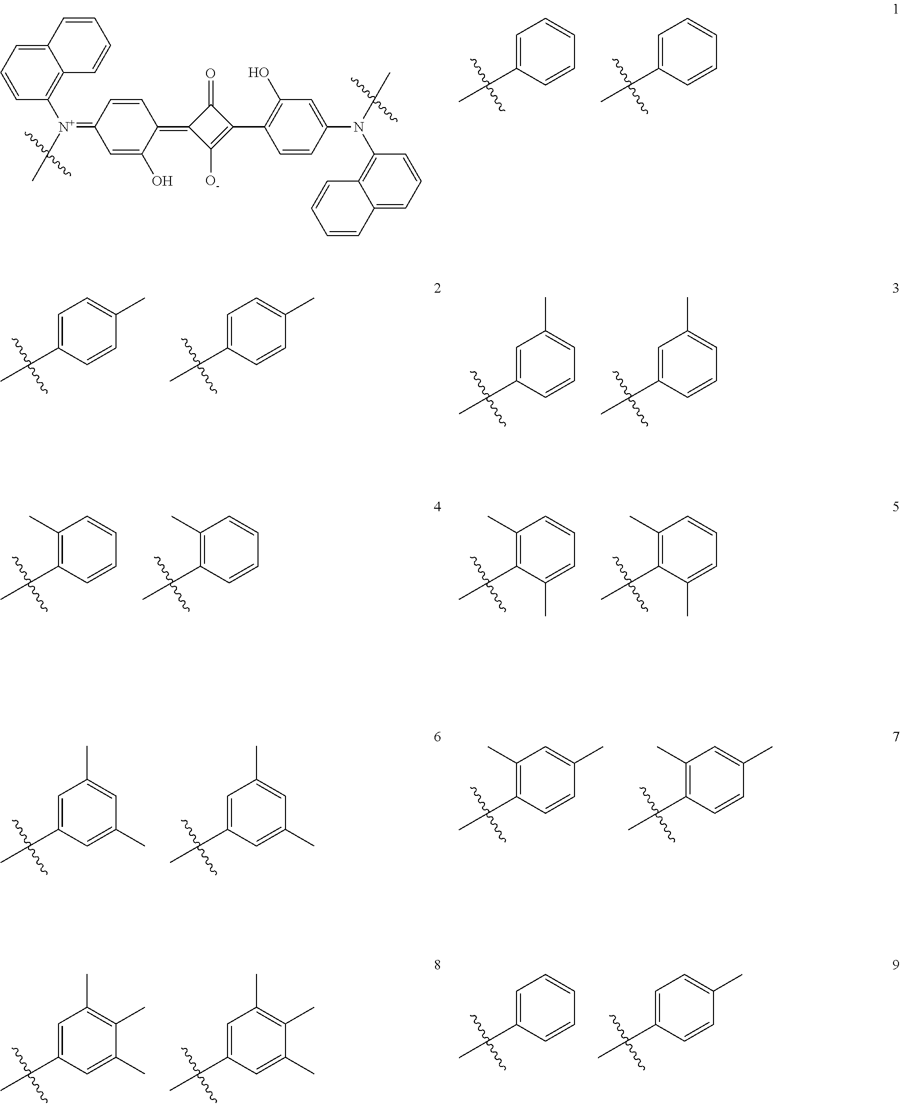

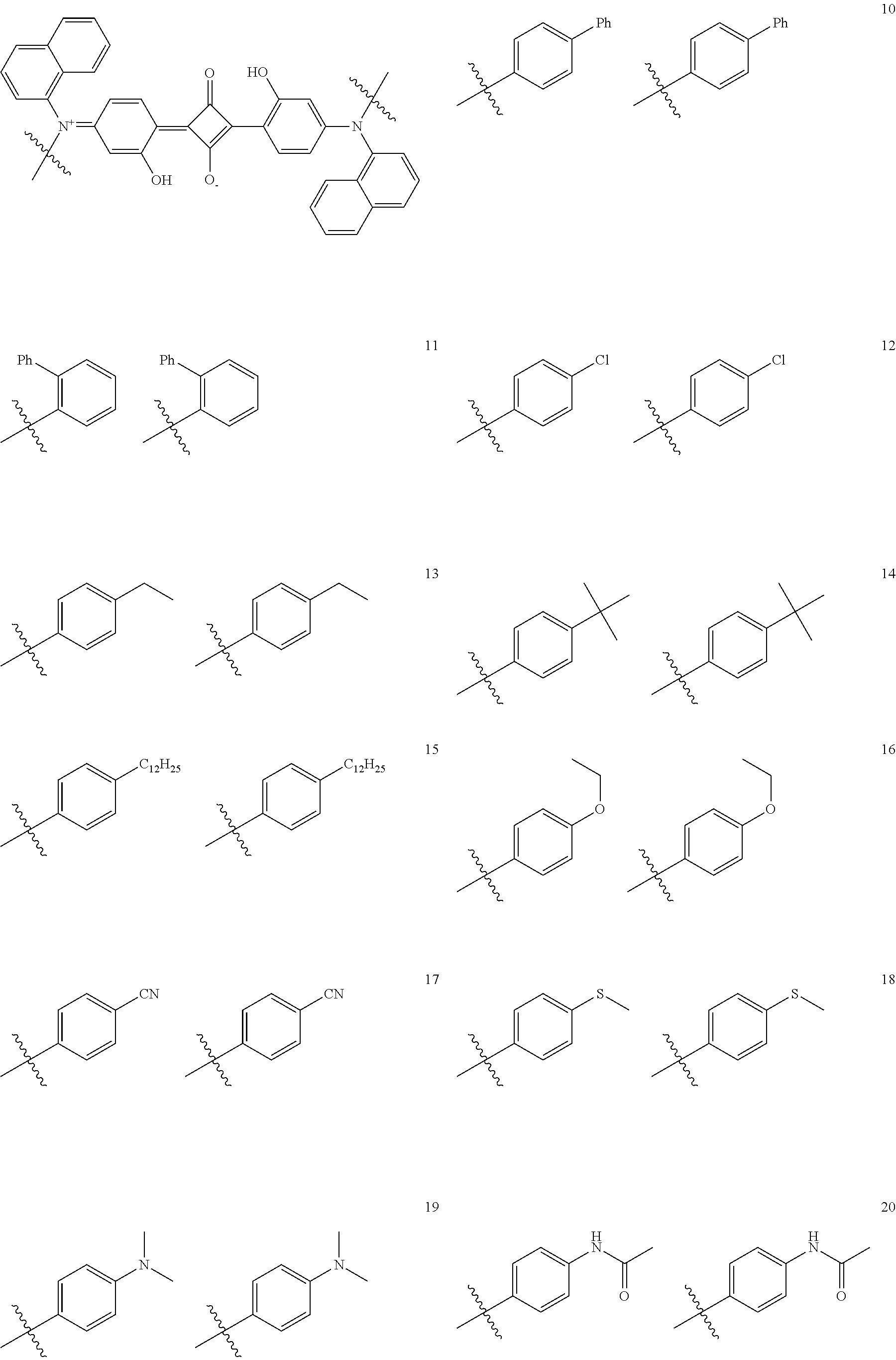

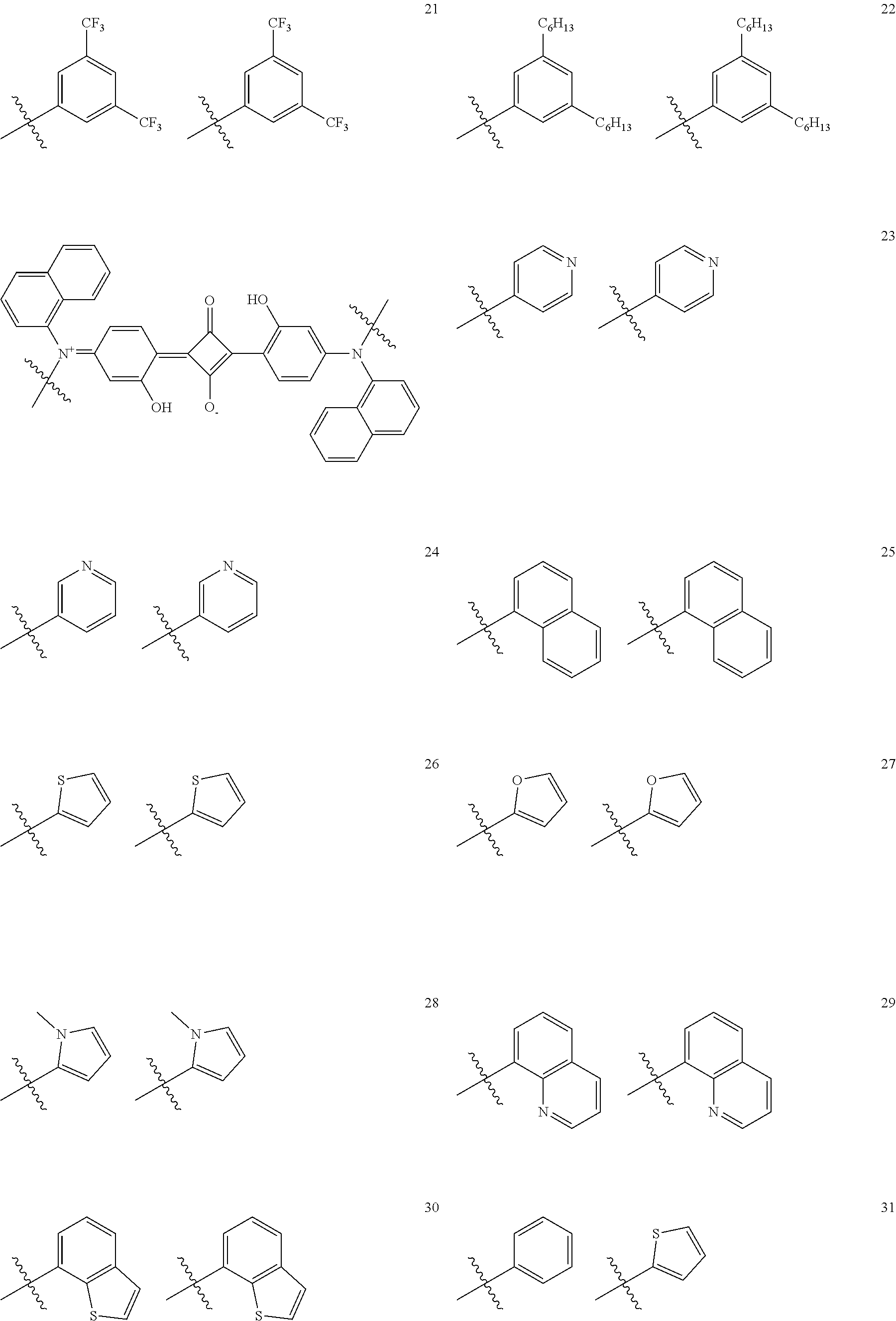

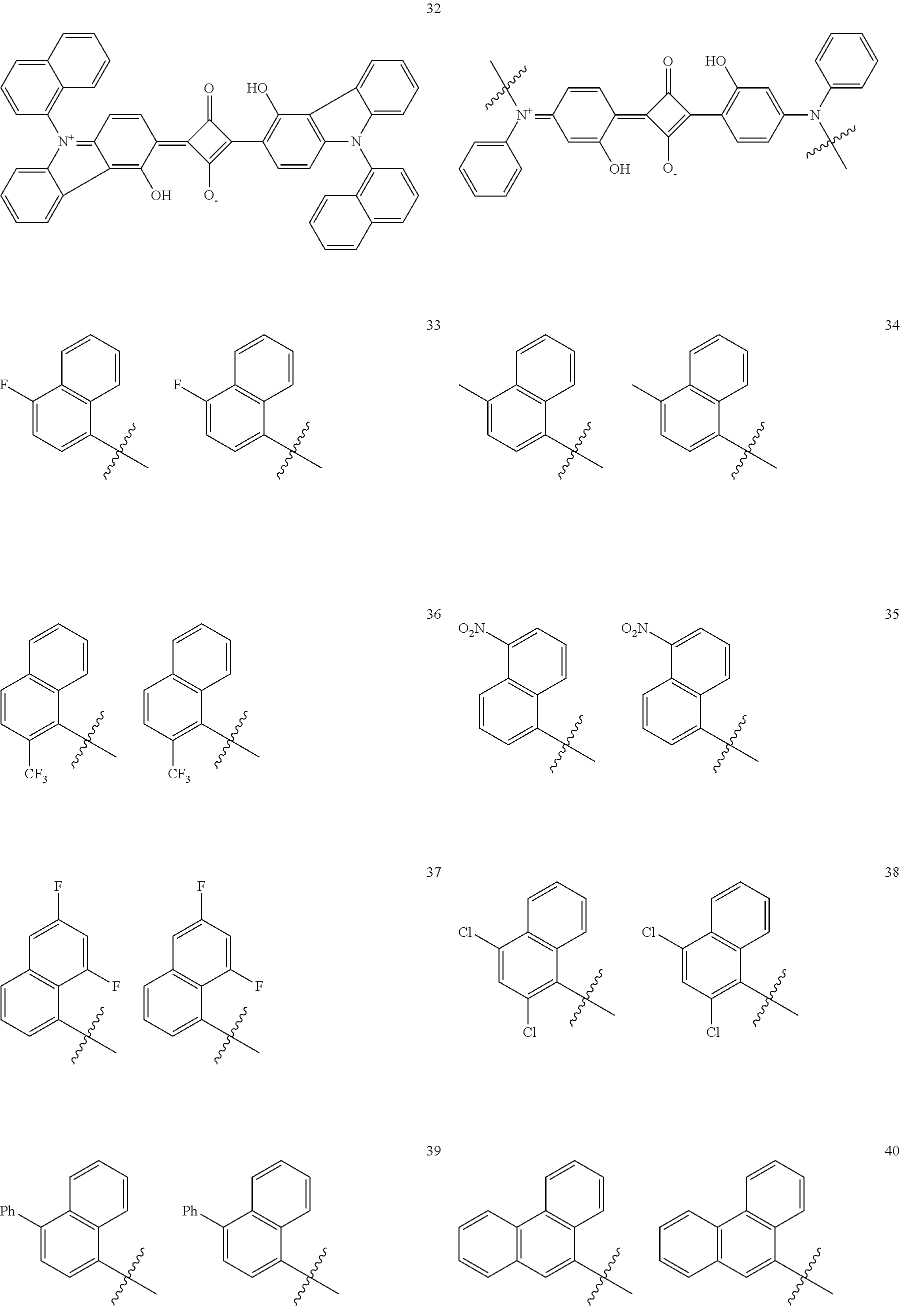

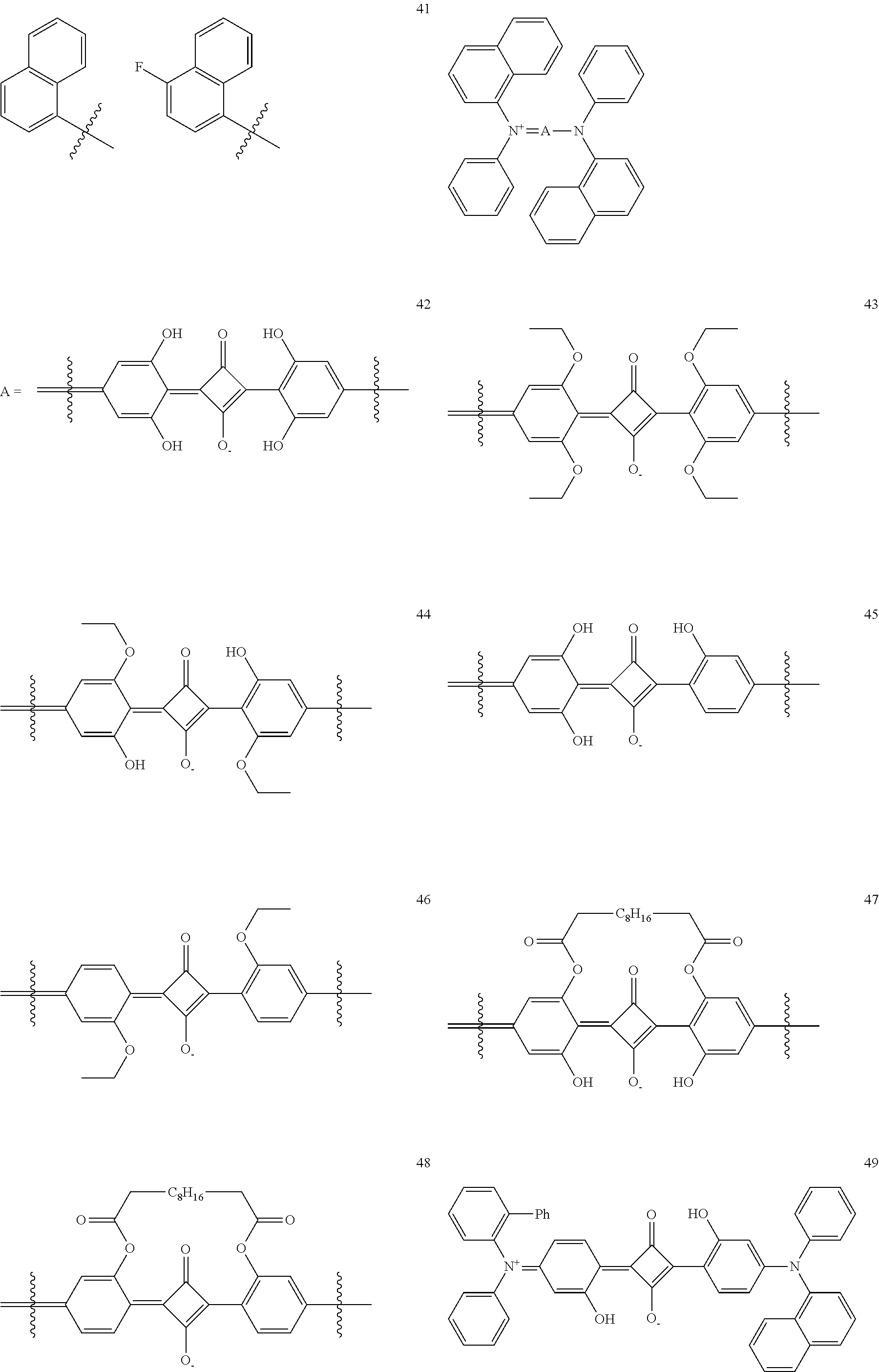

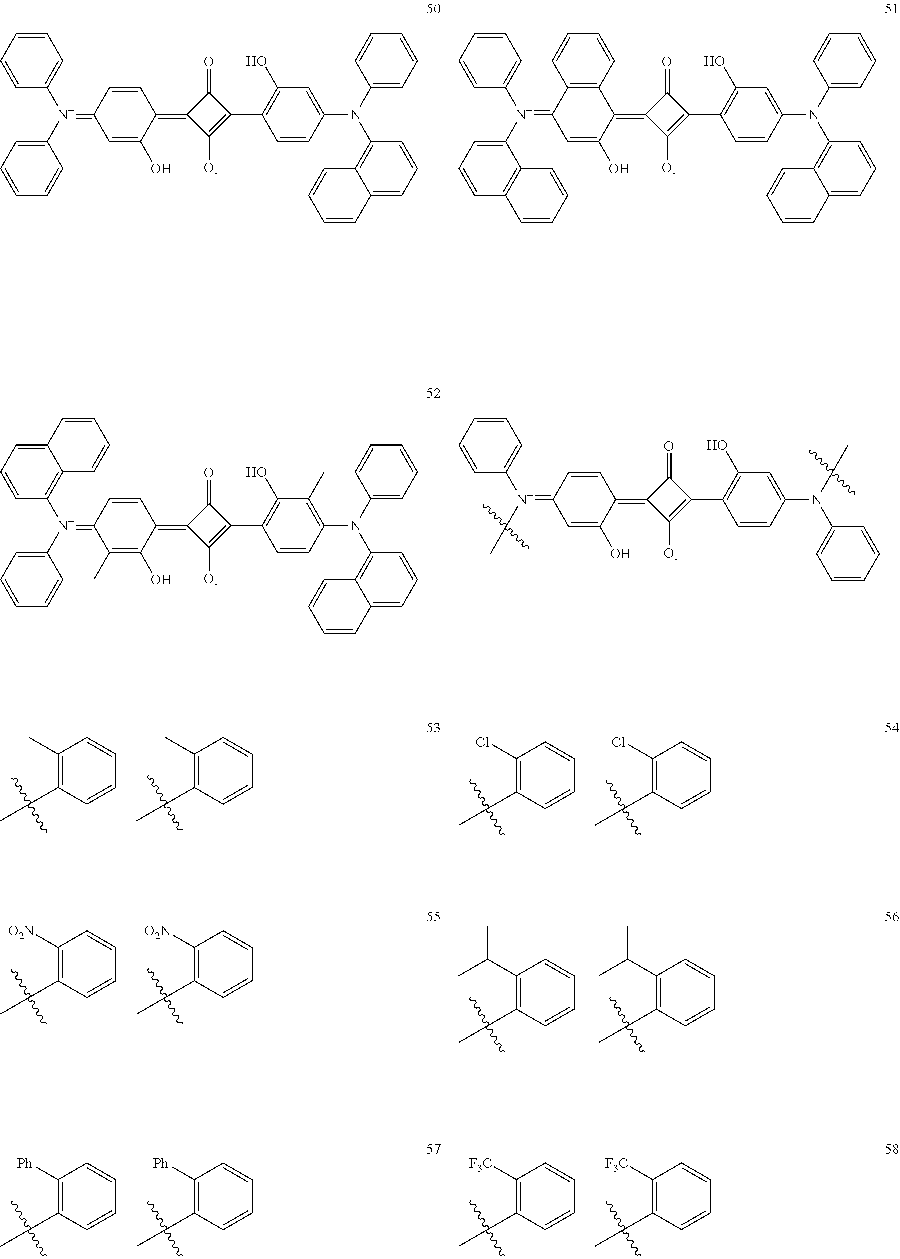

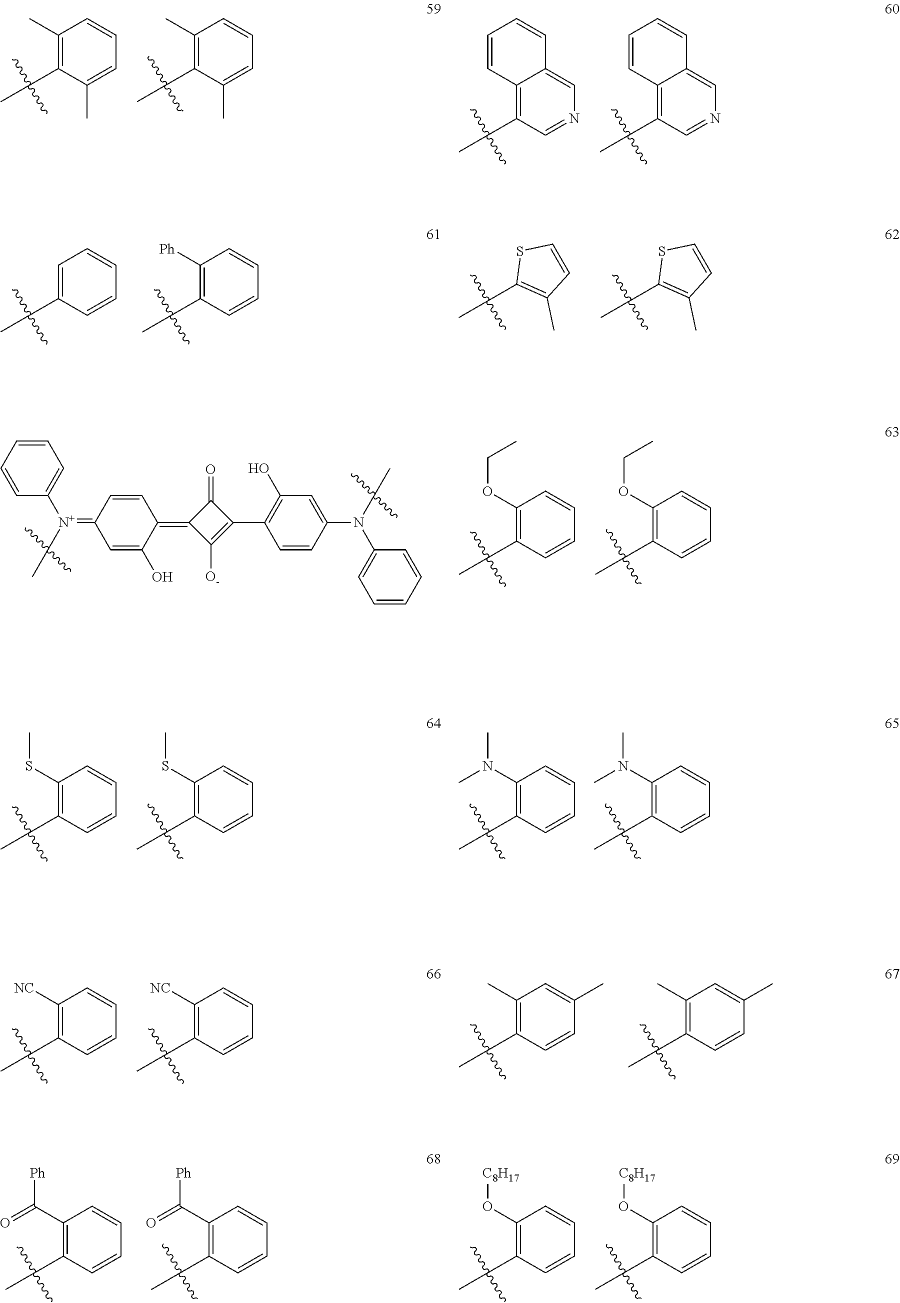

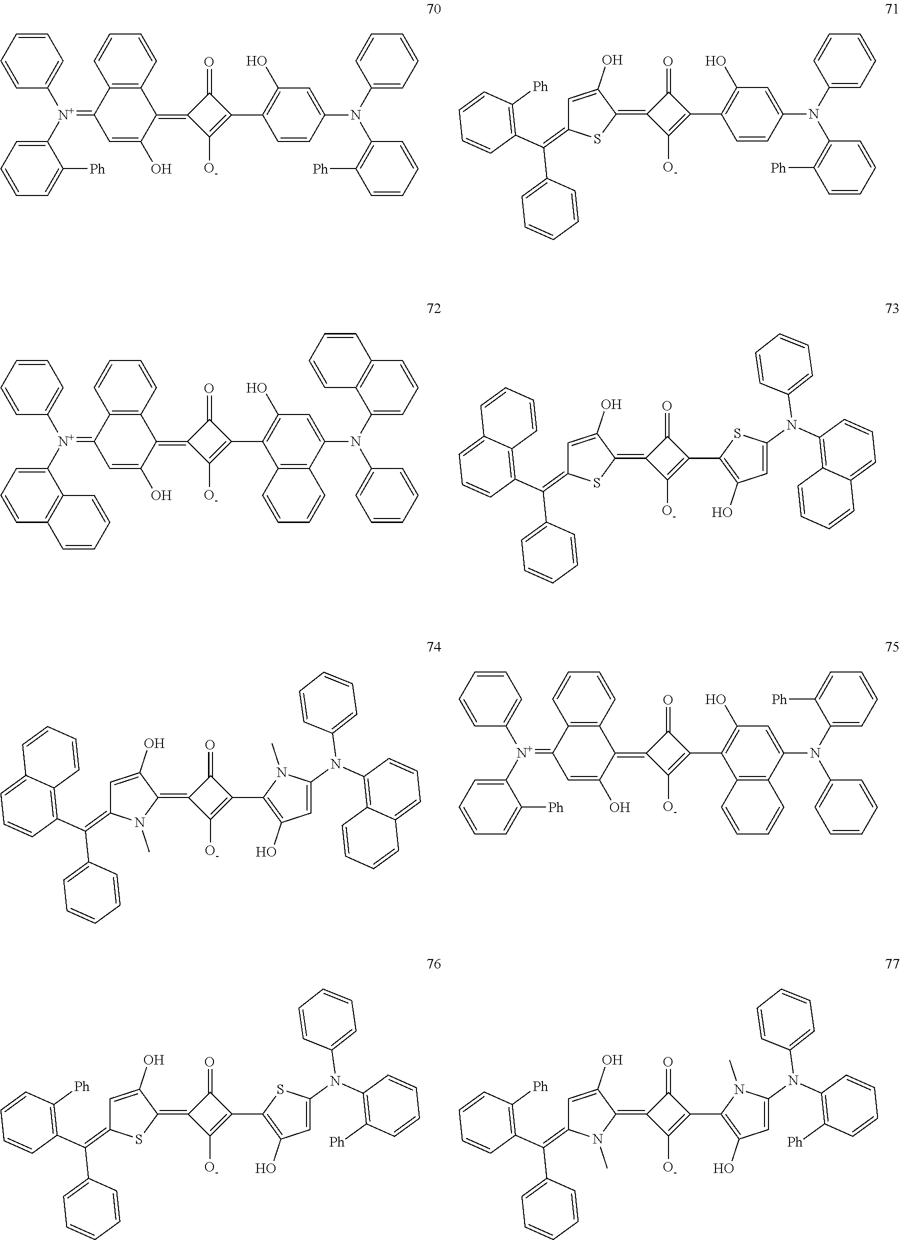

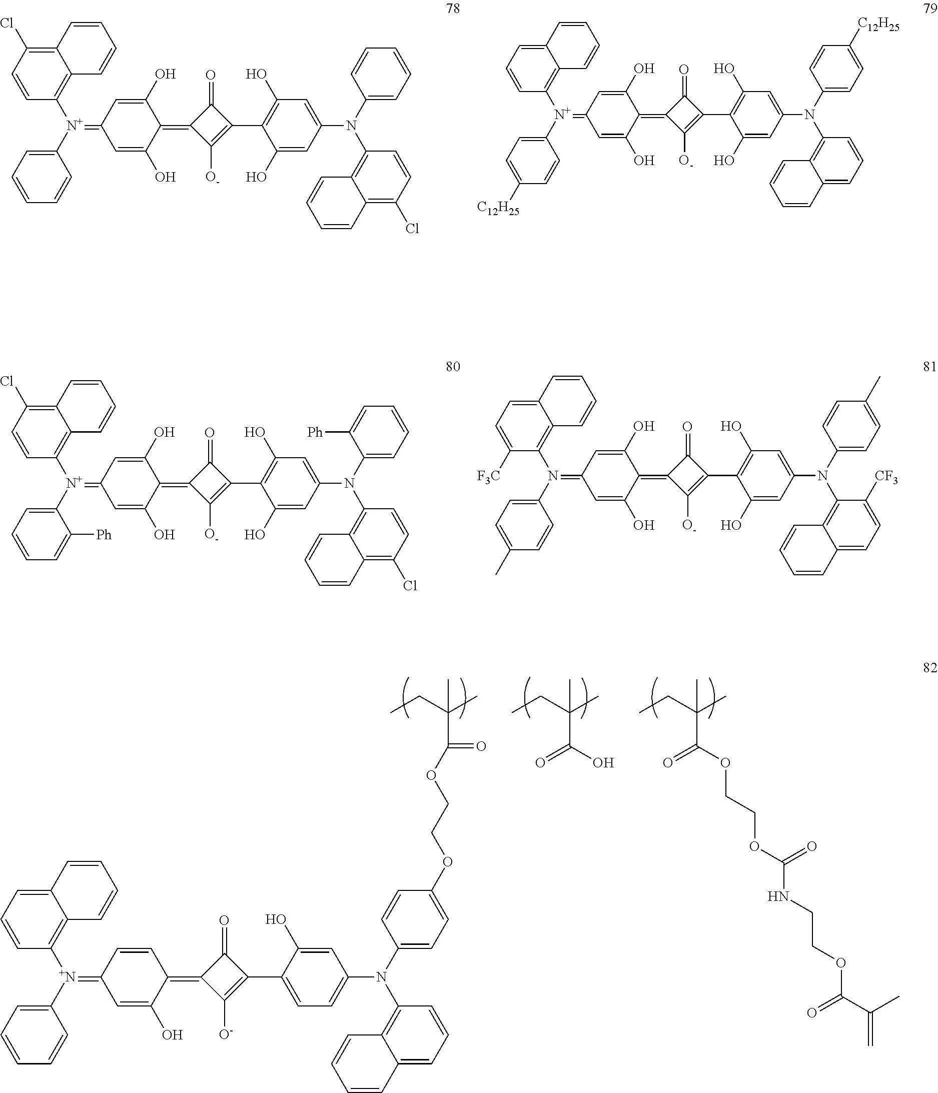

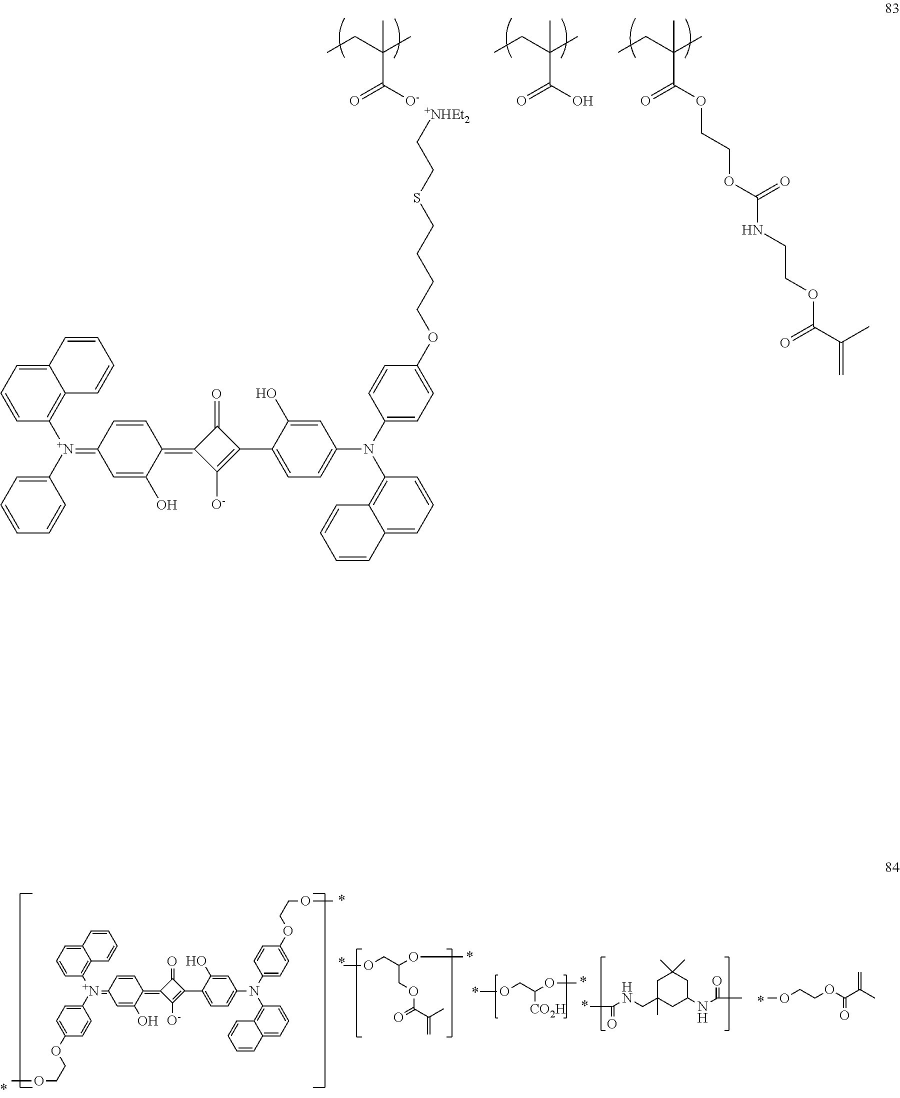

In the above chemical structural formulae, * represents a bonding position to **.

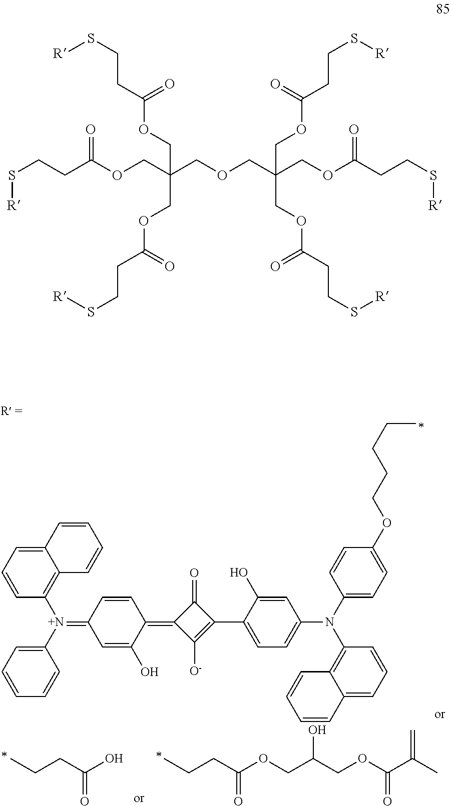

<Chromatic Colorant Different from Specific Compound>

The curable composition according to the first aspect contains a chromatic colorant different from the specific compound.

The curable composition according to the second aspect preferably contains a chromatic colorant different from the specific compound.

In the present disclosure, the chromatic colorant refers to a colorant other than a white colorant and a black colorant.

By appropriately selecting the chromatic coloring agent, it is possible to design the range of wavelengths which is absorbed by the curable composition according to the present disclosure and the cured product of the curable composition.

For example, by using a chromatic colorant having a maximum absorption wavelength shorter than that of the specific compound and the curable composition according to the present disclosure containing the specific compound, a cured film that absorbs light having a wavelength near the maximum absorption wavelength of the specific compound according to the present disclosure, and light having a wavelength near the maximum absorption wavelength of the chromatic colorant, which is a wavelength shorter than the wavelength near the maximum absorption wavelength of the specific compound, can be obtained.

That is, the cured film is a cured film that transmits light in a wavelength range other than the light having a wavelength near the maximum absorption wavelength of the specific compound according to the present disclosure, and the light having a wavelength near the maximum absorption wavelength of the chromatic colorant.

Since the specific compound in the present disclosure has excellent spectral characteristics, it can be said that the cured film has excellent spectral characteristics in the wavelength range on the maximum absorption wavelength side of the specific compound, which is included in the wavelength range of the transmitted light.

As an example, a pixel in a color filter that transmits green light having a wavelength of 530 nm to 580 nm can be produced by using a curable composition according to the present disclosure including a yellow colorant having a maximum absorption wavelength in a range of 400 nm to 500 nm and a specific compound having a maximum absorption wavelength in a range of 600 nm or more and less than 700 nm.

It is considered that, by including the specific compound, the pixel has a very small absorbance (for example, less than 8%) of light having a wavelength of 570 nm with respect to absorbance of light having a wavelength of 650 nm. Therefore, it is considered that the overlap of the transmission wavelength with the pixel that transmits red light (for example, light having a wavelength of 630 nm to 700 nm) (G/R overlap) becomes small.

In addition, since the specific compound has a small absorption wavelength peak width, in a case of being used as a pixel in a color filter, the curable composition may further include a green colorant in order to broaden the wavelength range of absorption.

As an example, a pixel that transmits green light having a wavelength of 530 nm to 580 nm and absorbs light in a wide wavelength range on a long wavelength side such as 600 nm to 750 nm can be produced by using a curable composition according to the present disclosure including a specific compound having a maximum absorption wavelength in a range of 600 nm or more and less than 700 nm, and a green colorant having a maximum absorption wavelength in a range of 600 nm or more and less than 700 nm and having a maximum absorption wavelength larger than that of the specific compound.

Also in the above-mentioned pixel, it is considered that the inclusion of the specific compound results in a very small absorbance (for example, less than 8%) of light having a wavelength of 570 nm with respect to absorbance of light having a wavelength of 650 nm. Therefore, it is considered that the overlap of the transmission wavelength with the color filter that transmits red light (for example, light having a wavelength of 630 nm to 700 nm) (G/R overlap) becomes small.

In addition, the curable composition according to the present disclosure may include all of the specific compound, the yellow colorant described above, and the green colorant described above.

In addition, in a case where the spectral characteristics of a colored pixel are adjusted by using the colorants of two or more colors in combination, two or more layers of films may be laminated to adjust to achieve the desired spectral characteristics. For example, in a case where the spectral characteristics of a green pixel are adjusted by using a specific compound, a yellow colorant, and optionally a green colorant in combination, a film containing a specific compound and a film containing a yellow colorant may be laminated to adjust to achieve the desired spectral characteristics. The green colorant may be included in any of the above films as needed. In addition, the lamination forms described in JP2017-167389A and JP2017-194560A can also be applied to the present disclosure.

Hereinafter, the chromatic colorant will be described with reference to specific examples.

[Yellow Colorant]

The chromatic colorant is preferably a yellow colorant from the viewpoint of forming the pixel that transmits green light.

In addition, the yellow colorant is preferably a yellow pigment from the viewpoint of light resistance and moisture resistance.

In addition, the average particle size of the yellow pigment is preferably 0.01 μm to 0.1 μm and more preferably 0.01 μm to 0.05 μm.

The yellow colorant is not particularly limited as long as it is a colorant exhibiting yellow, but preferably has a maximum absorption wavelength in a range of 400 nm to 500 nm, more preferably in a range of 450 nm to 480 nm, and still more preferably in a range of 450 nm to 460 nm.

The yellow colorant is preferably at least one selected from the group consisting of an azo compound and an isoindoline compound, more preferably an azo compound, and still more preferably an azo compound having a barbituric acid structure.

Specific examples of the yellow colorant include yellow pigments such as Color Index (C.I.) Pigment Yellow (also simply referred to as “Pigment Yellow”) 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, and 233; and yellow dyes such as C.I. Solvent Yellow 4, 82, 88, 14, 15, 24, 93, 94, 98, and 162. Pigment Yellow 233 is a quinoline-based yellow pigment.

The yellow colorant preferably includes at least one selected from the group consisting of Pigment Yellow 139, Pigment Yellow 150 and Pigment Yellow 185, and more preferably Pigment Yellow 150.

In addition, compounds having structures represented by Formulae (Y1) to (Y4) can also be used as a colorant Y.

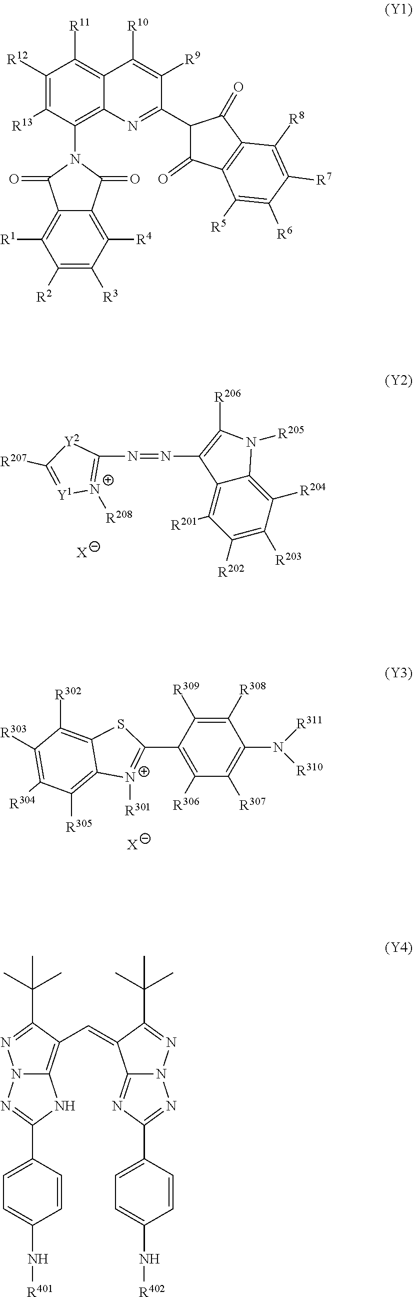

In Formula (Y1), R¹ to R¹³ each independently represent a hydrogen atom or a substituent, and adjacent groups among R¹ to R⁸ may be bonded to each other to form a ring. However, at least one set of two adjacent groups of R¹ to R⁸ is bonded to each other to form an aromatic ring.

In Formula (Y2), R²⁰⁵ and R²⁰⁸ each independently represent a hydrogen atom, an alkyl group, an aryl group, or a heteroaryl group, R²⁰¹ to R²⁰⁴, R²⁰⁶ and R²⁰⁷ each independently represent a hydrogen atom or a substituent, Y¹ represents a nitrogen atom or —CR^{Y1}—, Y² represents a sulfur atom or —NR^{Y2}—, R^{Y1} and R^{Y2} each independently represent a hydrogen atom, an alkyl group, an aryl group, or a heteroaryl group, and X represents a bis(sulfonyl)imide anion, a tris(sulfonyl)methide anion, or an anion having a boron atom.

In Formula (Y3), R³⁰¹, R³¹¹, and R³¹⁰ each independently represent a hydrogen atom, an alkyl group, an aryl group, or a heteroaryl group, R³⁰² to R³⁰⁵ and R³⁰⁶ to R³⁰⁹ each independently represent a hydrogen atom or a substituent, and X represents a bis(sulfonyl)imide anion, a tris(sulfonyl)methide anion, or an anion having a boron atom.

In Formula (Y4), R⁴⁰¹ and R⁴⁰² each independently represent SO₂R⁴³ or COR⁴⁰³; and R⁴⁰³ represents an alkyl group, an aryl group, or a heteroaryl group.

For details of Formulae (Y1) to (Y4), reference can be made to the description of paragraphs [0016] to [0046] of WO2017/082226A, the contents of which are incorporated in the present disclosure by reference.

In addition, quinophthalone compounds described in paragraphs [0011] to [0034] of JP2013-054339A, quinophthalone compounds described in paragraphs [0013] to [0058] of JP2014-026228A, and the like can also be used as the yellow colorant.

The curable composition may include only one type of yellow colorant or may include two or more types of yellow colorants.

The content of the yellow colorant is preferably 2% by mass to 40% by mass, more preferably 4% by mass to 30% by mass, and still more preferably 6% by mass to 20% by mass with respect to the total mass of the curable composition.

It is preferable that 50% by mass or more of the yellow colorant contained in the curable composition is at least one selected from an azo compound or an isoindoline compound (preferably an azo compound and more preferably an azo compound having a barbituric acid structure), more preferably 70% by mass or more, and still more preferably 90% by mass or more.

In addition, in the curable composition, it is preferable that 50% by mass or more of the yellow colorant contained in an absorbing layer is at least one selected from the group consisting of Pigment Yellow 139, Pigment Yellow 150, and Pigment Yellow 185 (preferably, Pigment Yellow 150), more preferably 70% by mass or more, and still more preferably 90% by mass or more.

[Green Colorant]

It is preferable that the chromatic colorant includes a green colorant from the viewpoint of forming the pixel that transmits green light.

In addition, the green colorant is preferably a green pigment from the viewpoint of light resistance and moisture resistance.

In addition, the average particle size of the green pigment is preferably 0.01 μm to 0.1 μm and more preferably 0.01 μm to 0.05 μm.

The green colorant is not particularly limited as long as it is a colorant exhibiting a green color, but preferably has a maximum absorption wavelength in a range of 600 nm to 700 nm, more preferably in a range of 620 nm to 695 nm, and particularly preferably in a range of 640 nm to 690 nm.

Examples of the green colorant include green pigments such as C.I. Pigment Green 7, 10, 36, 37, 58, and 59.

In addition, a halogenated zinc phthalocyanine pigment having an average number of halogen atoms of 10 to 14, an average number of bromine atoms of 8 to 12, and an average number of chlorine atoms of 2 to 5 in the molecule can also be used as the green colorant. Specific examples of the green colorant include compounds described in WO2015/118720A.

The curable composition may include only one type of green colorant or may include two or more types of green colorants.

The content of the green colorant is preferably 10% by mass to 70% by mass, more preferably 15% by mass to 60% by mass, and still more preferably 20% by mass to 50% by mass with respect to the total mass of the curable composition.

<Pigment Derivative>

The composition can contain a pigment derivative. Examples of the pigment derivative include an compound having a structure in which a part of a chromophore group is substituted with an acid group, a basic group, or a phthalimidomethyl group (for example, a derivative of the above-mentioned chromatic colorant). Examples of the chromophore group constituting the pigment derivative include a quinoline-based skeleton, a benzimidazolone-based skeleton, a diketopyrrolopyrrole-based skeleton, an azo-based skeleton, a phthalocyanine-based skeleton, an anthraquinone-based skeleton, a quinacridone-based skeleton, a dioxazine-based skeleton, a perinone-based skeleton, a perylene-based skeleton, a thioindigo-based skeleton, an isoindoline-based skeleton, an isoindolinone-based skeleton, a quinophthalone-based skeleton, a threne-based skeleton, and a metal complex-based skeleton, among which a quinoline-based skeleton, a benzimidazolone-based skeleton, a diketopyrrolopyrrole-based skeleton, an azo-based skeleton, a quinophthalone-based skeleton, an isoindoline-based skeleton, and a phthalocyanine-based skeleton are preferable, and an azo-based skeleton and a benzimidazolone-based skeleton are more preferable. The acid group contained in the pigment derivative is preferably a sulfo group or a carboxyl group and more preferably a sulfo group. The basic group contained in the pigment derivative is preferably an amino group and more preferably a tertiary amino group. With regard to specific examples of the pigment derivative, reference can be made to, for example, the description of paragraphs [0162] to [0183] of JP2011-252065A, the contents of which are incorporated herein by reference.

In a case where the composition contains a pigment derivative, the content of the pigment derivative is preferably 1 to 30 parts by mass and more preferably 3 to 20 parts by mass with respect to 100 parts by mass of the pigment. The pigment derivatives may be used alone or in combination of two or more thereof.

<Other Components>

The curable composition according to the present disclosure is a composition that can be finally cured to obtain a cured film.

In addition, the curable composition according to the present disclosure is preferably a composition that is capable forming a pattern of a cured film by pattern-wise exposure, for example. That is, the curable composition according to the present disclosure is preferably a negative composition.

In a case where the curable composition according to the present disclosure is a negative composition, for example, an aspect including a polymerization initiator, a polymerizable compound, and an alkali-soluble resin is preferable.

In addition, in a case where the curable composition according to the present disclosure is a positive composition, for example, there is an aspect including a photoacid generator, a polymer having a structural unit having a group in which an acid group is protected by an acid-decomposable group, and a polymer having a structural unit having a crosslinkable group.

Hereinafter, individual components included in the aspect in which the curable composition according to the present disclosure is a negative composition will be described. The individual components included in the aspect in which the curable composition according to the present disclosure is a positive composition include the individual components described in WO2014/003111A, and preferred aspects thereof are also the same.

<Polymerizable Compound>

The curable composition according to the present disclosure contains a polymerizable compound. The polymerizable compound that can be used in the present disclosure is preferably an ethylenically unsaturated compound and more preferably a compound having a terminal ethylenically unsaturated group.

As a group of such a compound, known compounds can be used without any particular limitation.

These compounds have a chemical form such as a monomer, a prepolymer, that is, a dimer, a trimer or an oligomer, or a mixture thereof and a copolymer thereof. Examples of the monomer and the copolymer thereof include unsaturated carboxylic acids (for example, acrylic acid, methacrylic acid, itaconic acid, crotonic acid, isocrotonic acid, and maleic acid), and esters and amides thereof, among which an ester of an unsaturated carboxylic acid with an aliphatic polyhydric alcohol compound, or an amide of an unsaturated carboxylic acid with an aliphatic polyvalent amine compound is preferably used. In addition, a product of an addition reaction of an unsaturated carboxylic acid ester or amide having a nucleophilic substituent such as a hydroxyl group, an amino group, or a mercapto group with a monofunctional or polyfunctional isocyanate or epoxy, and a product of a dehydration condensation reaction of such an unsaturated carboxylic acid ester or amide with a monofunctional or polyfunctional carboxylic acid are also suitably used. In addition, a product of an addition reaction of an unsaturated carboxylic acid ester or amide having an electrophilic substituent such as an isocyanate group or an epoxy group with a monofunctional or polyfunctional alcohol, amine or thiol, and further a product of a substitution reaction of an unsaturated carboxylic acid ester or amide having a leaving substituent such as a halogen group or a tosyloxy group with a monofunctional or polyfunctional alcohol, amine or thiol are also suitable. In addition, as another example, it is also possible to use a group of compounds substituted with unsaturated phosphonic acid, styrene, vinyl ether, or the like in place of the foregoing unsaturated carboxylic acid.

Specific examples of the monomer of an ester of an aliphatic polyhydric alcohol compound with an unsaturated carboxylic acid include acrylic acid esters such as ethylene glycol diacrylate, triethylene glycol diacrylate, 1,3-butanediol diacrylate, tetramethylene glycol diacrylate, propylene glycol diacrylate, neopentyl glycol diacrylate, trimethylolpropane triacrylate, trimethylolpropane tri(acryloyloxypropyl)ether, trimethylolethane triacrylate, hexanediol diacrylate, 1,4-cyclohexanediol diacrylate, tetraethylene glycol diacrylate, pentaerythritol diacrylate, pentaerythritol triacrylate, pentaerythritol tetraacrylate, dipentaerythritol diacrylate, dipentaerythritol hexaacrylate, sorbitol triacrylate, sorbitol tetraacrylate, sorbitol pentaacrylate, sorbitol hexaacrylate, tri(acryloyloxyethyl) isocyanurate, polyester acrylate oligomer, and isocyanuric acid ethylene oxide (EO)-modified triacrylate.

Examples of the methacrylic acid esters include tetramethylene glycol dimethacrylate, triethylene glycol dimethacrylate, neopentyl glycol dimethacrylate, trimethylolpropane trimethacrylate, trimethylolethane trimethacrylate, ethylene glycol dimethacrylate, 1,3-butanediol dimethacrylate, hexanediol dimethacrylate, pentaerythritol dimethacrylate, pentaerythritol trimethacrylate, pentaerythritol tetramethacrylate, dipentaerythritol dimethacrylate, dipentaerythritol hexamethacrylate, sorbitol trimethacrylate, sorbitol tetramethacrylate, bis[p-(3-methacryloxy-2-hydroxypropoxy)phenyl]dimethylmethane, and bis[p-(methacryloxyethoxy)phenyl]dimethylmethane.

In addition, a urethane-based addition polymerizable compound produced by using an addition reaction of an isocyanate group with a hydroxy group is also suitable, and specific examples thereof include a vinyl urethane compound containing two or more polymerizable vinyl groups in one molecule, which is obtained by addition of a vinyl monomer containing a hydroxy group represented by General Formula (I) to a polyisocyanate compound having two or more isocyanate groups in one molecule, which is described in JP1973-041708B (JP-S-48-041708B).

CH₂═C(R)COOCH₂CH(R′)OH (I)

where R and R′ each represent H or CH₃.

In addition, urethane acrylates described in JP1976-037193A (JP-S-51-037193A), JP1990-032293B (JP-H-02-032293B), and JP1990-016765B (JP-H-02-016765B), and urethane compounds having an ethylene oxide-based skeleton described in JP1983-049860B (JP-S-58-049860B), JP1981-017654B (JP-S-56-017654B), JP1987-039417B (JP-S-62-039417B), and JP1987-039418B (JP-S-62-039418B) are also suitable. Further, use of addition polymerizable compounds having an amino structure or a sulfide structure in the molecule, described in JP1989-277653A (JP-S-63-277653A), JP1989-260909A (JP-S-63-260909A), and JP1989-105238A (JP-H-01-105238A), makes it possible to obtain a curable composition having a very excellent photosensitizing speed.

Other examples of the polymerizable compound include compounds described in paragraphs [0178] to [0190] of JP2007-277514A.

In addition, the epoxy compounds described in JP2015-187211A may be used as the polymerizable compound.

The content of the polymerizable compound in the curable composition is preferably 1% to 90% by mass, more preferably 5% to 80% by mass, and still more preferably 10% to 70% by mass with respect to the total solid content of the composition. In a case where the content of the polymerizable compound is within the above range, the curing properties of the curable composition are excellent.

In particular, in a case where the curable composition according to the present disclosure is used for forming a colored pattern of a color filter, the content of the polymerizable compound is preferably 5% by mass to 50% by mass, more preferably 7% by mass to 40% by mass, and still more preferably 10% by mass to 35% by mass.

<Polymerization Initiator>

The curable composition according to the present disclosure preferably further includes a polymerization initiator, and more preferably further includes a photopolymerization initiator.

The photopolymerization initiator is not particularly limited as long as it has an ability to initiate polymerization of a polymerizable compound, and can be appropriately selected from known photopolymerization initiators. For example, a compound having photosensitivity to light in the ultraviolet region to the visible region is preferable. In addition, the photopolymerization initiator may be a compound that generates an active radical by causing some action with a photoexcited sensitizer. The photopolymerization initiator is preferably a photo-radical polymerization initiator.

Examples of the photopolymerization initiator include a halogenated hydrocarbon derivative (for example, a compound having a triazine skeleton or a compound having an oxadiazole skeleton), an acylphosphine compound, a hexaarylbiimidazole, an oxime compound, an organic peroxide, a thio compound, a ketone compound, an aromatic onium salt, an α-hydroxy ketone compound, and an α-amino ketone compound. From the viewpoint of exposure sensitivity, the photopolymerization initiator is preferably a trihalomethyltriazine compound, a benzyldimethylketal compound, an α-hydroxyketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, a halomethyloxadiazole compound, or a 3-aryl-substituted coumarin compound; more preferably a compound selected from an oxime compound, an α-hydroxyketone compound, an α-aminoketone compound, and an acylphosphine compound; and still more preferably an oxime compound. Regarding the photopolymerization initiator, reference can be made to the description of paragraphs [0065] to [0111] of JP2014-130173A and paragraphs [0274] to [0306] of JP2013-029760A, the contents of which are incorporated in the present disclosure by reference.

Examples of commercially available α-hydroxyketone compounds include IRGACURE-184, DAROCUR-1173, IRGACURE-500, IRGACURE-2959, and IRGACURE-127 (all of which are manufactured by BASF SE). Examples of commercially available α-aminoketone compounds include IRGACURE-907, IRGACURE-369, IRGACURE-379, and IRGACURE-379EG (all of which are manufactured by BASF SE). Examples of commercially available acylphosphine compounds include IRGACURE-819 and DAROCUR-TPO (both of which are manufactured by BASF SE).

Examples of the oxime compound include compounds described in JP2001-233842A, compounds described in JP2000-080068A, compounds described in JP2006-342166A, compounds described in J. C. S. Perkin II (1979, pp. 1653 to 1660), compounds described in J. C. S. Perkin II (1979, pp. 156 to 162), compounds described in Journal of Photopolymer Science and Technology (1995, pp. 202 to 232), compounds described in JP2000-066385A, compounds described in JP2000-080068A, compounds described in JP2004-534797A, compounds described in JP2006-342166A, compounds described in JP2017-019766A, compounds described in JP6065596B, compounds described in W2015/152153A, and compounds described in W2017/051680A. Specific examples of the oxime compound include 3-benzoyloxyiminobutan-2-one, 3-acetoxyiminobutan-2-one, 3-propionyloxyiminobutan-2-one, 2-acetoxyiminopentan-3-one, 2-acetoxyimino-1-phenylpropan-1-one, 2-benzoyloxyimino-1-phenylpropan-1-one, 3-(4-toluenesulfonyloxy)iminobutan-2-one, and 2-ethoxycarbonyloxyimino-1-phenylpropan-1-one. As commercially available oxime compounds, IRGACURE-OXE01, IRGACURE-OXE02, IRGACURE-OXE03, and IRGACURE-OXE04 (all of which are manufactured by BASF SE) are also suitably used. In addition, TRONLY TR-PBG-304, TRONLY TR-PBG-309, and TRONLY TR-PBG-305 (all of which are manufactured by CHANGZHOU TRONLY NEW ELECTRONIC MATERIALS CO., LTD), and ADEKA ARKLS NCI-930 and ADEKA OPTOMER N-1919 (photopolymerization initiator 2 of JP2012-014052A) (both of which are manufactured by ADEKA Corporation) can be mentioned as commercially available oxime compounds.

In addition, as the oxime compound other than the above-mentioned compounds, compounds described in JP2009-519904A in which an oxime is linked to an N-position of a carbazole ring; compounds described in U.S. Pat. No. 7,626,957B in which a hetero substituent is introduced into a benzophenone moiety; compounds described in JP2010-015025A and US2009-292039A in which a nitro group is introduced into a coloring agent moiety; ketoxime compounds described in WO2009/131189A; compounds described in U.S. Pat. No. 7,556,910B, which contain a triazine skeleton and an oxime skeleton in the same molecule; and compounds described in JP2009-221114A, which have a maximum absorption wavelength of 405 nm and satisfactory sensitivity to a g-ray light source, may be used.

In the present disclosure, an oxime compound having a fluorene ring can also be used as the photopolymerization initiator. Specific examples of the oxime compound having a fluorene ring include compounds described in JP2014-137466A, the contents of which are incorporated in the present disclosure by reference.

In the present disclosure, an oxime compound having a benzofuran skeleton can also be used as the photopolymerization initiator. Specific examples thereof include compounds OE-01 to OE-75 described in WO2015/036910A.

In the present disclosure, an oxime compound having a skeleton in which at least one benzene ring of a carbazole ring became a naphthalene ring can also be used as the photopolymerization initiator. Specific examples of such an oxime compound include compounds described in WO2013/083505A.

In the present disclosure, an oxime compound having a fluorine atom can also be used as the photopolymerization initiator. Specific examples of the oxime compound having a fluorine atom include compounds described in JP2010-262028A, Compounds 24 and 36 to 40 described in JP2014-500852A, and Compound (C-3) described in JP2013-164471A, the contents of which are incorporated in the present disclosure by reference.

In the present disclosure, an oxime compound having a nitro group can be used as the photopolymerization initiator. The oxime compound having a nitro group is also preferably a dimer. Specific examples of the oxime compound having a nitro group include compounds described in paragraphs [0031] to [0047] of JP2013-114249A, and paragraphs [0008] to [0012] and [0070] to [0079] of JP2014-137466A, compounds described in paragraphs [0007]to [0025] of JP4223071B, and ADEKA ARKLS NCI-831 (manufactured by ADEKA Corporation).

Specific examples of the oxime compound preferably used in the present disclosure are shown below, but the present disclosure is not limited thereto.

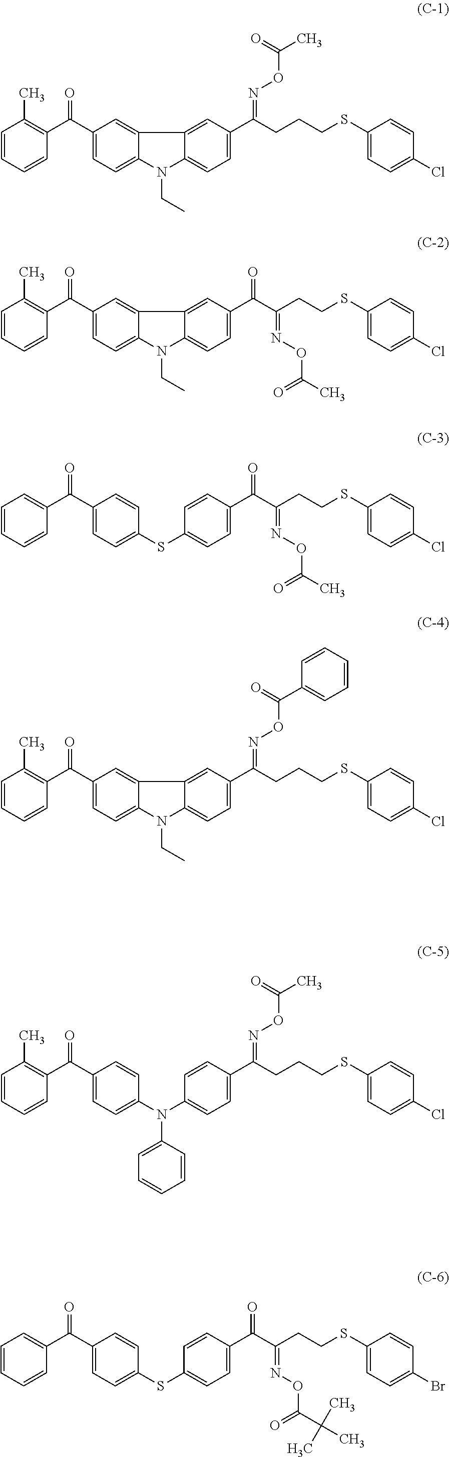 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1 ; CC(C)(C)C(=O)O/N=C(\CCSc1ccc(Br)cc1)C(=O)c1ccc(Sc2ccc(C(=O)c3ccccc3)cc2)cc1]

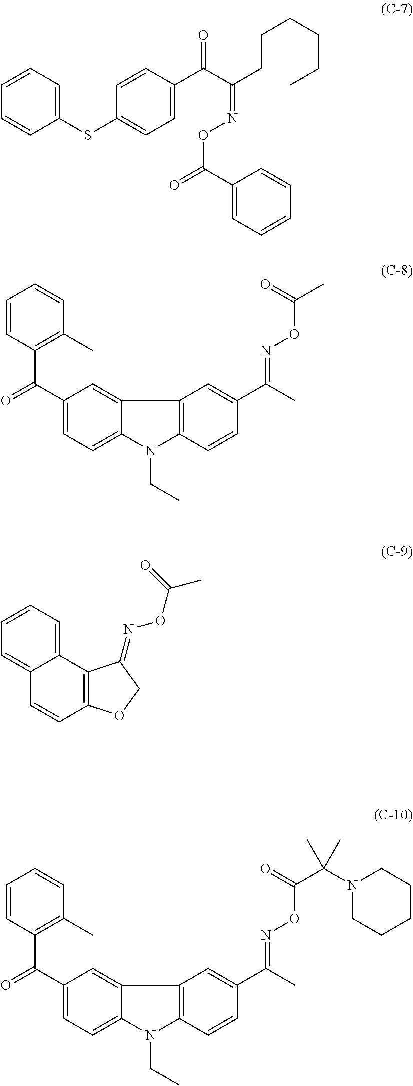 [SMILES: CCCCCC/C(=N/OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21 ; CC(=O)O/N=C1\COc2ccc3ccccc3c21 ; CCn1c2ccc(C(=O)c3ccccc3C)cc2c2cc(/C(C)=N/OC(=O)C(C)(C)N3CCCCC3)ccc21]

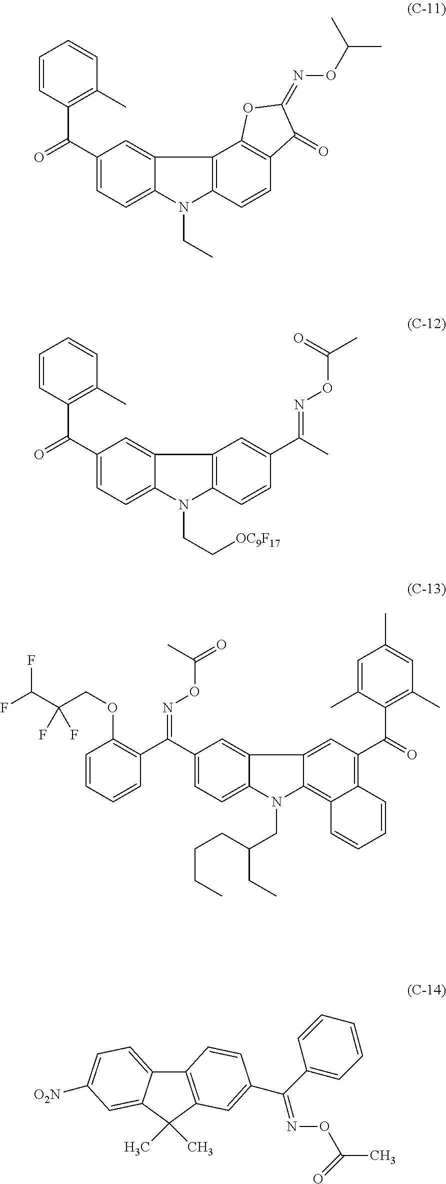

The oxime compound is preferably a compound having a maximum absorption wavelength in the wavelength range of 350 nm to 500 nm, and more preferably a compound having a maximum absorption wavelength in the wavelength range of 360 nm to 480 nm. In addition, the oxime compound is preferably a compound having a large absorbance at wavelengths of 365 nm and 405 nm.

The molar light absorption coefficient at a wavelength of 365 nm or 405 nm of the oxime compound is preferably 1,000 to 300,000, more preferably 2,000 to 300,000, and particularly preferably 5,000 to 200,000 from the viewpoint of sensitivity. The molar light absorption coefficient of the compound can be measured using a known method. For example, it is preferable to measure the molar light absorption coefficient of the compound with an ultraviolet-visible spectrophotometer (Cary-5 spectrophotometer manufactured by Varian Medical Systems, Inc.) using an ethyl acetate solvent at a concentration of 0.01 g/L.

In the present disclosure, a difunctional or tri- or higher functional photopolymerization initiator may be used as the photopolymerization initiator. Specific examples of such a photopolymerization initiator include dimers of oxime compounds described in JP2010-527339A, JP2011-524436A, WO2015/004565A, paragraphs [0417] to [0412] of JP2016-532675A, and paragraphs [0039] to [0055] of WO2017/033680A, Compound (E) and Compound (G) described in JP2013-522445A, and Cmpd 1 to 7 described in WO2016/034963A.

The polymerization initiators may be used alone or in combination of two or more thereof.

The content of the polymerization initiator in the curable composition is preferably 0.1% to 50% by mass, more preferably 0.5% to 30% by mass, and particularly preferably 1% to 20% by mass with respect to the total solid content of the composition. Within this range, satisfactory sensitivity and pattern formability can be obtained.

<Alkali-Soluble Resin>

The curable composition according to the present disclosure preferably contains at least one alkali-soluble resin.

The alkali-soluble resin is a high molecular weight polymer, and can be appropriately selected from alkali-soluble resins having at least one group (for example, a carboxyl group, a phosphoric acid group, or a sulfonic acid group) that promotes alkali solubility in a molecule (preferably a molecule having an acrylic-based copolymer or a styrene-based copolymer as a main chain). Of these, more preferred is an alkali-soluble resin which is soluble in an organic solvent and can be developed with a weak alkaline aqueous solution.

For example, a known radical polymerization method can be applied to the production of the alkali-soluble resin. Polymerization conditions such as temperature, pressure, type and amount of radical initiator, and type of solvent in a case of producing an alkali-soluble resin by a radical polymerization method can be easily set by those skilled in the art, and the polymerization conditions can also be determined experimentally.

The high molecular weight polymer is preferably a polymer having a carboxylic acid in a side chain thereof. Examples of such a high molecular weight polymer include polymers having a carboxylic acid in a side chain thereof, such as methacrylic acid copolymers, acrylic acid copolymers, itaconic acid copolymers, crotonic acid copolymers, maleic acid copolymers, and partially esterified maleic acid copolymers, such as those described in, for example, JP1984-044615A (JP-S-59-044615A), JP1979-034327B (JP-S-54-034327B), JP1983-012577B (JP-S-58-012577B), JP1979-025957B (JP-S-54-025957B), JP1984-053836A (JP-59-053836A), and JP1984-071048A (JP-S-59-071048A); acidic cellulose derivatives having a carboxylic acid in a side chain thereof, and polymers obtained by adding an acid anhydride to a polymer having a hydroxy group. Further, high molecular weight polymers having a (meth)acryloyl group in a side chain thereof are also preferred.

Specifically, a copolymer of (meth)acrylic acid and other monomers copolymerizable therewith is particularly suitable as the alkali-soluble resin.

Examples of other monomers copolymerizable with (meth)acrylic acid include (meth)acrylic acid esters, crotonic acid esters, vinyl esters, maleic acid diesters, fumaric acid diesters, itaconic acid diesters, (meth)acrylamides, styrenes, vinyl ethers, vinyl ketones, olefins, maleimides, and (meth)acrylonitriles.

Examples of (meth)acrylic acid esters include methyl (meth)acrylate, ethyl (meth)acrylate, n-propyl (meth)acrylate, isopropyl (meth)acrylate, n-butyl (meth)acrylate, isobutyl (meth)acrylate, t-butyl (meth)acrylate, amyl (meth)acrylate, n-hexyl (meth)acrylate, cyclohexyl (meth)acrylate, t-butyl cyclohexyl (meth)acrylate, 2-ethylhexyl (meth)acrylate, t-octyl (meth)acrylate, dodecy (meth)acrylate, octadecyl (meth)acrylate, acetoxyethyl (meth)acrylate, phenyl (meth)acrylate, 2-hydroxy ethyl (meth)acrylate, 2-hydroxypropyl (meth)acrylate, 3-hydroxypropyl (meth)acrylate, 4-hydroxybutyl (meth)acrylate, 2-methoxyethyl (meth)acrylate, 2-ethoxyethyl (meth)acrylate, 2-(2-methoxyethoxy)ethyl (meth)acrylate, 3-phenoxy-2-hydroxypropyl (meth)acrylate, 2-chloroethyl (meth)acrylate, glycidyl (meth)acrylate, 3,4-epoxycyclohexylmethyl (meth)acrylate, vinyl (meth)acrylate, 2-phenylvinyl (meth)acrylate, 1-propenyl (meth)acrylate, allyl (meth)acrylate, 2-aryloxyethyl (meth)acrylate, propargyl (meth)acrylate, benzyl (meth)acrylate, diethylene glycol monomethyl ether (meth)acrylate, diethylene glycol monoethyl ether (meth)acrylate, triethylene glycol monomethyl ether (meth)acrylate, triethylene glycol monoethyl ether (meth)acrylate, polyethylene glycol monomethyl ether (meth)acrylate, polyethylene glycol monoethyl ether (meth)acrylate, β-phenoxyethoxyethyl (meth)acrylate, nonylphenoxy polyethylene glycol (meth)acrylate, dicyclopentenyl (meth)acrylate, dicyclopentenyloxyethyl (meth)acrylate, trifluoroethyl (meth)acrylate, octafluoropentyl (meth)acrylate, perfluorooctylethyl (meth)acrylate, dicyclopentanyl (meth)acrylate, tribromophenyl (meth)acrylate, tribromophenyloxyethyl (meth)acrylate, and γ-butyrolactone (meth)acrylate.

The weight-average molecular weight of the alkali-soluble resin that can be used in the present disclosure is preferably 5,000 or more and more preferably 10,000 to 300,000, and the number-average molecular weight of the alkali-soluble resin that can be used in the present disclosure is preferably 1,000 or more and more preferably 2,000 to 250,000. The polydispersity (weight-average molecular weight/number-average molecular weight) is preferably in a range of 1.1 to 10 and more preferably in a range of 1.2 to 5. The alkali-soluble resin may be any of a random polymer, a block polymer, a graft polymer, or the like.

Other examples of the alkali-soluble resin include compounds described in paragraphs [0162] to [0175] of JP2007-277514A.

In addition, at least one selected from the group consisting of the first polymer compound and the second polymer compound according to the present disclosure can also be used as the alkali-soluble resin.

The content of the alkali-soluble resin in the curable composition is preferably 1% by mass to 20% by mass, more preferably 2% by mass to 15% by mass, and particularly preferably 3% by mass to 12% by mass with respect to the total solid content of the curable composition.

<Dispersant>

The curable composition according to the present disclosure may contain a specific compound, and a dispersant for dispersing a pigment such as a yellow pigment or a green pigment, which is added as necessary.

The dispersant is not particularly limited, and a known dispersant can be used as the dispersant for a pigment.

Examples of the dispersant include a polymer dispersant [for example, a polyamidoamine and a salt thereof, a polycarboxylic acid and a salt thereof, a high-molecular weight unsaturated acid ester, a modified polyurethane, a modified polyester, a modified poly(meth)acrylate, a (meth)acrylic copolymer, and a naphthalene sulfonic acid/formalin condensate], a polyoxyethylene alkyl phosphoric acid ester, a polyoxyethylene alkylamine, and an alkanolamine.

The polymer dispersants can be further classified into a linear polymer, a terminal-modified polymer, a graft type polymer, and a block type polymer, depending on its structure. The polymer dispersant is adsorbed on a surface of a pigment and therefore acts to prevent re-aggregation of the pigment. For this reason, examples of a preferred structure thereof include a terminal-modified polymer, a graft type polymer, and a block type polymer, which have an anchoring site for the surface of a pigment. Incidentally, also preferably used are the dispersants described in paragraphs [0028] to [0124] of JP2011-070156A, the contents of which are incorporated herein by reference and the dispersants described in JP2007-277514A, the contents of which are incorporated herein by reference.

The polymer dispersant preferably contains a structural unit having an acid group. In a case where the resin used as the dispersant contains a structural unit having an acid group, residues generated on the base of the pixel can be further reduced in a case where patterning is carried out by a photolithography method.

It is also preferable that the polymer dispersant is a graft copolymer. The graft copolymer has an affinity for a solvent due to a graft chain, which thus results in excellent pigment dispersibility and excellent dispersion stability over time. For details of the graft copolymer, reference can be made to the description in paragraphs [0025] to [0094] of JP2012-255128A, the contents of which are incorporated herein by reference. In addition, specific examples of the graft copolymer include, but are not limited to, P-1 and P-2 in the Examples which will be described later. The following resins are also resins having an acid group (alkali-soluble resins). In addition, examples of the graft copolymer include the resins described in paragraphs [0072] to [0094] of JP2012-255128A, the contents of which are incorporated herein by reference.

In addition, a polymer dispersant having an ethylenically unsaturated group may be used as the polymer dispersant. Examples of the ethylenically unsaturated group include a vinyl group, a vinyloxy group, an allyl group, a methallyl group, a (meth)acryloyl group, a vinylphenyl group, a cinnamoyl group, and a maleimide group, among which a (meth)acryloyl group, a vinylphenyl group, or a maleimide group is preferable, a (meth)acryloyl group is more preferable, and an acryloyl group is particularly preferable, from the viewpoint of reactivity.

Examples of the polymer dispersant having an ethylenically unsaturated group include, but are not limited to, P-3 and P-4 in the Examples which will be described later.

A commercially available product can also be used as the dispersant. For example, a product described in paragraph [0129] of JP2012-137564A can be used as the dispersant. For example, Disperbyk-111 (manufactured by BYK-Chemie GmbH) can be mentioned as the commercially available dispersant product. In addition, the resin described as the dispersant can also be used for purposes other than the dispersant. For example, such a resin can also be used as a binder.

In the present disclosure, the dispersants may be used alone or in combination of two or more thereof.

The content of the dispersant may be appropriately adjusted according to the pigment used, but is preferably 1 to 200 parts by mass with respect to 100 parts by mass of the total content of the specific compound and the pigment. The lower limit of the content of the dispersant is preferably 5 parts by mass or more and more preferably 10 parts by mass or more. The upper limit of the content of the dispersant is preferably 150 parts by mass or less and more preferably 100 parts by mass or less.

<Polymerization Inhibitor>

The curable composition according to the present disclosure preferably contains a polymerization inhibitor from the viewpoint of storage stability.

The polymerization inhibitor is not particularly limited, and a known polymerization inhibitor can be used.

Examples of the polymerization inhibitor include hydroquinone, p-methoxyphenol, di-t-butyl-p-cresol, pyrogallol, t-butylcatechol, benzoquinone, 4,4′-thiobis(3-methyl-6-t-butylphenol), 2,2′-methylenebis(4-methyl-6-t-butylphenol), an N-nitrosophenylhydroxyamine salt (an ammonium salt, a cerous salt, or the like), and 2,2,6,6-tetramethylpiperidine-1-oxyl. Incidentally, the polymerization inhibitor may function as an antioxidant.

The polymerization inhibitors may be used alone or in combination of two or more thereof.

The content of the polymerization inhibitor is preferably 0.1 ppm to 1,000 ppm, more preferably 1 ppm to 500 ppm, and particularly preferably 1 ppm to 100 ppm with respect to the total solid content of the curable composition, from the viewpoint of storage stability.

<Solvent>

The curable composition according to the present disclosure may contain a solvent.

Examples of the solvent include esters such as ethyl acetate, n-butyl acetate, isobutyl acetate, amyl formate, isoamyl acetate, isobutyl acetate, butyl propionate, isopropyl butyrate, ethyl butyrate, butyl butyrate, alkyl esters, methyl lactate, ethyl lactate, alkyl oxyacetates (such as methyl oxyacetates, ethyl oxyacetates, and butyl oxyacetates (for example, methyl methoxyacetate, ethyl methoxyacetate, butyl methoxyacetate, methyl ethoxyacetate, and ethyl ethoxyacetate), alkyl 3-oxypropionates (such as methyl 3-oxypropionates and ethyl 3-oxypropionates (for example, methyl 3-methoxypropionate, ethyl 3-methoxypropionate, methyl 3-ethoxypropionate, and ethyl 3-ethoxypropionate), alkyl 2-oxypropionates (such as methyl 2-oxypropionates, ethyl 2-oxypropionates, and propyl 2-oxypropionates (for example, methyl 2-methoxypropionate, ethyl 2-methoxypropionate, propyl 2-methoxypropionate, methyl 2-ethoxypropionate, ethyl 2-ethoxypropionate, methyl 2-oxy-2-methylpropionate, ethyl 2-oxy-2-methylpropionate, methyl 2-methoxy-2-methylpropionate, and ethyl 2-ethoxy-2-methylpropionate), methyl pyruvate, ethyl pyruvate, propyl pyruvate, methyl acetoacetate, ethyl acetoacetate, methyl 2-oxobutanoate, and ethyl 2-oxobutanoate;

ethers such as diethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, propylene glycol monomethyl ether, propylene glycol methyl ether acetate, propylene glycol ethyl ether acetate, and propylene glycol propyl ether acetate;

ketones such as methyl ethyl ketone, cyclohexanone, 2-heptanone, and 3-heptanone; and

aromatic hydrocarbons such as toluene and xylene.

Among these, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, ethyl carbitol acetate, butyl carbitol acetate, propylene glycol methyl ether acetate, and the like are suitable.

The solvents may be used alone or in combination of two or more thereof.

<Sensitizer>

The curable composition according to the present disclosure may contain a sensitizer for the purpose of improving the radical generation efficiency of the radical initiator and widening the photosensitive wavelength. The sensitizer that can be used in the present disclosure is preferably a sensitizer that sensitizes the above-mentioned photopolymerization initiator by an electron transfer mechanism or an energy transfer mechanism.

The sensitizer that can be used in the present disclosure includes those belonging to the compounds listed below and having an absorption wavelength in the wavelength range of 300 nm to 450 nm.

Preferred examples of the sensitizer include those belonging to the following compounds and having an absorption wavelength in the wavelength range of 330 nm to 450 nm.

Examples of the sensitizer include polynuclear aromatics (for example, phenanthrene, anthracene, pyrene, perylene, triphenylene, and 9,10-dialkoxyanthracene), xanthenes (for example, fluorescein, eosin, erythrosine, rhodamine B, and rose bengal), thioxanthones (isopropyl thioxanthone, diethyl thioxanthone, and chlorothioxanthone), cyanines (for example, thiacarbocyanine and oxacarbocyanine), merocyanines (for example, merocyanine and carbomerocyanine), phthalocyanines, thiazines (for example, thionine, methylene blue, and toluidine blue), acridines (for example, acridine orange, chloroflavin, and acriflavine), anthraquinones (for example, anthraquinone), squaliums (for example, squalium), acridine orange, coumarins (for example, 7-diethylamino-4-methylcoumarin), ketocoumarins, phenothiazines, phenazines, styrylbenzenes, azo compounds, diphenylmethane, triphenylmethane, distyrylbenzenes, carbazoles, porphyrins, spiro compounds, quinacridones, indigo, styryl, pyrylium compounds, pyrromethene compounds, pyrazolotriazole compounds, benzothiazole compounds, barbituric acid derivatives, thiobarbituric acid derivatives, aromatic ketone compounds such as acetophenone, benzophenone, thioxanthone, and Michler's ketone, and heterocyclic compounds such as N-aryloxazolidinone. Further, other examples of the sensitizer include the compounds described in EP568993B, U.S. Pat. Nos. 4,508,811A, 5,227,227A, JP2001-125255A, JP1999-271969A (JP-H-11-271969A), and the like.

The sensitizers may be used alone or in combination of two or more thereof.

From the viewpoint of light absorption efficiency in a deep portion and initiation decomposition efficiency, the content of the sensitizer in the curable composition according to the present disclosure is preferably 0.1% to 20% by mass and more preferably 0.5% to 15% by mass with respect to the total solid content of the curable composition.

<Co-Sensitizer>

The curable composition according to the present disclosure may contain a co-sensitizer. The co-sensitizer has a function such as further improving the sensitivity of a sensitizing dye and an initiator to actinic radiation, or preventing the inhibition of polymerization of a polymerizable compound due to oxygen.

In addition, examples of the co-sensitizer include the compounds described in paragraphs [0233] to [0241] of JP2007-277514A.

From the viewpoint of improving the curing rate by balancing polymerization growth rate and chain transfer, the content of the co-sensitizer is preferably in a range of 0.1% to 30% by mass, more preferably in a range of 0.5% to 25% by mass, and still more preferably in a range of 1% to 20% by mass with respect to the mass of the total solid content of the curable composition.

<Other Components>

The curable composition according to the present disclosure may contain, as necessary, various additives such as a fluorine-based organic compound, a thermal polymerization inhibitor, a photopolymerization initiator, other fillers, a polymer compound other than an alkali-soluble resin and a dispersant, a surfactant, an adhesion promoter, an antioxidant, an ultraviolet absorber, and an aggregation inhibitor.

Examples of other components include the compounds described in paragraphs [0238] to [0249] of JP2007-277514A.

<Preparation of Curable Composition>

The method for preparing the curable composition according to the present disclosure is not particularly limited, and the curable composition can be obtained by mixing individual components contained in the curable composition by a known method.

In addition, in order to improve the dispersibility of the specific compound and the chromatic colorant, the curable composition according to the present disclosure may be prepared in such a manner that the specific compound and the dispersant are mixed to prepare a dispersion liquid of the specific compound, the chromatic colorant and the dispersant are mixed to prepare a dispersion liquid of the chromatic colorant, and then these dispersion liquids and other components are further mixed.

In addition, filtration may be carried out through a filter in order to remove a foreign material or reduce defects. Any filter can be used without particular limitation as long as it has been conventionally used for filtration or the like.

(Cured Product)

The cured product according to the present disclosure is a cured product obtained by curing the curable composition according to the present disclosure.

The curing method is not particularly limited, and examples thereof include curing by exposure to actinic rays such as ultraviolet light and curing by heating.

The cured product according to the present disclosure is preferably in the form of a thin film, for example.

The cured product according to the present disclosure is suitably used as a color filter, an infrared absorption filter, a black matrix provided between pixels of the color filter, a refractive index adjusting film, or the like, and is particularly suitably used as the color filter.

(Color Filter and Production Method Thereof)

The color filter according to the present disclosure comprises the cured product according to the present disclosure.

The color filter according to the present disclosure preferably comprises the cured product according to the present disclosure on a support.

In the color filter, the cured product according to the present disclosure is preferably a pixel of the color filter and more preferably a green pixel of the color filter.

In addition, the cured product according to the present disclosure and another colored film (for example, a colored film containing the above-mentioned yellow colorant) may be overlapped to form one color filter pixel.

Hereinafter, the color filter according to the present disclosure will be described in detail through the production method thereof.

(First Aspect of Method for Producing Color Filter)

A first aspect of the method for producing a color filter according to the present disclosure includes a step of applying the curable composition according to the present disclosure onto a support to form a composition film (composition film forming step), a step of exposing the formed composition film to light in a pattern-wise manner (hereinafter, abbreviated as “exposing step” where appropriate), and a step of developing the composition film after exposure to form a colored pattern (hereinafter, abbreviated as “developing step” where appropriate).

Hereinafter, individual steps will be described.

<Composition Film Forming Step>

In the composition film forming step, the curable composition according to the present disclosure is applied onto a support to form a composition film.

Examples of the support which can be used in the present step include a soda glass, a Pyrex (registered trademark) glass, a quartz glass, and those glasses with a transparent conductive film attached thereto which are used in a liquid crystal display element or the like, a photoelectric conversion element substrate used in an imaging element or the like, for example, a silicon substrate, and a complementary metal oxide film semiconductor (CMOS). On these substrates, a black stripe, which isolates individual pixels, is formed in some cases.

In addition, on these substrates, as necessary, an undercoat layer (another layer) may be provided for improving adhesion with an upper layer, preventing diffusion of a substance, or flattening a substrate surface.

As the method for applying the curable composition according to the present disclosure onto the support, various application methods such as slit coating, ink jet method, spin coating, cast coating, roll coating, and screen printing can be applied.

The coating film thickness of the curable composition is preferably 0.1 μm to 10 μm, more preferably 0.2 μm to 5 μm, and still more preferably 0.2 μm to 3 μm.

The composition film applied onto the support may be dried (pre-baked) at a temperature of 50° C. to 140° C. for 10 seconds to 300 seconds using a hot plate, an oven, or the like.

<Exposing Step>

In the exposing step, the composition film formed in the composition film forming step is exposed in a pattern-wise manner. The method of exposing the composition film to light in a pattern-wise manner may be, for example, a method of exposing the composition film to light through a mask having a predetermined mask pattern.

In the present step, in a case where the curable composition according to the present disclosure is a negative curable composition, a light-irradiated portion can be cured. In a case where the curable composition according to the present disclosure is a positive curable composition, the solubility of the light-irradiated portion in a developer increases.

As the radiation that can be used in the exposure, ultraviolet rays such as g-line and i-line are particularly preferably used. The exposure amount is preferably 5 mJ/cm² to 1500 mJ/cm², more preferably 10 mJ/cm² to 1000 mJ/cm², and most preferably 10 mJ/cm² to 500 mJ/cm².

In a case where the color filter according to the present disclosure is for a liquid crystal display element, the exposure amount is preferably 5 mJ/cm² to 200 mJ/cm², more preferably 10 mJ/cm² to 150 mJ/cm², and most preferably 10 mJ/cm² to 100 mJ/cm², in the above range. In addition, in a case where the color filter according to the present disclosure is for a solid-state imaging element, the exposure amount is preferably 30 mJ/cm² to 1500 mJ/cm², more preferably 50 mJ/cm² to 1000 mJ/cm², and most preferably 80 mJ/cm² to 500 mJ/cm², in the above range.

<Developing Step>

Next, by carrying out a development treatment, an unexposed portion in the exposing step is eluted in a developer, and therefore a photocured portion is obtained as a colored pattern. The developer is not particularly limited as long as it can remove the curable composition in an uncured portion, and a known developer can be used. Specifically, a combination of various organic solvents or an alkaline aqueous solution can be used as the developer.

The development temperature is preferably 20° C. to 30° C., and the development time is preferably 20 seconds to 90 seconds.

Examples of the organic solvent include the above-mentioned solvents that can be used in a case of preparing the pigment dispersion composition or curable composition according to the present disclosure.

As to the alkaline aqueous solution, an alkaline aqueous solution obtained by diluting an alkaline compound, such as sodium hydroxide, potassium hydroxide, sodium carbonate, sodium hydrogen carbonate, sodium silicate, sodium metasilicate, ammonia water, ethylamine, diethylamine, dimethylethanolamine, tetramethylammonium hydroxide, tetraethylammonium hydroxide, choline, pyrrole, piperidine, or 1,8-diazabicyclo-[5.4.0]-7-undecene, with pure water so as to have a concentration of 0.001% by mass to 10% by mass and preferably 0.01% by mass to 1% by mass is preferably used as the developer.

In addition, in a case where the developer consisting of such an alkaline aqueous solution is used, an aspect of washing (rinsing) with pure water after development is also preferred.

After the developing step, an excess developer may be washed away and drying may be carried out, followed by a heat treatment (post-baking).

The post-baking is a heat treatment after development, and preferably a heat curing treatment at 100° C. to 240° C. is carried out. In a case where the substrate is a glass substrate or a silicon substrate, 200° C. to 240° C. is preferable in the above temperature range. The post-baking treatment can be carried out continuously or batchwise using a heating unit such as a hot plate, a convection oven (hot air circulation dryer), or a high-frequency heater such that the coating film after development is in the above condition.

A color filter having desired hues is produced by repeating the above-mentioned steps of the composition film forming step, the exposing step, and the developing step (further, the heat treatment if necessary) only a number of times corresponding to the number of desired hues.

In a case where a film is formed by applying the curable composition according to the present disclosure onto a substrate, the dry thickness of the film is preferably 0.3 μm to 5.0 μm, more preferably 0.5 μm to 3.5 μm, and still more preferably 1.0 μm to 2.5 μm.

Examples of the substrate include a non-alkali glass, a soda glass, a Pyrex (registered trademark) glass, a quartz glass, and those glasses with a transparent conductive film attached thereto which are used in a liquid crystal display element or the like, a photoelectric conversion element substrate used in a solid-state imaging element or the like, for example, a silicon substrate, and a plastic substrate. A black stripe for isolating individual pixels is preferably formed on these substrates.

The plastic substrate preferably has a gas barrier layer and/or a solvent resistant layer on the surface thereof.

The above production method is a method for producing a pixel of a color filter, but according to the curable composition according to the present disclosure, for example, a black matrix provided between the pixels of the color filter is also produced. The black matrix can be formed, for example, by carrying out pattern-wise exposure, alkali development, and then post-baking to accelerate the curing of the film in the same manner as in the above-mentioned pixel production method, except that a black colorant such as carbon black or titanium black is added as the colorant to the curable composition according to the present disclosure.

(Second Aspect of Method for Producing Color Filter)

A second aspect of the method for producing a color filter according to the present disclosure includes a step of applying the curable composition according to the present disclosure onto a support and curing the applied curable composition to form a cured product (cured product forming step); a step of forming a photoresist layer on the cured product (photoresist layer forming step); a step of exposing the photoresist layer to light in a pattern-wise manner and developing the exposed photoresist layer to form a resist pattern (resist pattern forming step); and a step of etching the cured product through the resist pattern (etching step). Hereinafter, individual steps will be described.

<Cured Product Forming Step>

In the cured product forming step, the curable composition according to the present disclosure is applied onto a support and cured to form a cured product.

The support in the composition film forming step described above is preferably used as the support.

In addition, the application method in the composition film forming step described above is preferably used as the method for applying the curable composition.

The method for curing the applied curable composition is not particularly limited, and it is preferable to cure the applied curable composition by light or heat.

In a case where the curable composition is cured by light, the light may be appropriately selected according to the initiator included in the composition, but for example, ultraviolet rays such as g-line and i-line are preferably used. The exposure amount is preferably 5 mJ/cm² to 1500 mJ/cm², more preferably 10 mJ/cm² to 1000 mJ/cm², and most preferably 10 mJ/cm² to 500 mJ/cm².

In a case where the curable composition is cured by heat, the heating temperature is preferably 120° C. to 250° C. and more preferably 160° C. to 230° C. The heating time varies depending on the heating unit, but is preferably about 3 to 30 minutes in a case of being heated on a hot plate and preferably about 30 to 90 minutes in a case of being heated in an oven.

<Photoresist Layer Forming Step>

In the photoresist layer forming step, a photoresist layer is formed on the cured product.

In the formation of the photoresist layer, for example, a known negative or positive photosensitive composition is used, and a positive photosensitive composition is preferable.

The photoresist layer is obtained by applying the photosensitive composition onto the cured product and drying the applied photosensitive composition as necessary.

The method for forming the photoresist layer is not particularly limited, and may be carried out by a known method.

The thickness of the photoresist layer is preferably 0.1 μm to 3 μm, more preferably 0.2 μm to 2.5 μm, and still more preferably 0.3 μm to 2 μm.

<Resist Pattern Forming Step>

In the resist pattern forming step, the photoresist layer is exposed in a pattern-wise manner and developed to form a resist pattern.

The exposure and development are not particularly limited and are carried out by a known method.

<Etching Step>

In the etching step, the cured product is etched through the resist pattern.

The etching method is not particularly limited, and may be carried out by a known method, for example, a dry etching method.

<Step of Peeling Resist Pattern>

The second aspect of the method for producing a color filter according to the present disclosure may further include a step of peeling the resist pattern after the etching step.

The method of peeling the resist pattern is not particularly limited, and a known method is used.

(Image Display Device)

The image display device according to the present disclosure (for example, a liquid crystal display device, an organic electroluminescence (EL) display device, or an electronic paper) includes the color filter according to the present disclosure.

Specifically, for example, an alignment film is formed on an inner surface side of the color filter, the alignment film is opposed to an electrode substrate, and a gap portion therebetween is filled with liquid crystal and then sealed, whereby a liquid crystal panel that is the image display device according to the present disclosure is obtained.

The definition of the liquid crystal display device or details of the respective display devices are described in, for example, “Electronic Display Device (Akio Sasaki, Kogyo Chosakai Publishing Co., Ltd., published in 1990)”, “Display Device (Sumiaki Ibuki, Sangyo Tosho Co., Ltd., published in 1989)”, and the like. In addition, the liquid crystal display device is described in, for example, “Next-Generation Liquid Crystal Display Technology (edited by Tatsuo Uchida, Kogyo Chosakai Publishing Co., Ltd., published in 1994)”. The liquid crystal display device to which the present disclosure can be applied is not particularly limited, and for example, the present disclosure can be applied to various types of liquid crystal display devices described in the “Next-Generation Liquid Crystal Display Technology”.

(Solid-State Imaging Element)

The solid-state imaging element according to the present disclosure (for example, an image sensor such as a charge coupled device (CCD) or a complementary metal oxide semiconductor (CMOS)) includes the color filter according to the present disclosure.

For example, the solid-state imaging element according to the present disclosure can be obtained by forming a color filter on a light-receiving element.

Specifically, the solid-state imaging element according to the present disclosure has a configuration which has a plurality of photodiodes constituting a light-receiving area of a solid-state imaging element (a CCD image sensor, a CMOS image sensor, or the like) and transfer electrodes consisting of polysilicon or the like, on a substrate; a light shielding film consisting of tungsten or the like onto the photodiodes and the transfer electrodes, which has openings only over the light-receiving portion of the photodiode; a device consisting of silicon nitride or the like, which is formed so as to cover the entire surface of the light shielding film and the light-receiving portion of the photodiodes, on the light shielding film; and a color filter for a solid-state imaging element according to the present disclosure on the device.

Further, the solid-state imaging element according to the present disclosure may have, for example, a configuration having a light collecting unit (for example, a microlens; the same applies hereinafter) on the device protective layer and below the color filter (on the side close to the support), or a configuration having the light collecting unit on the color filter.

### EXAMPLES

Hereinafter, the present disclosure will be described in more detail with reference to Examples, but the present disclosure is not limited thereto.

In the Examples, “%” and “part(s)” refer to “% by mass” and “part(s) by mass”, respectively, unless otherwise specified. In addition, in the polymer compound, the molecular weight is a weight-average molecular weight (Mw) and the proportion of the structural unit is a mole percentage, unless otherwise specified.

The weight-average molecular weight (Mw) is a value measured in terms of polystyrene by gel permeation chromatography (GPC).

In addition, in the present examples, compound 1 to compound 81 which are specific compounds have the same meanings as the compound 1 to the compound 81 in the above-mentioned specific examples.

<Synthesis of Compound Represented by Formula 1>

[Synthesis of Compound 1]

3-methoxyaniline (2.20 g, 17.9 mmol), bromobenzene (17 mmol), sodium tert-butoxide (4.08 g, 42.5 mmol), tri-tert-butylphosphonium tetrafluoroborate (0.49 g, 1.7 mmol), and tris(dibenzylideneacetone)palladium (0) (0.62 g, 0.68 mmol) were stirred in toluene (85 mL) at room temperature for 3 hours under a nitrogen stream. After the completion of the reaction was confirmed by NMR, 1-bromonaphthalene (3.52 g, 17 mmol) was added thereto, followed by stirring at 100° C. for 12 hours under a nitrogen stream. After cooling to room temperature, the mixture was filtered through celite and washed with toluene. The resulting filtrate was concentrated to obtain intermediate A.

The intermediate A was dissolved in chloroform (200 mL), and a boron tribromide dichloromethane solution (1 mmol/mL, 45 mL) was slowly added thereto at 0° C. under a nitrogen stream. The mixture was heated and stirred under reflux for 6 hours. After cooling to 0° C., water cooled to 0° C. was slowly added thereto, followed by liquid separation with chloroform and then concentration. The resulting mixture was purified by column chromatography to obtain intermediate B.

Conversion into squarylium was carried out by the method described in Chem. Mater., 2011, 23, 4789-4798.

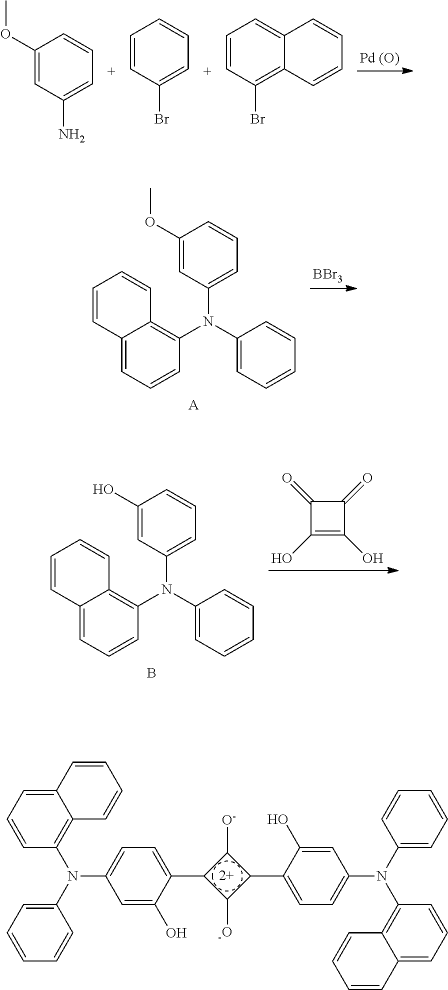

[Synthesis of Compound 25]

3-methoxyaniline (2.09 g, 17 mmol), 1-bromonaphthalene (7.22 g, 34.9 mmol), sodium tert-butoxide (4.08 g, 42.5 mmol), tri-tert-butylphosphonium tetrafluoroborate (0.49 g, 1.7 mmol), and tris(dibenzylideneacetone)palladium (0) (0.62 g, 0.68 mmol) were stirred in toluene (85 mL) at 100° C. for 12 hours under a nitrogen stream. After cooling to room temperature, the mixture was filtered through celite and washed with toluene.

The resulting filtrate was concentrated to obtain intermediate C.

Conversion into squarylium was carried out in the same manner as in the synthesis of the compound 1, except that the intermediate C was used in place of the intermediates A and B, whereby compound 25 was obtained.

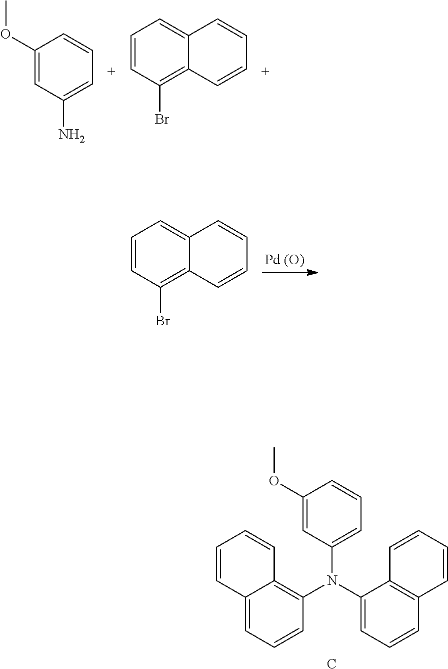

In addition, the compounds in Table 1 below used in the Examples were synthesized by appropriately adjusting the raw materials and the amounts thereof used with reference to the synthesis method of the compound 1 or the compound 25.

<Characteristic Evaluation of Compound Represented by Formula 1>

Using the compounds shown in Table 1 below, the maximum absorption wavelength (λmax) and the half-width (cm⁻¹) thereof were evaluated.

(Measurement of Maximum Absorption Wavelength)

50 mg of each compound shown in Table 1 below was dissolved in 200 mL of chloroform, and chloroform was added to 2 mL of this solution to make 200 mL. This solution was measured at wavelengths of from 400 nm to 800 nm using a Cary 5000 UV-Vis-NIR spectrophotometer (manufactured by Agilent Technologies, Inc.) to measure the maximum absorption wavelength. The evaluation results are shown in Table 1.

[Measurement of Half-Width]

In a wavelength-absorbance curve obtained in the measurement of the maximum absorption wavelength, given that the absorbance at the maximum absorption wavelength is 1.0, the width of the wavelength peak at which the absorbance becomes 0.5 is defined as a half-width (full width at half maximum). The evaluation results are shown in Table 1.

TABLE 1

| | Maximum | |
|---|---|---|
| | absorption | |
| | wavelength | |
| Specific | Λmax | Half-width |
| compound | (nm) | (cm-1) |
| Compound 1 | 670 | 1240 |
| Compound 2 | 675 | 1270 |
| Compound 3 | 675 | 1270 |
| Compound 4 | 675 | 1230 |
| Compound 7 | 680 | 1230 |
| Compound 10 | 680 | 1320 |
| Compound 11 | 680 | 1230 |
| Compound 12 | 665 | 1240 |
| Compound 14 | 670 | 1310 |
| Compound 15 | 675 | 1360 |
| Compound 16 | 680 | 1300 |
| Compound 17 | 660 | 1270 |
| Compound 18 | 675 | 1270 |
| Compound 19 | 685 | 1300 |
| Compound 20 | 670 | 1270 |
| Compound 22 | 675 | 1360 |
| Compound 25 | 680 | 1230 |
| Compound 26 | 665 | 1240 |
| Compound 33 | 665 | 1240 |
| Compound 35 | 660 | 1220 |
| Compound 37 | 665 | 1230 |
| Compound 42 | 670 | 1280 |
| Compound 46 | 690 | 1340 |
| Compound 49 | 670 | 1370 |
| Compound 50 | 675 | 1380 |
| Compound 51 | 685 | 1280 |
| Compound 53 | 680 | 1390 |
| Compound 55 | 685 | 1400 |
| Compound 57 | 675 | 1390 |
| Compound 63 | 680 | 1400 |
| Compound 72 | 695 | 1290 |
| Compound 73 | 695 | 1380 |
| Compound 78 | 665 | 1280 |
| Comparative | 690 | 1590 |
| Compound 1 | | |
| Comparative | 710 | 1280 |
| Compound 2 | | |

In Table 1, the details of Comparative Compound 1 and Comparative Compound 2 are as follows.

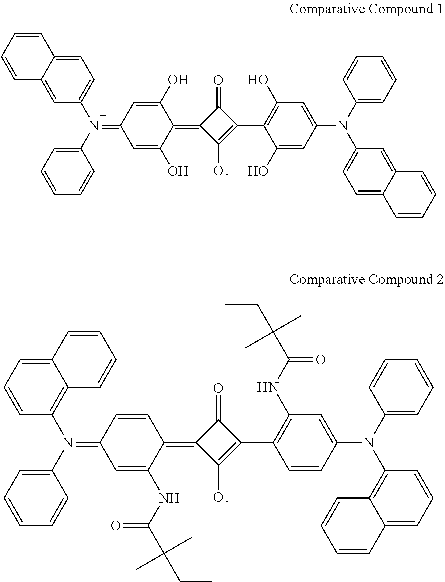

<Characteristic Evaluation of Cured Film>

[Preparation of Pigment Dispersion Liquid]

Raw materials shown in Table 2 below were mixed in parts by mass shown in Table 2, 230 parts by mass of zirconia beads having a diameter of 0.3 mm were added thereto, a dispersion treatment was carried out for 5 hours using a paint shaker, and the beads were separated by filtration to produce a dispersion liquid.

TABLE 2

| | Colorant | | Pigment derivative | | Dispersant | | Solvent | |
|---|---|---|---|---|---|---|---|---|
| | Type | Parts by mass | Type | Parts by mass | Type | Parts by mass | Type | Parts by mass |
| Yellow dispersion | PY185 | 11.57 | B-1 | 1.39 | P-1 | 4.54 | PGMEA | 82.50 |
| liquid 1 | | | | | | | | |
| Yellow dispersion | py139 | 11.57 | B-1 | 1.39 | P-1 | 4.54 | PGMEA | 82.50 |
| liquid 2 | | | | | | | | |
| Yellow dispersion | PY150 | 11.57 | B-1 | 1.39 | P-1 | 4.54 | PGMEA | 82.50 |
| liquid 3 | | | | | | | | |
| Yellow dispersion | PY185 | 11.57 | B-1 | 1.39 | P-2 | 4.54 | PGMEA | 82.50 |
| liquid 4 | | | | | | | | |
| Yellow dispersion | PY185 | 11.57 | B-1 | 1.39 | P-3 | 4.54 | PGMEA | 82.50 |
| liquid 5 | | | | | | | | |
| Yellow dispersion | PY185 | 11.57 | B-1 | 1.39 | P-4 | 4.54 | PGMEA | 82.50 |
| liquid 6 | | | | | | | | |
| Green dispersion | PY185 | 5.90 | B-1 | 1.39 | P-1 | 4.54 | PGMEA | 82.50 |
| liquid 1 | PG36 | 5.67 | | | | | | |
| Green dispersion | PY185 | 5.90 | B-1 | 1.39 | P-1 | 4.54 | PGMEA | 82.50 |
| liquid 2 | PG58 | 5.67 | | | | | | |

The details of the compounds shown in Table 2 are as follows.

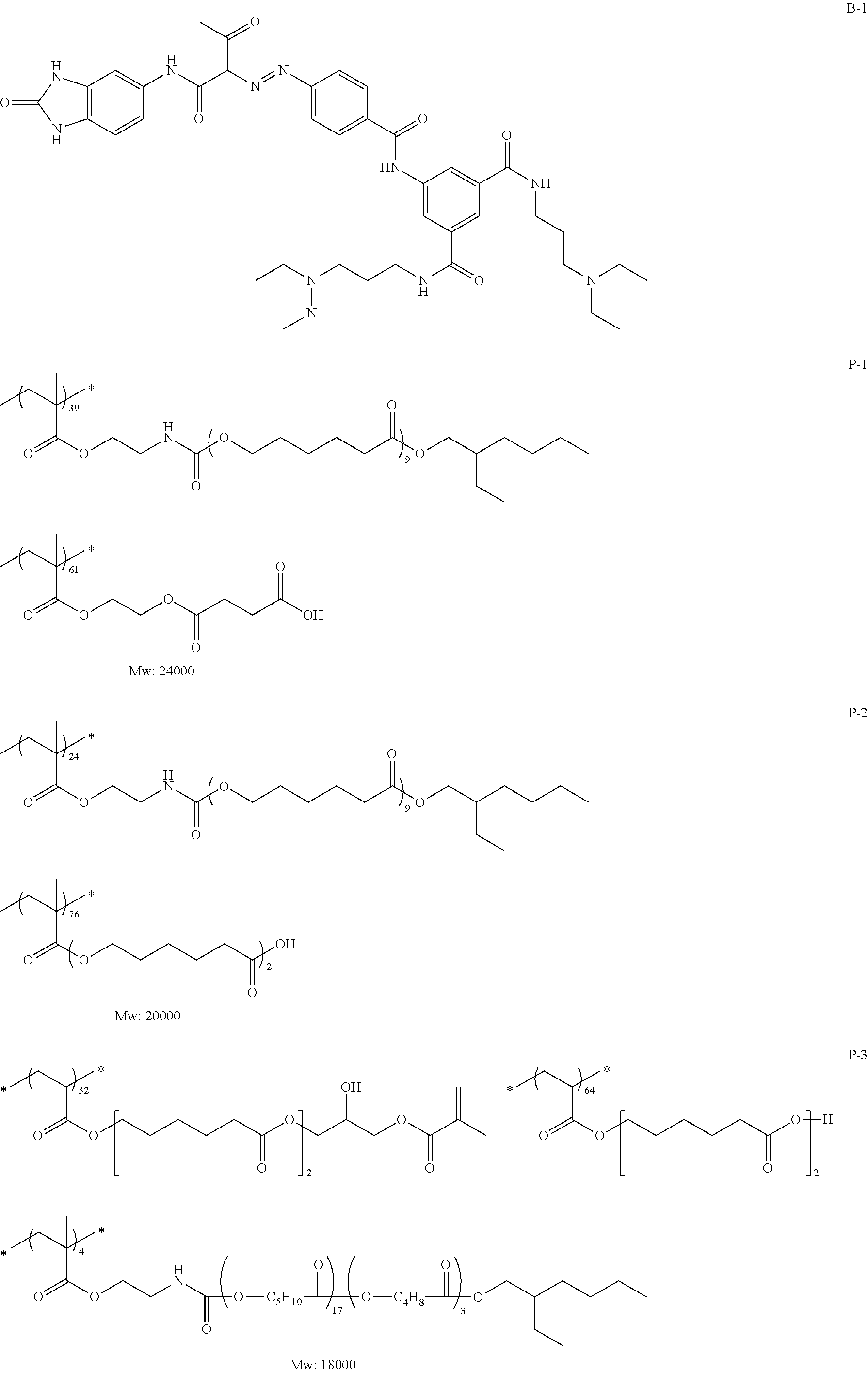

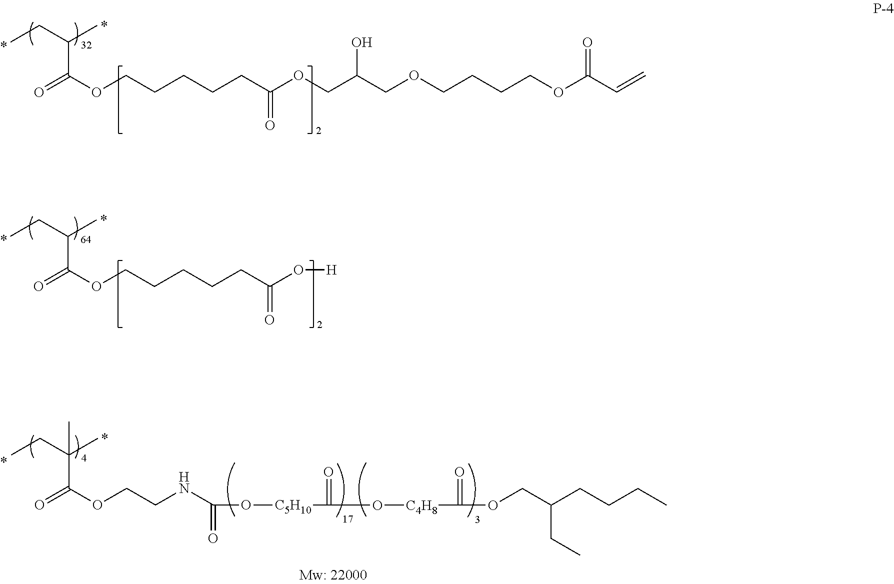

In Formulae P-1 to P-4, the subscript in parentheses indicating the structural units represents the content ratio (molar ratio) of each structural unit. In addition, the subscript in parentheses indicating an alkylene ester unit represents the number of repetitions.

In addition, in the present disclosure, PGMEA is an abbreviation for propylene glycol 1-monomethyl ether 2-acetate.

[Preparation of Curable Composition]

The raw materials described in Table 3 or Table 4 below were mixed to prepare a curable composition.

(Evaluation of Spectral Characteristics)

Each curable composition was spin-coated on a glass substrate such that the film thickness after post-baking was 0.4 μm, dried on a hot plate at 100° C. for 120 seconds, and then a heat treatment (post-baking) was further carried out for 300 seconds using a hot plate at 200° C. to form a cured film. Using a UV-visible-near infrared spectrophotometer U-4100 (manufactured by Hitachi High-Technologies Corporation) (ref. glass substrate), the glass substrate on which the cured film was formed was measured for the transmittance of light in a wavelength range of 300 nm to 1000 nm.

For the spectral evaluation, the ratio of the absorbance at a wavelength of 570 nm to the absorbance at a wavelength of 650 nm (absorbance at a wavelength of 570 nm/absorbance at a wavelength of 650 nm×100(%)) was used. A lower ratio indicates more excellent spectral characteristics as a green colored layer, and the ratio is preferably lower than 8%.

(Evaluation of Light Resistance)

The obtained film was irradiated with 20,000 lux light for 20 hours through an ultraviolet cut filter with a Xe lamp to carry out a light resistance test, and the ΔEab value of the color difference before and after the light resistance test was measured with a colorimeter MCPD-1000 (manufactured by Otsuka Electronics Co., Ltd.). The measurement results are shown in Table 3 or Table 4. It can be said that a smaller ΔEab value indicates more excellent light resistance, and the ΔEab value is preferably less than 10, more preferably less than 5, and still more preferably less than 2.5.

—Evaluation Standards—

A: ΔEab value<2.5

B: 2.5≤ΔEab value<5

C: 5≤ΔEab value<10

TABLE 3

| | | | | | | | | | Photopoly- | | | | | | | | | | | |
|---|---|---|---|---|---|---|---|---|---|---|---|---|---|---|---|---|---|---|---|---|
| | | | | | | | Polymerizable | | merization | | | | Polymerization | | Polymerizable | | | | Evaluation results | |
| | Specific compound | | Pigment dispersion liquid | | Dispersant | | compound 1 | | initiator | | Surfactant | | inhibitor | | compound 2 | | Solvent | | Spectral | |
| | | Parts by | | Parts by | | Parts by | | Parts by | | Parts by | | Parts by | | Parts by | | Parts by | | Parts by | characteristics | Light |
| | Type | mass | Type | mass | Type | mass | Type | mass | Type | mass | Type | mass | Type | mass | Type | mass | Type | mass | (%) | resistance |
| Example 1 | Compound 1 | 7.04 | Yellow dispersion | 19.07 | P-1 | 4.90 | E-1 | 2.41 | F-1 | 0.83 | G-1 | 0.009 | H-1 | 0.002 | I-1 | 0.37 | PGMEA | 65.37 | 6.0 | B |
| | | | liquid 1 | | | | | | | | | | | | | | | | | |
| Example 2 | Compound 2 | 7.04 | Yellow dispersion | 19.07 | P-1 | 4.90 | E-1 | 2.41 | F-1 | 0.83 | G-1 | 0.009 | H-1 | 0.002 | I-1 | 0.37 | PGMEA | 65.37 | 6.4 | B |
| | | | liquid 1 | | | | | | | | | | | | | | | | | |
| Example 3 | Compound 3 | 7.04 | Yellow dispersion | 19.07 | p-1 | 4.90 | E-1 | 2.41 | F-1 | 0.83 | G-1 | 0.009 | H-1 | 0.002 | I-1 | 0.37 | PGMEA | 65.37 | 6.4 | B |
| | | | liquid 1 | | | | | | | | | | | | | | | | | |
| Example 4 | Compound 4 | 7.04 | Yellow dispersion | 19.07 | P-1 | 4.90 | E-1 | 2.41 | F-1 | 0.83 | G-1 | 0.009 | H-1 | 0.002 | I-1 | 0.37 | PGMEA | 65.37 | 6.0 | A |
| | | | liquid 1 | | | | | | | | | | | | | | | | | |
| Example 5 | Compound 7 | 7.04 | Yellow dispersion | 19.07 | P-1 | 4.90 | E-1 | 2.41 | F-1 | 0.83 | G-1 | 0.009 | H-1 | 0.002 | I-1 | 0.37 | PGMEA | 65.37 | 6.1 | A |
| | | | liquid 1 | | | | | | | | | | | | | | | | | |
| Example 6 | Compound 10 | 7.04 | Yellow dispersion | 19.07 | P-1 | 4.90 | E-1 | 2.41 | F-1 | 0.83 | G-1 | 0.009 | H-1 | 0.002 | I-1 | 0.37 | PGMEA | 65.37 | 7.0 | B |
| | | | liquid 1 | | | | | | | | | | | | | | | | | |
| Example 7 | Compound 11 | 7.04 | Yellow dispersion | 19.07 | P-1 | 4.90 | E-1 | 2.41 | F-1 | 0.83 | G-1 | 0.009 | H-1 | 0.002 | I-1 | 0.37 | PGMEA | 65.37 | 6.1 | A |
| | | | liquid 1 | | | | | | | | | | | | | | | | | |
| Example 8 | Compound 12 | 7.04 | Yellow dispersion | 19.07 | P-1 | 4.90 | E-1 | 2.41 | F-1 | 0.83 | G-1 | 0.009 | H-1 | 0.002 | I-1 | 0.37 | PGMEA | 65.37 | 5.9 | B |
| | | | liquid 1 | | | | | | | | | | | | | | | | | |
| Example 9 | Compound 14 | 7.04 | Yellow dispersion | 1907 | P-1 | 4.90 | E-1 | 2.41 | F-1 | 0.83 | G-1 | 0.009 | H-1 | 0.002 | I-1 | 0.37 | PGMEA | 65.37 | 6.7 | A |
| | | | liquid 1 | | | | | | | | | | | | | | | | | |
| Example 10 | Compound 15 | 7.04 | Yellow dispersion | 19.07 | P-1 | 4.90 | E-1 | 2.41 | F-1 | 0.83 | G-1 | 0.009 | H-1 | 0.002 | I-1 | 0.37 | PGMEA | 65.37 | 7.3 | A |
| | | | liquid 1 | | | | | | | | | | | | | | | | | |
| Example 11 | Compound 16 | 7.04 | Yellow dispersion | 19.07 | P-1 | 4.90 | E-1 | 2.41 | F-1 | 0.83 | G-1 | 0.009 | H-1 | 0.002 | I-1 | 0.37 | PGMEA | 65.37 | 6.8 | A |
| | | | liquid 1 | | | | | | | | | | | | | | | | | |
| Example 12 | Compound 17 | 7.04 | Yellow dispersion | 19.07 | P-1 | 4.90 | E-1 | 2.41 | F-1 | 0.83 | G-1 | 0.009 | H-1 | 0.002 | I-1 | 0.37 | PGMEA | 65.37 | 6.1 | B |
| | | | liquid 1 | | | | | | | | | | | | | | | | | |
| Example 13 | Compound 18 | 7.04 | Yellow dispersion | 19.07 | P-1 | 4.90 | E-1 | 2.41 | F-1 | 0.83 | G-1 | 0.009 | H-1 | 0.002 | I-1 | 0.37 | PGMEA | 65.37 | 6.4 | B |
| | | | liquid 1 | | | | | | | | | | | | | | | | | |
| Example 14 | Compound 19 | 7.04 | Yellow dispersion | 19.07 | P-1 | 4.90 | E-1 | 2.41 | F-1 | 0.83 | G-1 | 0.009 | H-1 | 0.002 | I-1 | 0.37 | PGMEA | 65.37 | 6.9 | B |
| | | | liquid 1 | | | | | | | | | | | | | | | | | |
| Example 15 | Compound 20 | 7.04 | Yellow dispersion | 19.07 | P-1 | 4.90 | E-1 | 2.41 | F-1 | 0.83 | G-1 | 0.009 | H-1 | 0.002 | I-1 | 0.37 | PGMEA | 65.37 | 6.3 | B |
| | | | liquid 1 | | | | | | | | | | | | | | | | | |
| Example 16 | Compound 22 | 7.04 | Yellow dispersion | 19.07 | P-1 | 4.90 | E-1 | 2.41 | F-1 | 0.83 | G-1 | 0.009 | H-1 | 0.002 | I-1 | 0.37 | PGMEA | 65.37 | 7.3 | A |
| | | | liquid 1 | | | | | | | | | | | | | | | | | |
| Example 17 | Compound 25 | 7.04 | Yellow dispersion | 19.07 | P-1 | 4.90 | E-1 | 2.41 | F-1 | 0.83 | G-1 | 0.009 | H-1 | 0.002 | I-1 | 0.37 | PGMEA | 65.37 | 6.1 | A |
| | | | liquid 1 | | | | | | | | | | | | | | | | | |
| Example 18 | Compound 26 | 7.04 | Yellow dispersion | 19.07 | P-1 | 4.90 | E-1 | 2.41 | F-1 | 0.83 | G-1 | 0.009 | H-1 | 0.002 | I-1 | 0.37 | PGMEA | 65.37 | 5.9 | B |
| | | | liquid 1 | | | | | | | | | | | | | | | | | |
| Example 19 | Compound 33 | 7.04 | Yellow dispersion | 19.07 | P-1 | 4.90 | E-1 | 2.41 | F-1 | 0.83 | G-1 | 0.009 | H-1 | 0.002 | I-1 | 0.37 | PGMEA | 65.37 | 5.9 | B |
| | | | liquid 1 | | | | | | | | | | | | | | | | | |
| Example 20 | Compound 35 | 7.04 | Yellow dispersion | 19.07 | P-1 | 4.90 | E-1 | 2.41 | F-1 | 0.83 | G-1 | 0.009 | H-1 | 0.002 | I-1 | 0.37 | PGMEA | 65.37 | 5.6 | B |
| | | | liquid 1 | | | | | | | | | | | | | | | | | |
| Example 21 | Compound 37 | 7.04 | Yellow dispersion | 19.07 | P-1 | 4.90 | E-1 | 2.41 | F-1 | 0.83 | G-1 | 0.009 | H-1 | 0.002 | I-1 | 0.37 | PGMEA | 65.37 | 5.8 | B |
| | | | liquid 1 | | | | | | | | | | | | | | | | | |
| Example 22 | Compound 42 | 7.04 | Yellow dispersion | 19.07 | P-1 | 4.90 | E-1 | 2.41 | F-1 | 0.83 | G-1 | 0.009 | H-1 | 0.002 | I-1 | 0.37 | PGMEA | 65.37 | 6.4 | A |
| | | | liquid 1 | | | | | | | | | | | | | | | | | |
| Example 23 | Compound 46 | 7.04 | Yellow dispersion | 19.07 | P-1 | 4.90 | E-1 | 2.41 | F-1 | 0.83 | G-1 | 0.009 | H-1 | 0.002 | I-1 | 0.37 | PGMEA | 65.37 | 7.4 | B |
| | | | liquid 1 | | | | | | | | | | | | | | | | | |
| Example 24 | Compound 49 | 7.04 | Yellow dispersion | 19.07 | P-1 | 4.90 | E-1 | 2.41 | F-1 | 0.83 | G-1 | 0.009 | H-1 | 0.002 | I-1 | 0.37 | PGMEA | 65.37 | 7.3 | B |
| | | | liquid 1 | | | | | | | | | | | | | | | | | |
| Example 25 | Compound 50 | 7.04 | Yellow dispersion | 19.07 | P-1 | 4.90 | E-1 | 2.41 | F-1 | 0.83 | G-1 | 0.009 | H-1 | 0.002 | I-1 | 0.37 | PGMEA | 65.37 | 7.5 | B |
| | | | liquid 1 | | | | | | | | | | | | | | | | | |
| Example 26 | Compound 51 | 7.04 | Yellow dispersion | 19.07 | P-1 | 4.90 | E-1 | 2.41 | F-1 | 0.83 | G-1 | 0.009 | H-1 | 0.002 | I-1 | 0.37 | PGMEA | 65.37 | 6.7 | A |
| | | | liquid 1 | | | | | | | | | | | | | | | | | |
| Example 27 | Compound 53 | 7.04 | Yellow dispersion | 19.07 | P-1 | 4.90 | E-1 | 2.41 | F-1 | 0.83 | G-1 | 0.009 | H-1 | 0.002 | I-1 | 0.37 | PGMEA | 65.37 | 7.7 | B |
| | | | liquid 1 | | | | | | | | | | | | | | | | | |
| Example 28 | Compound 55 | 7.04 | Yellow dispersion | 19.07 | P-1 | 4.90 | E-1 | 2.41 | F-1 | 0.83 | G-1 | 0.009 | H-1 | 0.002 | I-1 | 0.37 | PGMEA | 65.37 | 7.9 | B |
| | | | liquid 1 | | | | | | | | | | | | | | | | | |
| Example 29 | Compound 57 | 7.04 | Yellow dispersion | 19.07 | P-1 | 4.90 | E-1 | 2.41 | F-1 | 0.83 | G-1 | 0.009 | H-1 | 0.002 | I-1 | 0.37 | PGMEA | 65.37 | 7.6 | B |
| | | | liquid 1 | | | | | | | | | | | | | | | | | |
| Example 30 | Compound 63 | 7.04 | Yellow dispersion | 19.07 | P-1 | 4.90 | E-1 | 2.41 | F-1 | 0.83 | G-1 | 0.009 | H-1 | 0.002 | I-1 | 0.37 | PGMEA | 65.37 | 7.8 | B |
| | | | liquid 1 | | | | | | | | | | | | | | | | | |
| Example 31 | Compound 72 | 7.04 | Yellow dispersion | 19.07 | P-1 | 4.90 | E-1 | 2.41 | F-1 | 0.83 | G-1 | 0.009 | H-1 | 0.002 | I-1 | 0.37 | PGMEA | 65.37 | 7.0 | A |
| | | | liquid 1 | | | | | | | | | | | | | | | | | |
| Example 32 | Compound 73 | 7.04 | Yellow dispersion | 19.07 | P-1 | 4.90 | E-1 | 2.41 | F-1 | 0.83 | G-1 | 0.009 | H-1 | 0.002 | I-1 | 0.37 | PGMEA | 65.37 | 7.9 | A |
| | | | liquid 1 | | | | | | | | | | | | | | | | | |

TABLE 4

| | | | Pigment | | | | | | Photo- | | | | | | | | | | | |
|---|---|---|---|---|---|---|---|---|---|---|---|---|---|---|---|---|---|---|---|---|
| | | | dispersion | | | | Polymerizable | | polymerization | | | | Polymerization | | Polymerizable | | | | Evaluation results | |
| | Specific compound | | liquid | | Dispersant | | compound 1 | | initiator | | Surfactant | | inhibitor | | compound 2 | | Solvent | | Special | |
| | | Parts by | | Parts by | | Parts by | | Parts by | | Parts by | | Parts by | | Parts by | | Parts by | | Parts by | characteristics | Light |
| | Type | mass | Type | mass | Type | mass | Type | mass | Type | mass | Type | mass | Type | mass | Type | mass | Type | mass | (%) | resistance |
| Example 33 | Compound 78 | 7.04 | Yellow | 19.07 | P-1 | 4.90 | E-1 | 2.41 | F-1 | 0.83 | G-1 | 0.009 | H-1 | 0.002 | I-1 | 0.37 | PGMEA | 65.37 | 6.0 | A |
| | | | dispersion | | | | | | | | | | | | | | | | | |
| | | | liquid 1 | | | | | | | | | | | | | | | | | |
| Example 34 | Compound 1 | 2.00 | Yellow | 19.07 | P-1 | 4.90 | E-1 | 2.41 | F-1 | 0.83 | G-1 | 0.009 | H-1 | 0.002 | I-1 | 0.37 | PGMEA | 65.37 | 6.1 | B |
| | Compound 11 | 5.04 | dispersion | | | | | | | | | | | | | | | | | |
| | | | liquid 1 | | | | | | | | | | | | | | | | | |
| Example 35 | Compound 1 | 2.00 | Yellow | 19.07 | P-1 | 4.90 | E-1 | 2.41 | F-1 | 0.83 | G-1 | 0.009 | H-1 | 0.002 | I-1 | 0.37 | PGMEA | 65.37 | 6.2 | B |
| | Compound 15 | 5.04 | dispersion | | | | | | | | | | | | | | | | | |
| | | | liquid 1 | | | | | | | | | | | | | | | | | |
| Example 36 | Compound 12 | 4.83 | Green | 38.14 | P-1 | 4.04 | E-1 | 2.41 | F-1 | 0.83 | G-1 | 0.009 | H-1 | 0.002 | I-1 | 0.37 | PGMEA | 49.37 | 7.0 | B |
| | | | dispersion | | | | | | | | | | | | | | | | | |
| | | | liquid 1 | | | | | | | | | | | | | | | | | |
| Example 37 | Compound 12 | 4.83 | Green | 38.14 | P-1 | 4.04 | E-1 | 2.41 | F-1 | 0.83 | G-1 | 0.009 | H-1 | 0.002 | I-1 | 0.37 | PGMEA | 49.37 | 6.8 | B |
| | | | dispersion | | | | | | | | | | | | | | | | | |
| | | | liquid 2 | | | | | | | | | | | | | | | | | |
| Example 38 | Compound 12 | 7.04 | Yellow | 19.07 | P-1 | 3.90 | E-1 | 2.41 | F-1 | 0.83 | G-1 | 0.009 | H-1 | 0.002 | I-1 | 0.37 | PGMEA | 65.37 | 5.9 | B |
| | | | dispersion | | D-1 | 1.00 | | | | | | | | | | | | | | |
| | | | liquid 1 | | | | | | | | | | | | | | | | | |
| Example 39 | Compound 12 | 7.04 | Yellow | 19.07 | P-1 | 3.90 | E-1 | 2.41 | F-1 | 0.83 | G-1 | 0.009 | H-1 | 0.002 | I-1 | 0.37 | PGMEA | 65.37 | 5.9 | B |
| | | | dispersion | | D-2 | 1.00 | | | | | | | | | | | | | | |
| | | | liquid 1 | | | | | | | | | | | | | | | | | |
| Example 40 | Compound 12 | 7.04 | Yellow | 19.07 | P-1 | 4.90 | E-2 | 2.41 | F-1 | 0.83 | G-1 | 0.009 | H-1 | 0.002 | I-1 | 0.37 | PGMEA | 65.37 | 5.9 | B |
| | | | dispersion | | | | | | | | | | | | | | | | | |
| | | | liquid 1 | | | | | | | | | | | | | | | | | |
| Example 41 | Compound 12 | 7.04 | Yellow | 19.07 | P-1 | 4.90 | E-3 | 2.41 | F-1 | 0.83 | G-1 | 0.009 | H-1 | 0.002 | I-1 | 0.37 | PGMEA | 65.37 | 5.9 | B |
| | | | dispersion | | | | | | | | | | | | | | | | | |
| | | | liquid 1 | | | | | | | | | | | | | | | | | |
| Example 42 | Compound 12 | 7.04 | Yellow | 19.07 | P-1 | 4.90 | E-4 | 2.41 | F-1 | 0.83 | G-1 | 0.009 | H-1 | 0.002 | I-1 | 0.37 | PGMEA | 65.37 | 5.9 | B |
| | | | dispersion | | | | | | | | | | | | | | | | | |
| | | | liquid 1 | | | | | | | | | | | | | | | | | |
| Example 43 | Compound 12 | 7.04 | Yellow | 19.07 | P-1 | 4.90 | E-5 | 2.41 | F-1 | 0.83 | G-1 | 0.009 | H-1 | 0.002 | I-1 | 0.37 | PGMEA | 65.37 | 5.9 | B |
| | | | dispersion | | | | | | | | | | | | | | | | | |
| | | | liquid 1 | | | | | | | | | | | | | | | | | |
| Example 44 | Compound 12 | 7.04 | Yellow | 19.07 | P-1 | 4.90 | E-1 | 1.40 | F-1 | 0.83 | G-1 | 0.009 | H-1 | 0.002 | I-1 | 0.37 | PGMEA | 65.37 | 5.9 | B |
| | | | dispersion | | | | E-2 | 1.01 | | | | | | | | | | | | |
| | | | liquid 1 | | | | | | | | | | | | | | | | | |
| Example 45 | Compound 12 | 7.04 | Yellow | 19.07 | P-1 | 4.90 | E-1 | 2.41 | F-2 | 0.83 | G-1 | 0.009 | H-1 | 0.002 | I-1 | 0.37 | PGMEA | 65.37 | 5.9 | B |
| | | | dispersion | | | | | | | | | | | | | | | | | |
| | | | liquid 1 | | | | | | | | | | | | | | | | | |
| Example 46 | Compound 12 | 7.04 | Yellow | 19.07 | P-1 | 4.90 | E-1 | 2.41 | F-3 | 0.83 | G-1 | 0.009 | H-1 | 0.002 | I-1 | 0.37 | PGMEA | 65.37 | 5.9 | B |
| | | | dispersion | | | | | | | | | | | | | | | | | |
| | | | liquid 1 | | | | | | | | | | | | | | | | | |
| Example 47 | Compound 12 | 7.04 | Yellow | 19.07 | P-1 | 4.90 | E-1 | 2.41 | F-4 | 0.83 | G-1 | 0.009 | H-1 | 0.002 | I-1 | 0.37 | PGMEA | 65.37 | 5.9 | B |
| | | | dispersion | | | | | | | | | | | | | | | | | |
| | | | liquid 1 | | | | | | | | | | | | | | | | | |
| Example 48 | Compound 12 | 7.04 | Yellow | 19.07 | P-1 | 4.90 | E-1 | 2.41 | F-5 | 0.83 | G-1 | 0.009 | H-1 | 0.002 | I-1 | 0.37 | PGMEA | 65.37 | 5.9 | B |
| | | | dispersion | | | | | | | | | | | | | | | | | |
| | | | liquid 1 | | | | | | | | | | | | | | | | | |
| Example 49 | Compound 12 | 7.04 | Yellow | 19.07 | P-1 | 4.90 | E-1 | 2.41 | F-1 | 0.62 | G-1 | 0.009 | H-1 | 0.002 | I-1 | 0.37 | PGMEA | 65.37 | 5.9 | B |
| | | | dispersion | | | | | | F-4 | 0.21 | | | | | | | | | | |
| | | | liquid 1 | | | | | | | | | | | | | | | | | |
| Example 50 | Compound 12 | 7.04 | Yellow | 19.07 | P-1 | 4.90 | E-1 | 2.41 | F-1 | 0.83 | G-1 | 0.009 | H-1 | 0.002 | I-1 | 0.37 | PGMEA | 65.37 | 6.1 | B |
| | | | dispersion | | | | | | | | | | | | | | | | | |
| | | | liquid 2 | | | | | | | | | | | | | | | | | |
| Example 51 | Compound 12 | 7.04 | Yellow | 19.07 | P-1 | 4.90 | E-1 | 2.41 | F-1 | 0.83 | G-1 | 0.009 | H-1 | 0.002 | I-1 | 0.37 | PGMEA | 65.37 | 6.0 | B |
| | | | dispersion | | | | | | | | | | | | | | | | | |
| | | | liquid 3 | | | | | | | | | | | | | | | | | |
| Example 52 | Compound 12 | 7.04 | Yellow | 19.07 | P-2 | 4.90 | E-1 | 2.41 | F-1 | 0.83 | G-1 | 0.009 | H-1 | 0.002 | I-1 | 0.37 | PGMEA | 65.37 | 6.0 | B |
| | | | dispersion | | | | | | | | | | | | | | | | | |
| | | | liquid 4 | | | | | | | | | | | | | | | | | |
| Example 53 | Compound 12 | 7.04 | Yellow | 19.07 | P-3 | 4.90 | E-1 | 2.41 | F-1 | 0.83 | G-1 | 0.009 | H-1 | 0.002 | I-1 | 0.37 | PGMEA | 65.37 | 6.0 | B |
| | | | dispersion | | | | | | | | | | | | | | | | | |
| | | | liquid 5 | | | | | | | | | | | | | | | | | |
| Example 54 | Compound 12 | 7.04 | Yellow | 19.07 | P-4 | 4.90 | E-1 | 2.41 | F-1 | 0.83 | G-1 | 0.009 | H-1 | 0.002 | I-1 | 0.37 | PGMEA | 65.37 | 6.0 | B |
| | | | dispersion | | | | | | | | | | | | | | | | | |
| | | | liquid 6 | | | | | | | | | | | | | | | | | |
| Example 55 | Compound 12 | 7.04 | Yellow | 19.07 | P-1 | 4.90 | E-1 | 2.41 | F-1 | 0.83 | G-1 | 0.009 | H-2 | 0.002 | I-1 | 0.37 | PGMEA | 65.37 | 5.9 | B |
| | | | dispersion | | | | | | | | | | | | | | | | | |
| | | | liquid 1 | | | | | | | | | | | | | | | | | |
| Example 56 | Compound 12 | 7.04 | Yellow | 19.07 | P-1 | 4.90 | E-1 | 2.41 | F-1 | 0.83 | G-1 | 0.009 | H-1 | 0.002 | I-2 | 0.37 | PGMEA | 65.37 | 5.9 | B |
| | | | dispersion | | | | | | | | | | | | | | | | | |
| | | | liquid 1 | | | | | | | | | | | | | | | | | |
| Example 57 | Compound 12 | 7.04 | Yellow | 19.07 | P-1 | 4.90 | E-1 | 2.41 | F-1 | 0.83 | G-1 | 0.009 | H-1 | 0.002 | — | — | PGMEA | 65.37 | 5.9 | B |
| | | | dispersion | | | | | | | | | | | | | | | | | |
| | | | liquid 1 | | | | | | | | | | | | | | | | | |
| Example 58 | Compound 12 | 7.04 | Yellow | 19.07 | P-1 | 4.90 | E-1 | 2.41 | F-1 | 0.83 | G-1 | 0.009 | H-1 | 0.002 | I-1 | 0.37 | CHN | 65.37 | 5.9 | B |
| | | | dispersion | | | | | | | | | | | | | | | | | |
| | | | liquid 1 | | | | | | | | | | | | | | | | | |
| Example 59 | Compound | 10.00 | — | — | P-1 | 5.20 | E-1 | 2.41 | F-1 | 0.83 | G-1 | 0.009 | H-1 | 0.002 | I-1 | 0.37 | PGMEA | 81.18 | 7.6 | C |
| | 50 | | | | | | | | | | | | | | | | | | | |
| Comparative | Compound | 10.00 | — | — | P-1 | 5.20 | E-1 | 2.41 | F-1 | 0.83 | G-1 | 0.009 | H-1 | 0.002 | I-1 | 0.37 | PGMEA | 81.18 | 9.9 | C |
| Example 1 | (1) | | | | | | | | | | | | | | | | | | | |
| Comparative | Compound | 10.00 | — | — | P-1 | 5.20 | E-1 | 2.41 | F-1 | 0.83 | G-1 | 0.009 | H-1 | 0.002 | I-1 | 0.37 | PGMEA | 81.18 | 10.0 | C |
| Example 2 | (2) | | | | | | | | | | | | | | | | | | | |

From the above Examples, it can be seen that the cured product of the curable composition according to the present disclosure has excellent spectral characteristics. Therefore, the curable composition according to the present disclosure is considered to be suitable as a curable composition used for producing a color filter.

In addition, it can be seen that the cured product has excellent light resistance by containing a chromatic colorant different from the specific compound.

Details of the compounds described in Table 3 or Table 4 other than those described above are as follows.

—Resin—

D-1 and D-2 are each a resin having the following structure.

In the following structural formulae, the subscript in parentheses indicating the structural units represents the content ratio (molar ratio) of each structural unit. In addition, Me represents a methyl group.

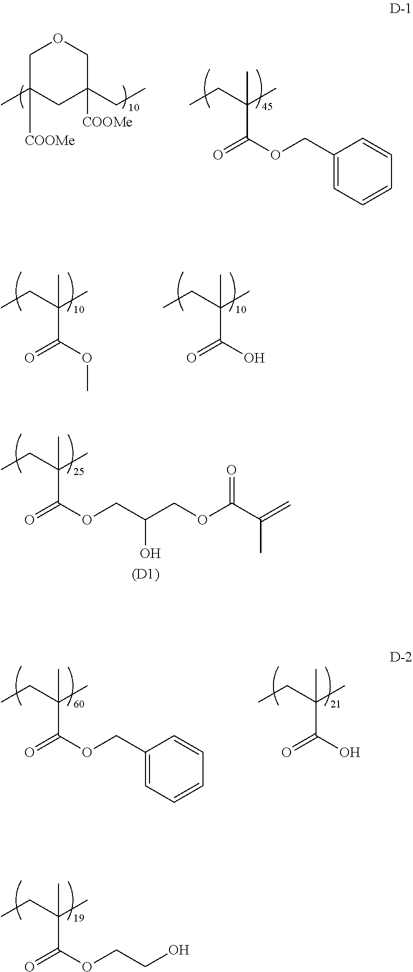

—Polymerizable Compound 1 (Monomer)—

E-1 to E-4 are each a polymerizable compound (monomer) having the following structure.

E-5 is ARONIX TO-2349 (manufactured by Toagosei Co., Ltd.).

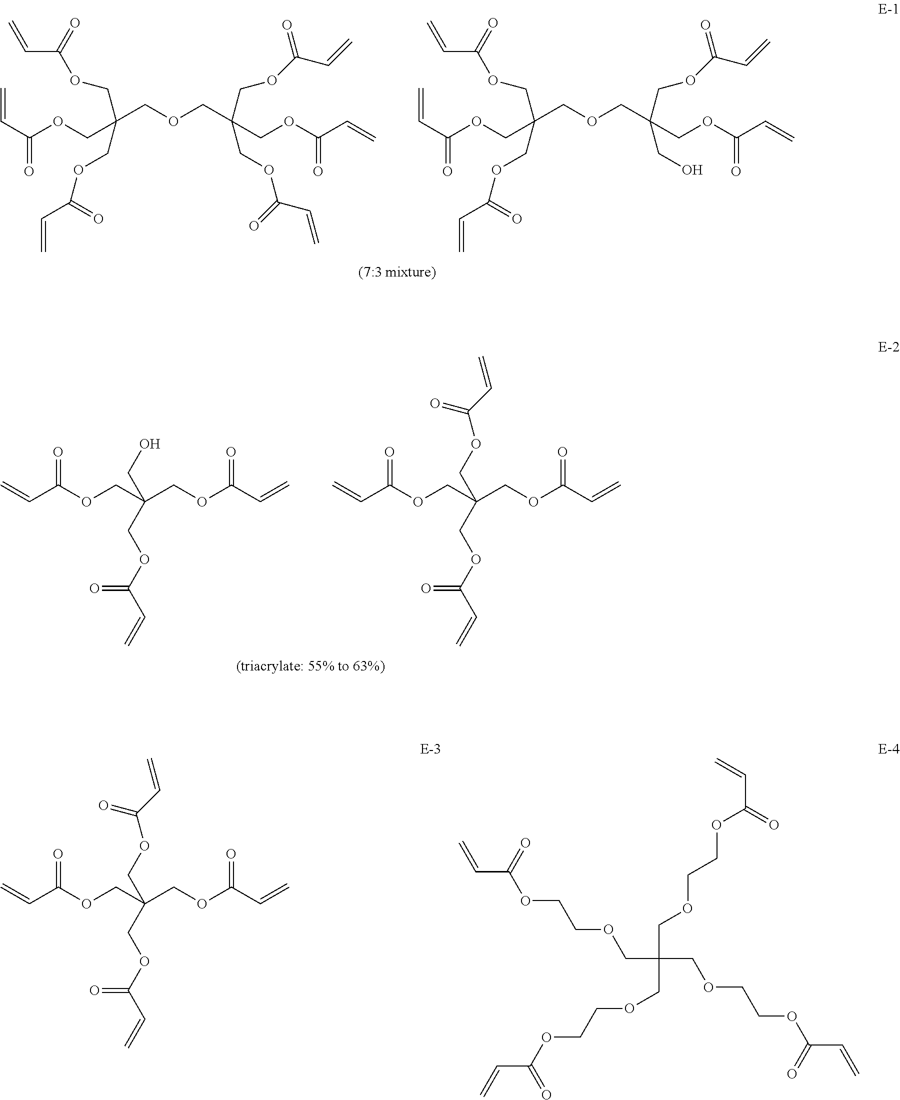

—Photopolymerization Initiator (Photoinitiator)—

F-1 to F-5 are each a photopolymerization initiator (photoinitiator) having the following structure.

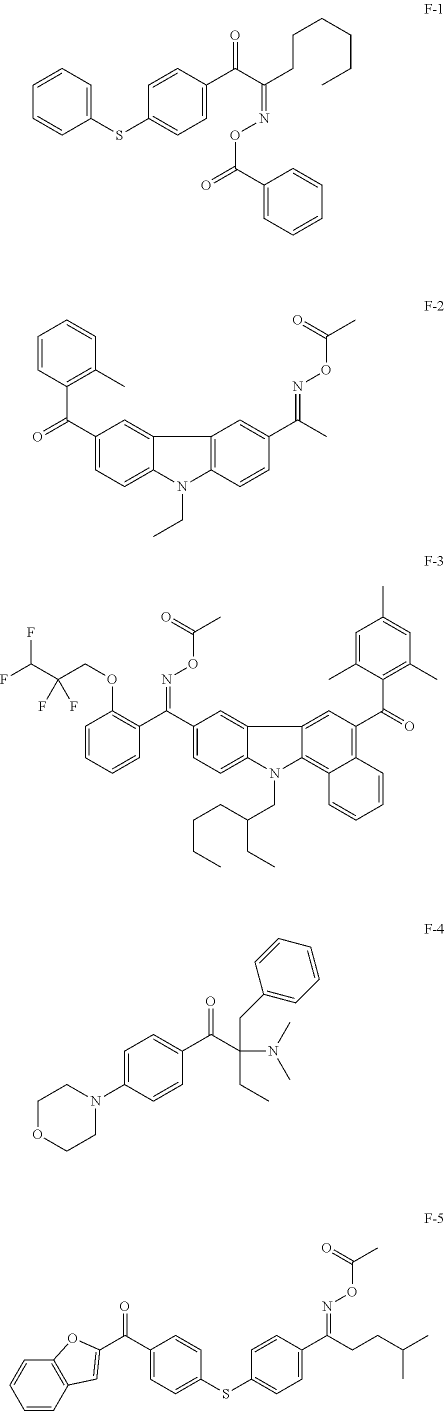 [SMILES: CCCCCC/C(=N/OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21 ; CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21 ; CCC(Cc1ccccc1)(C(=O)c1ccc(N2CCOCC2)cc1)N(C)C ; CC(=O)O/N=C(\CCC(C)C)c1ccc(Sc2ccc(C(=O)c3cc4ccccc4o3)cc2)cc1]

—Surfactant—

A surfactant G-1 is a 1% by mass PGMEA solution of the following mixture (Mw=14000). In the following formula, the subscript in parentheses represents the content ratio (molar ratio) of each structural unit. In addition, the description of 62% and 38% is a content percentage by mass.

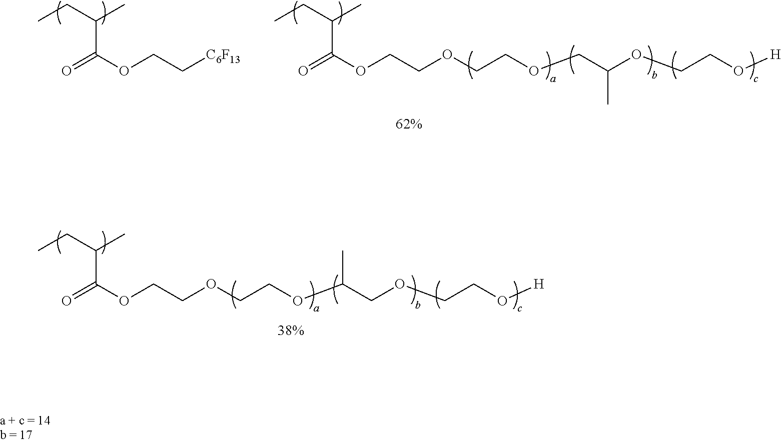

—Polymerization Inhibitor—

A polymerization inhibitor H-1 is paramethoxyphenol.

A polymerization inhibitor H-2 is 2,2,6,6-tetramethylpiperidine-1-oxyl.

—Polymerizable Compound 2—

I-1 and T-2 are each a polymerizable compound (monomer) having the following structure.

I-1: 1,2-epoxy-4-(2-oxiranyl)cyclohexane adduct of 2,2-bis(hydroxymethyl)-1-butanol (Mw: 23000)

I-2: EPICLON HP-4032 (manufactured by DIC Corporation)

<Synthesis of Compound 82>

A monomer (82-M) was synthesized according to the following scheme.

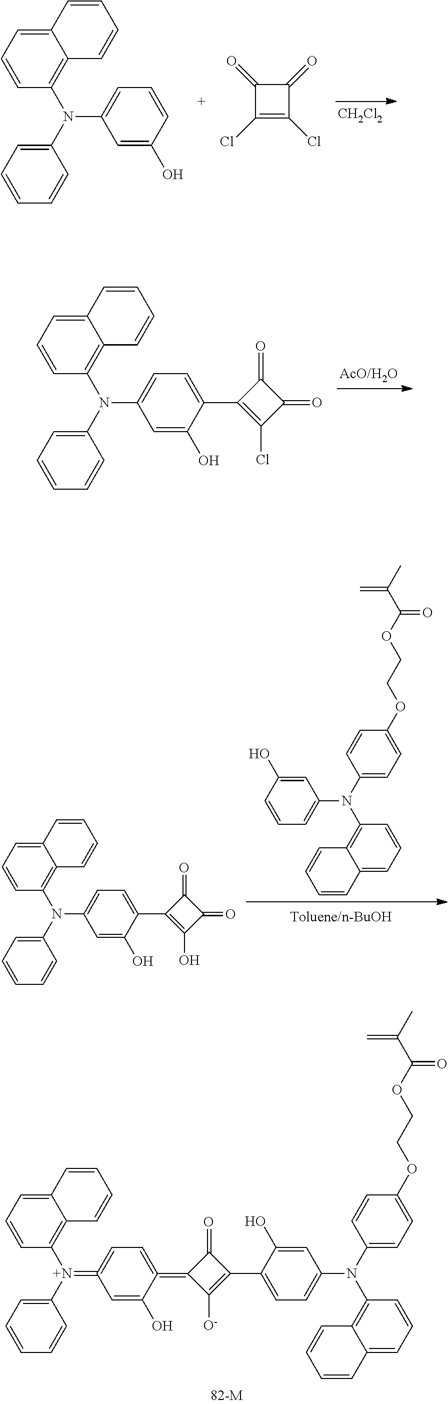

A compound 82 was synthesized according to the following scheme.

In the following synthesis scheme, V-601 is dimethyl 2,2′-azobis(isobutyrate) (manufactured by Fujifilm Wako Pure Chemical Industries, Ltd.), and PGMEA is propylene glycol methyl ether acetate.

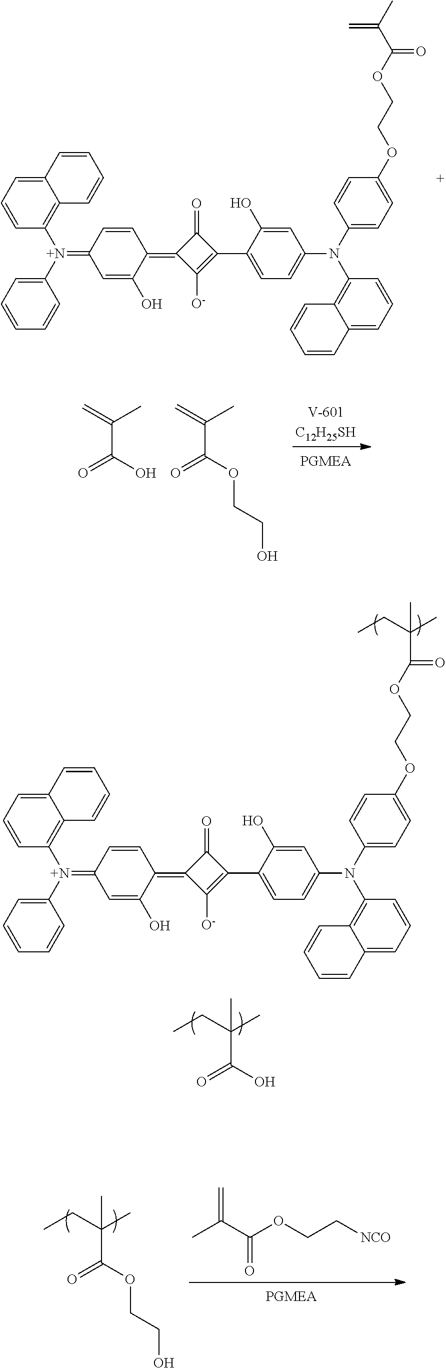

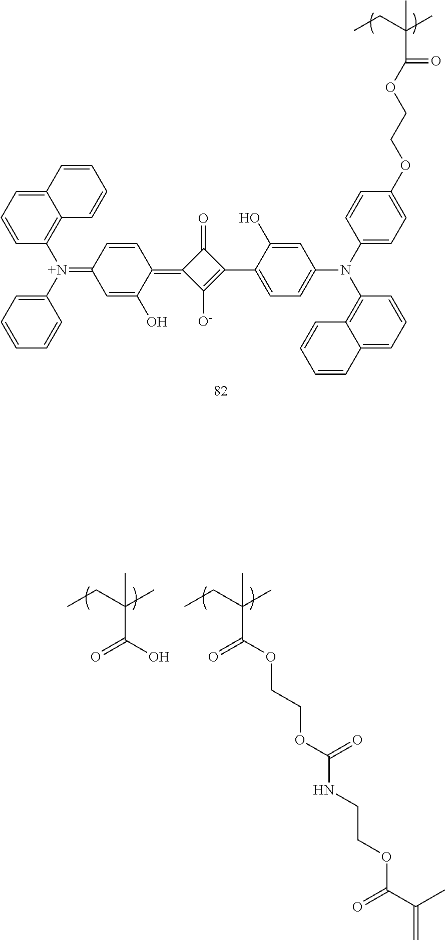

<Synthesis of Compound 83>

A compound 83 was synthesized in the same manner as in the synthesis of the compound 82, except that the monomer (82-M) used was changed to the following monomer (83-M).

Monomer (83-M): a structure shown below

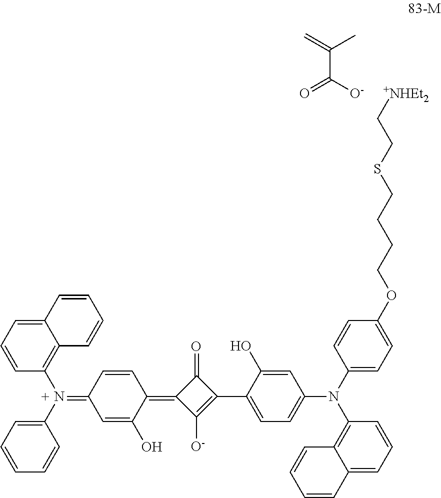

Compound 83: a structure shown below

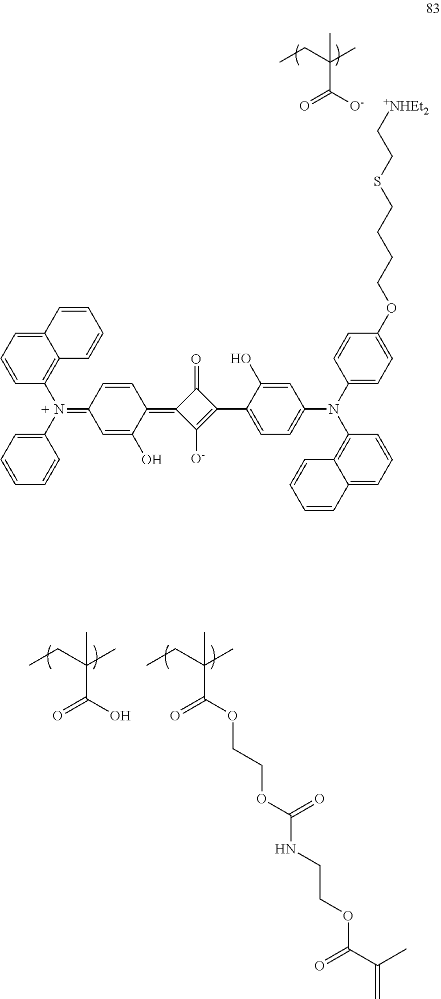

<Synthesis of Compound 84>

A compound 84 was synthesized according to the following scheme.

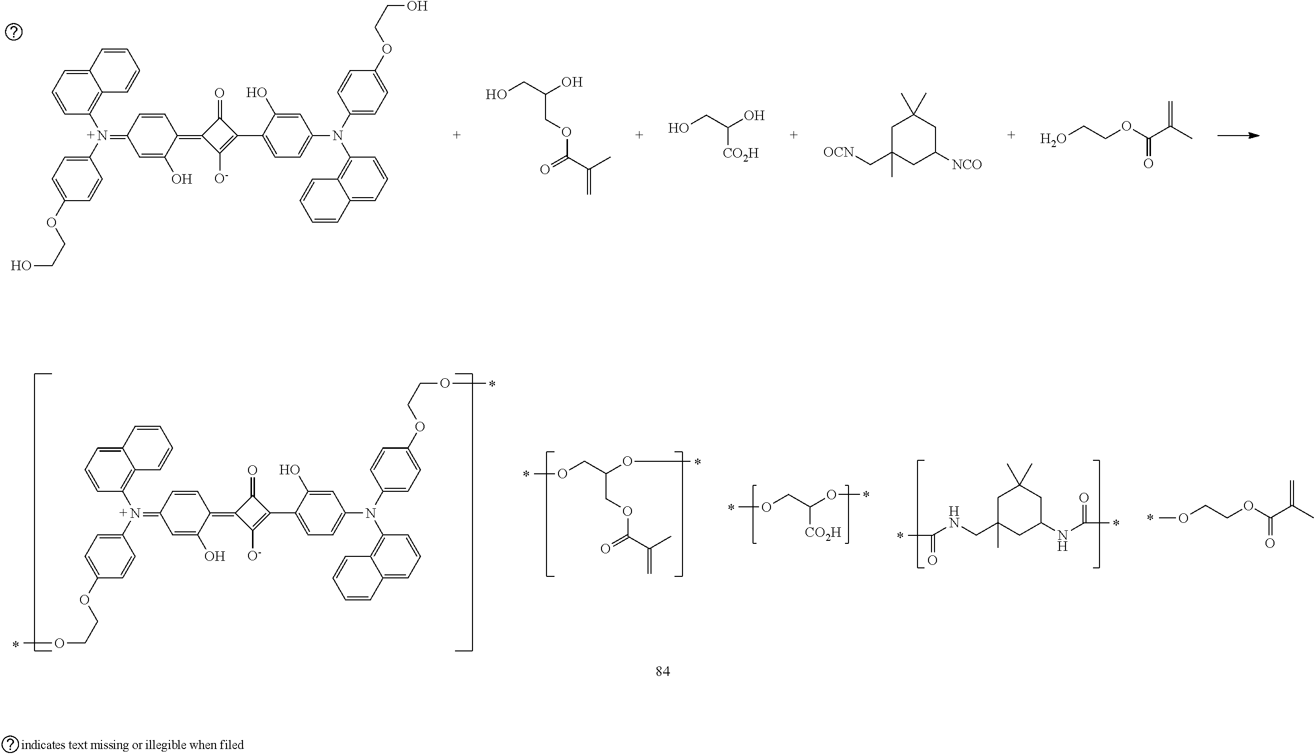

In the above chemical structural formulae, * represents a bonding position to **.

<Synthesis of Compound 85>

A compound 85 was synthesized according to the following scheme.

In the following synthesis scheme, V-601 is dimethyl 2,2′-azobis(isobutyrate) (manufactured by Fujifilm Wako Pure Chemical Industries, Ltd.), and PGMEA is propylene glycol methyl ether acetate.

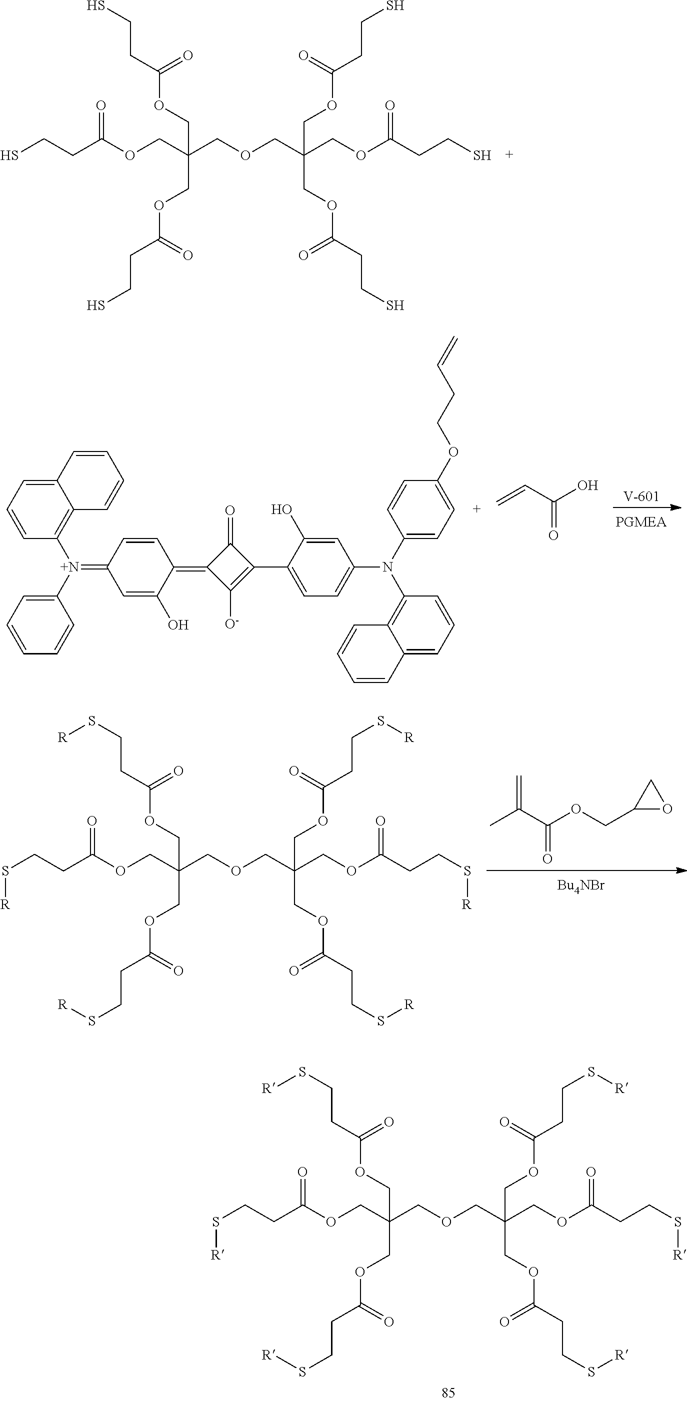

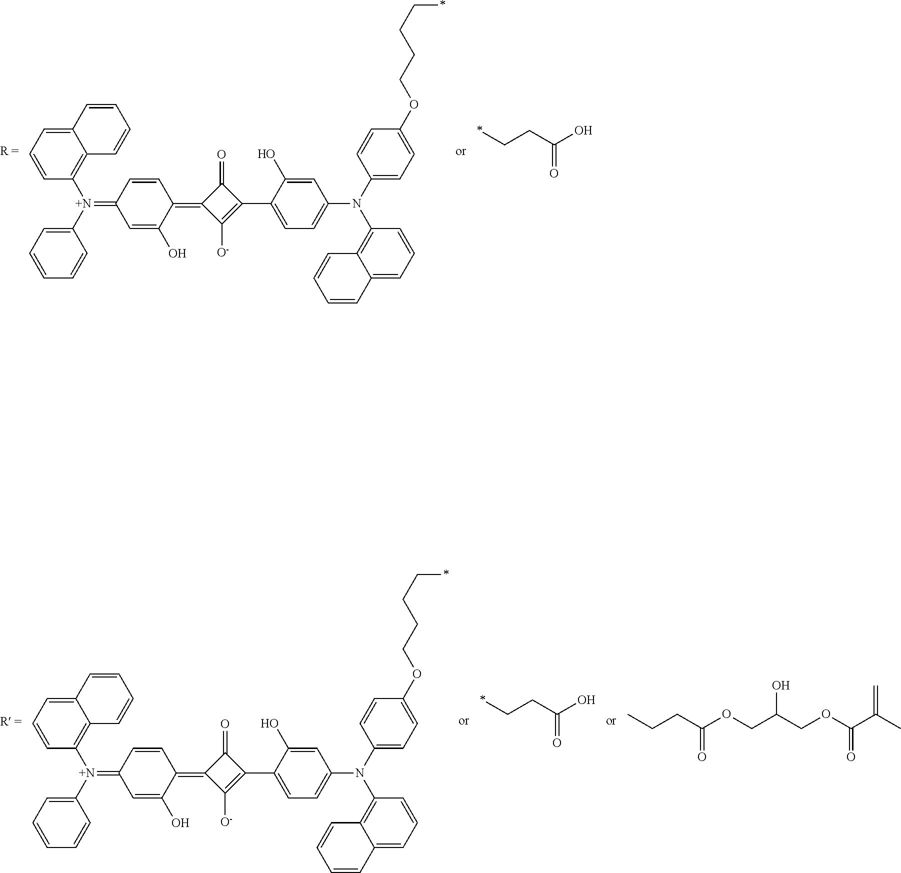

### Examples 60 to 64

<Preparation 2 of Curable Composition>

The following components were mixed to prepare a curable composition.
Specific compound shown in Table 5: amount shown in Table 5
Pigment dispersion liquid (yellow pigment dispersion liquid 1): 19.07 parts by mass
Dispersant (P-1): 4.9 parts by mass
Polymerizable compound 1 (E-1): 2.41 parts by mass
Photopolymerization initiator (F-1): 0.83 parts by mass
Surfactant (G-1): 0.009 parts by mass
Polymerization inhibitor (H-1): 0.002 parts by mass
Polymerizable compound 1 (I-1): 0.37 parts by mass
Solvent (propylene glycol monomethyl ether acetate): 65.37 parts by mass

The same evaluation as in Examples 1 to 59 was carried out. The evaluation results are shown in Table 5.

TABLE 5

| | Specific compound | | Evaluation results | |
|---|---|---|---|---|
| | | Parts | Spectral | |
| | | by | characteristics | Light |
| | Type | mass | (%) | resistance |
| Example 60 | Compound 82 | 7.04 | 6.0 | A |
| Example 61 | Compound 83 | 7.04 | 6.0 | A |
| Example 62 | Compound 84 | 7.04 | 6.0 | A |
| Example 63 | Compound 85 | 7.04 | 6.0 | A |
| Example 64 | Compound 1 | 2.00 | 6.0 | A |
| | Compound 82 | 5.04 | | |

From the Examples shown in Table 5, it can be seen that the cured product of the curable composition according to the present disclosure has excellent spectral characteristics and light resistance. Therefore, the curable composition according to the present disclosure is considered to be suitable as a curable composition used for producing a color filter.

### Example 201 to Example 264

Green composition was applied onto a silicon wafer by spin coating such that the film thickness after film formation was 1.0 μm. This was followed by heating at 100° C. for 2 minutes using a hot plate. Then, the exposure was carried out at 1,000 mJ/cm² through a mask having a dot pattern of 2 μm square using an i-line stepper exposure apparatus FPA-3000i5+(manufactured by Canon Inc.). Next, the puddle development was carried out at 23° C. for 60 seconds using a 0.3% by mass aqueous solution of tetramethylammonium hydroxide (TMAH). This was followed by rinsing with a spin shower and then further washing with pure water. Next, the Green composition was patterned on the silicon wafer by heating at 200° C. for 5 minutes using a hot plate. Similarly, the Red composition and the Blue composition were sequentially patterned to form red, green, and blue colored patterns (Bayer patterns).

The curable compositions prepared in Example 1 to Example 64 were used as the Green composition. Examples in which the solid-state imaging element was formed using the curable composition prepared in each of Example 1 to Example 64 as the Green composition correspond to Example 201 to Example 264, respectively.

The Red composition and the Blue composition will be described later.

The Bayer pattern is a pattern in which a 2×2 array of color filter elements each having one red (Red) element, two green (Green) elements, and one blue (Blue) element is repeated, as disclosed in U.S. Pat. No. 3,971,065A.

The obtained color filter was incorporated into a solid-state imaging element according to a known method. It was confirmed that the solid-state imaging element had excellent spectral characteristics, high resolution, and excellent color separation even in a case where any of the compositions obtained in Example 1 to Example 64 was used.

The Red composition and the Blue composition used in Example 201 to Example 264 are as follows.

—Red Composition—

The following components were mixed, stirred, and then filtered through a nylon filter (manufactured by Pall Corporation) having a pore size of 0.45 μm to prepare a Red composition.

Red pigment dispersion liquid: 51.7 parts by mass

Resin 4 (40% by mass PGMEA solution): 0.6 parts by mass

Polymerizable compound 4: 0.6 parts by mass

Photopolymerization initiator 1: 0.3 parts by mass

Surfactant 1: 4.2 parts by mass

PGMEA: 42.6 parts by mass

—Blue Composition—

The following components were mixed, stirred, and then filtered through a nylon filter (manufactured by Pall Corporation) having a pore size of 0.45 μm to prepare a Blue composition.

Blue pigment dispersion liquid: 44.9 parts by mass

Resin 4 (40% by mass PGMEA solution): 2.1 parts by mass

Polymerizable compound 1: 1.5 parts by mass

Polymerizable compound 4: 0.7 parts by mass

Photopolymerization initiator 1: 0.8 parts by mass

Surfactant 1: 4.2 parts by mass

PGMEA: 45.8 parts by mass

The raw materials used for the Red composition, the Green composition, and the Blue composition are as follows.

Red Pigment Dispersion Liquid

A mixed liquid consisting of 9.6 parts by mass of C.I. Pigment Red 254, 4.3 parts by mass of C.I. Pigment Yellow 139, 6.8 parts by mass of a dispersant (Disperbyk-161, manufactured by BYK-Chemie GmbH), and 79.3 parts by mass of PGMEA was mixed and dispersed for 3 hours by a beads mill (zirconia beads having a diameter of 0.3 mm) to prepare a pigment dispersion liquid. Thereafter, a dispersion treatment was further carried out at a flow rate of 500 g/min under a pressure of 2,000 kg/cm², using a high-pressure disperser NANO-3000-10 (manufactured by Nippon BEE Chemical Co., Ltd.) equipped with a pressure reducing mechanism. This dispersion treatment was repeated 10 times to obtain a Red pigment dispersion liquid.

Blue Pigment Dispersion Liquid

A mixed liquid consisting of 9.7 parts by mass of C.I. Pigment Blue 15:6, 2.4 parts by mass of C.I. Pigment Violet 23, 5.5 parts by mass of a dispersant (Disperbyk-161, manufactured by BYK-Chemie GmbH), and 82.4 parts by mass of PGMEA was mixed and dispersed for 3 hours by a beads mill (zirconia beads having a diameter of 0.3 mm) to prepare a pigment dispersion liquid. Thereafter, a dispersion treatment was further carried out at a flow rate of 500 g/min under a pressure of 2,000 kg/cm², using a high-pressure disperser NANO-3000-10 (manufactured by Nippon BEE Chemical Co., Ltd.) equipped with a pressure reducing mechanism. This dispersion treatment was repeated 10 times to obtain a Blue pigment dispersion liquid.
Polymerizable compound 1: KAYARAD DPHA (mixture of dipentaerythritol hexaacrylate and dipentaerythritol pentaacrylate, manufactured by Nippon Kayaku Co., Ltd.)
Polymerizable compound 4: a structure shown below

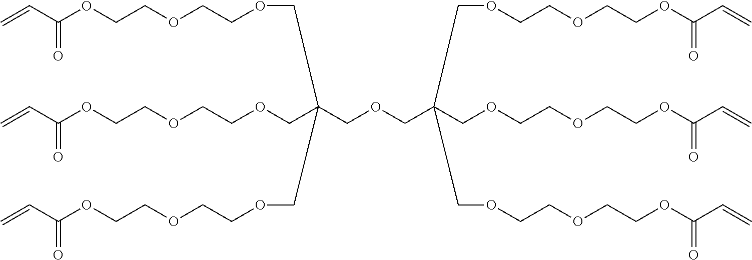 [SMILES: C=CC(=O)OCCOCCOCC(COCCOCCOC(=O)C=C)(COCCOCCOC(=O)C=C)COCC(COCCOCCOC(=O)C=C)(COCCOCCOC(=O)C=C)COCCOCCOC(=O)C=C]

Resin 4: a structure shown below (acid value: 70 mgKOH/g, Mw=11,000, the ratio in each structural unit is a molar ratio)

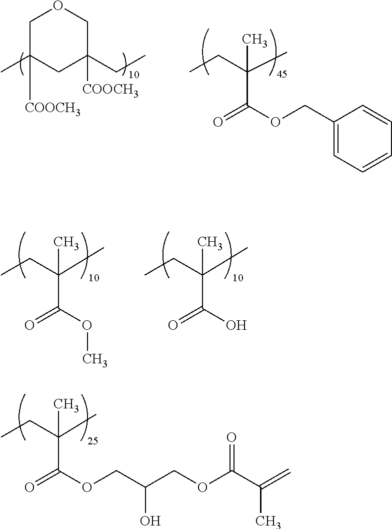

Photopolymerization initiator 1: IRGACURE-OXE01 (1-[4-(phenylthio)]-1,2-octanedione-2-(O-benzoyloxime), manufactured by BASF SE)
Surfactant 1: a 1% by mass PGMEA solution of the following mixture (Mw=14,000). In the following formula, the unit of % (62% and 38%) indicating the percentage of the structural units is % by mass.

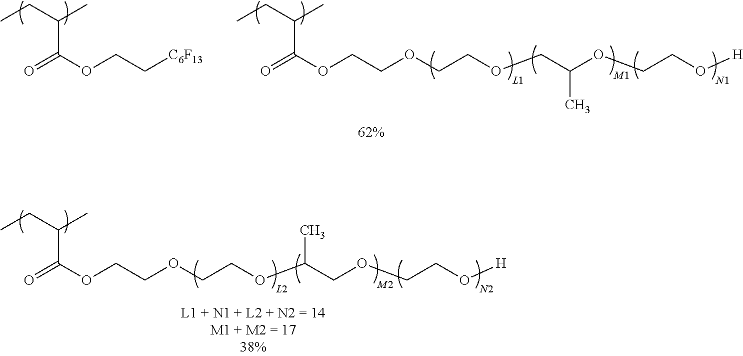

### Example 301

<Formation of Resist Pattern>

Next, a positive photoresist “FHi622BC” (manufactured by FUJIFILM Electronics Materials Co., Ltd.) was applied and pre-baked to form a 0.8 μm-thick photoresist layer. Next, using an i-line stepper exposure apparatus FPA-3000i5+(manufactured by Canon Inc.), the exposure was carried out at a wavelength of 365 nm through a Bayer pattern mask of 1.4 μm square by adjusting the exposure amount such that the pattern size was 1.4 μm square.

Next, a heat treatment was carried out for 1 minute at a temperature at which the temperature of the photoresist layer or an ambient temperature was 90° C. Thereafter, a development treatment was carried out for 1 minute with a developer “FHD-5” (manufactured by FUJIFILM Electronics Materials Co., Ltd.), and further a post-baking treatment was carried out at 110° C. for 1 minute.

<Dry Etching>

Next, dry etching was carried out in the following procedure.

A first stage etching treatment for 80 seconds was carried out in a dry etching apparatus (U-621, manufactured by Hitachi High-Technologies Corporation) with an RF power: 800 W, an antenna bias: 400 W, a wafer bias: 200 W, a chamber internal pressure: 4.0 Pa, a substrate temperature: 50° C., and a gas type and a flow rate of a mixed gas set to CF₄: 80 mL/min., 02: 40 mL/min., and Ar: 800 mL/min.

Then, a second stage etching treatment, over-etching treatment for 28 seconds was carried out in the same etching chamber with an RF power: 600 W, an antenna bias: 100 W, a wafer bias: 250 W, a chamber internal pressure: 2.0 Pa, a substrate temperature: 50° C., and a gas type and a flow rate of a mixed gas set to N₂: 500 mL/min., 02: 50 mL/min., and Ar: 500 mL/min (N₂/O₂/Ar=10/1/10).

After carrying out the dry etching under the above-mentioned conditions, the resist was removed by carrying out a peeling treatment using a photoresist peeling solution “MS230C” (manufactured by FUJIFILM Electronics Materials Co., Ltd.) for 120 seconds, further followed by washing with pure water and spin drying. Thereafter, a dehydration baking treatment was carried out at 100° C. for 2 minutes. Thus, a colored layer was obtained.

The same results as in Example 1 were obtained in a case where the obtained colored layer was evaluated for spectral characteristics and light resistance by the same operation as in Example 1.

The disclosure of JP2018-035195 filed on Feb. 28, 2018 and the disclosure of JP2019-007285 filed on Jan. 18, 2019 are incorporated herein by reference in their entirety.

All publications, patent applications, and technical standards mentioned in the present specification are herein incorporated by reference to the same extent as if each individual publication, patent application, and technical standard were specifically and individually indicated to be incorporated by reference.

What is claimed is:

1. A curable composition comprising:
a compound represented by Formula 1 and having a maximum absorption wavelength in a range of 600 nm or more and less than 700 nm, or a polymer having a structure represented by Formula 2 and having a maximum absorption wavelength in a range of 600 nm or more and less than 700 nm;
a polymerizable compound; and
a chromatic colorant different from the compound represented by Formula 1 and the polymer represented by Formula 2: 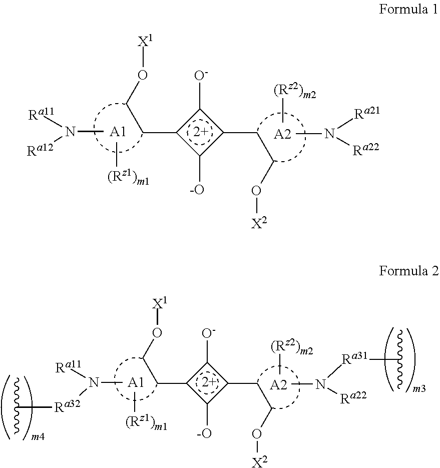
in Formula 1 and Formula 2, A1 and A2 each independently represent an aromatic ring structure which may have a fused ring, R^{z1} and R^{z2} each independently represent a monovalent substituent, at least one of R^{z1}'s and at least one of R^{z2}'s may be bonded to each other to form a ring structure, m1 represents an integer of 0 to mA1, mA1 represents the maximum number of substituents in A1, m2 represents an integer of 0 to mA2, mA2 represents the maximum number of substituents in A2, R^{z} may form a ring structure with any one of R^{a11} or R^{a12}, R^{z2} may form a ring structure with any one of R^{a21} or R^{a22}, X¹ and X² each independently represent a hydrogen atom or a substituent, X¹ and X² may be bonded to each other to form a ring structure, R^{a11}, R^{a12}, R^{a21}, and R^{a22} each independently represent an aromatic ring structure which may have a fused ring, R^{a31} and R^{a32} each independently represent an aromatic ring structure which may have a fused ring, or a linking group having an aromatic ring structure which may have a fused ring, m3 and m4 each independently represent 0 or 1, at least one of m3 or m4 is 1, at least one of R^{a11}, R^{a12}, R^{a21}, or R^{a22} in Formula 1 represents an aromatic ring structure represented by A1 or A2 and having a substituent at a position adjacent to an atom to which a nitrogen atom in Formula 1 is bonded, or an aromatic ring structure represented by A1 or A2 and having a fused ring at a position adjacent to the atom to which a nitrogen atom in Formula 1 is bonded, at least one of R^{a11}, R^{a22}, R^{a31}, or R^{a32} in Formula 2 represents an aromatic ring structure represented by A1 or A2 and having a substituent at a position adjacent to an atom to which a nitrogen atom in Formula 2 is bonded, or an aromatic ring structure represented by A1 or A2 and having a fused ring at a position adjacent to the atom to which a nitrogen atom in Formula 2 is bonded, and a wavy line portion represents a bonding position to another structure.

2. The curable composition according to claim 1,
wherein the chromatic colorant is a yellow colorant.

3. The curable composition according to claim 1,
wherein the chromatic colorant is a yellow pigment.

4. The curable composition according to claim 1,
wherein the chromatic colorant includes at least one selected from the group consisting of C.I. Pigment Yellow 139, C.I. Pigment Yellow 150, and C.I. Pigment Yellow 185.

5. A curable composition used for producing a color filter, the curable composition comprising:
a compound represented by Formula 1 and having a maximum absorption wavelength in a range of 600 nm or more and less than 700 nm, or a polymer having a structure represented by Formula 2 and having a maximum absorption wavelength in a range of 600 nm or more and less than 700 nm; and
a polymerizable compound: 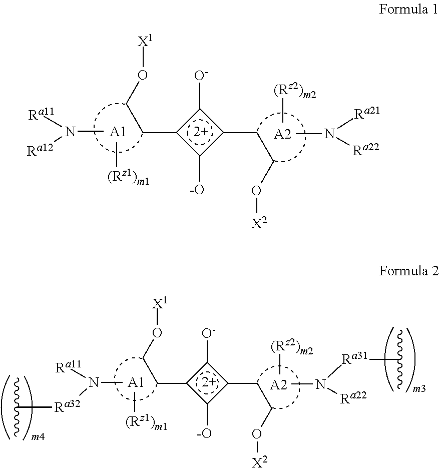
in Formula 1 and Formula 2, A1 and A2 each independently represent an aromatic ring structure which may have a fused ring, R^{z1} and R^{z2} each independently represent a monovalent substituent, at least one of R^{z1}'s and at least one of R^{z2}'s may be bonded to each other to form a ring structure, m1 represents an integer of 0 to mA1, mA1 represents the maximum number of substituents in A1, m2 represents an integer of 0 to mA2, mA2 represents the maximum number of substituents in A2, R^{z1} may form a ring structure with any one of R^{a11} or R^{a12}, R^{z2} may form a ring structure with any one of R^{a21} or R^{a22}, X¹ and X² each independently represent a hydrogen atom or a substituent, X¹ and X² may be bonded to each other to form a ring structure, R^{a11}, R^{a12}, R^{a21}, and R^{a22} each independently represent an aromatic ring structure which may have a fused ring, R^{a31} and R^{a32} each independently represent an aromatic ring structure which may have a fused ring, or a linking group having an aromatic ring structure which may have a fused ring, m3 and m4 each independently represent 0 or 1, at least one of m3 or m4 is 1, at least one of R^{a11}, R^{a12}, R^{a21}, or R^{a22} in Formula 1 represents an aromatic ring structure represented by A1 or A2 and having a substituent at a position adjacent to an atom to which a nitrogen atom in Formula 1 is bonded, or an aromatic ring structure represented by A1 or A2 and having a fused ring at a position adjacent to the atom to which a nitrogen atom in Formula 1 is bonded, at least one of R^{a11}, R^{a22}, R^{a31}, or R^{a32} in Formula 2 represents an aromatic ring structure represented by A1 or A2 and having a substituent at a position adjacent to an atom to which a nitrogen atom in Formula 2 is bonded, or an aromatic ring structure represented by A1 or A2 and having a fused ring at a position adjacent to the atom to which a nitrogen atom in Formula 2 is bonded, and a wavy line portion represents a bonding position to another structure.

6. The curable composition according to claim 1,
wherein at least one of A1 or A2 has a benzene ring structure.

7. The curable composition according to claim 1,
wherein at least one of R^{a11}, R^{a12}, R²¹, or R^{a22} has a structure represented by Formula R-1: 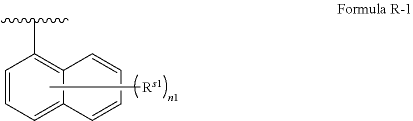
in Formula R-1, R^{z1}'s each independently represent a substituent, a plurality of R^{z1}'s may be bonded to each other to form a ring structure, n1 represents an integer of 0 to 7, and a wavy line portion represents a bonding site to a nitrogen atom in Formula 1.

8. The curable composition according to claim 1, further comprising:
a photopolymerization initiator.

9. A cured product obtained by curing the curable composition according to claim 1.

10. A color filter comprising:
the cured product according to claim 9.

11. A method for producing a color filter, comprising:
a step of applying the curable composition according to claim 1 onto a support to form a composition film;
a step of exposing the formed composition film to light in a pattern-wise manner; and
a step of developing the composition film after exposure to form a colored pattern.

12. A method for producing a color filter, comprising:
a step of applying the curable composition according to claim 1 onto a support and curing the applied curable composition to form a cured product;
a step of forming a photoresist layer on the cured product;
a step of exposing the photoresist layer to light in a pattern-wise manner and developing the exposed photoresist layer to form a resist pattern; and
a step of etching the cured product through the resist pattern.

13. A solid-state imaging element comprising:
the color filter according to claim 10.

14. An image display device comprising:
the color filter according to claim 10.

15. The curable composition according to claim 5,
wherein at least one of A1 or A2 has a benzene ring structure.

16. The curable composition according to claim 5,
wherein at least one of R^{a11}, R^{a12}, R^{a21}, or R^{a22} has a structure represented by Formula R-1: 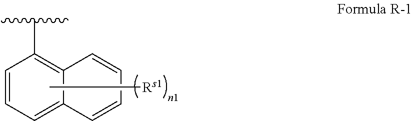
in Formula R-1, R^{s1}'s each independently represent a substituent, a plurality of R^{s1}'s may be bonded to each other to form a ring structure, n1 represents an integer of 0 to 7, and a wavy line portion represents a bonding site to a nitrogen atom in Formula 1.

17. The curable composition according to claim 5, further comprising:
a photopolymerization initiator.

18. A cured product obtained by curing the curable composition according to claim 5.

19. A color filter comprising:
the cured product according to claim 18.

20. A method for producing a color filter, comprising:
a step of applying the curable composition according to claim 5 onto a support to form a composition film;
a step of exposing the formed composition film to light in a pattern-wise manner; and
a step of developing the composition film after exposure to form a colored pattern.

21. A method for producing a color filter, comprising:
a step of applying the curable composition according to claim 5 onto a support and curing the applied curable composition to form a cured product;
a step of forming a photoresist layer on the cured product;
a step of exposing the photoresist layer to light in a pattern-wise manner and developing the exposed photoresist layer to form a resist pattern; and
a step of etching the cured product through the resist pattern.

22. A solid-state imaging element comprising:
the color filter according to claim 19.

23. An image display device comprising:
the color filter according to claim 19.
